(19) United States
(12) Patent Application Publication
(10) Pub. No.: US 2025/0070103 A1
(43) Pub. Date: Feb. 27, 2025

(54) SEMICONDUCTOR DEVICE

(71) Applicant: ROHM CO., LTD., Kyoto (JP)

(72) Inventors: Masanobu TSUJI, Kyoto (JP); Yoshizo OSUMI, Kyoto (JP); Keiji WADA, Kyoto (JP); Bungo TANAKA, Kyoto (JP)

(21) Appl. No.: 18/790,093

(22) Filed: Jul. 31, 2024

(30) Foreign Application Priority Data
Aug. 23, 2023 (JP) 2023-135890

(51) Int. Cl. H01L 25/16; H01F 27/28; H01L 23/00; H01L 23/31; H01L 23/495

(52) U.S. Cl. CPC H01L 25/162; H01F 27/2804; H01L 23/3135; H01L 23/49575; H01L 24/48; H01L 24/49; H01L 28/10; H01L 24/32; H01L 24/73; H01L 2224/32245; H01L 2224/48228; H01L 2224/48245; H01L 2224/4903; H01L 2224/73265

(57) ABSTRACT

A semiconductor device includes: a first chip including a first circuit; a second chip disposed to be spaced apart from the first chip in a first direction and including a second circuit; and a transformer chip disposed over the first chip and including a transformer. The first circuit and the second circuit are configured to transmit a signal or power via the transformer. The transformer chip includes: an element insulating layer; and an outer coil and an inner coil disposed as the transformer in the element insulating layer. The inner coil is disposed inside the outer coil so as not to overlap the outer coil when viewed from a thickness direction of the element insulating layer.

### CROSS-REFERENCE TO RELATED APPLICATION

This application is based upon and claims the benefit of priority from Japanese Patent Application No. 2023-135890, filed on Aug. 23, 2023, the entire contents of which are incorporated herein by reference.

### TECHNICAL FIELD

The present disclosure relates to a semiconductor device.

### BACKGROUND

The related art discloses a transformer chip including a semiconductor substrate, an insulating layer stack structure formed on the substrate, and an upper coil and a lower coil formed within the insulating layer stack structure.

### BRIEF DESCRIPTION OF DRAWINGS

The accompanying drawings, which are incorporated in and constitute a part of the specification, illustrate embodiments of the present disclosure.

FIG. 1 is a schematic circuit diagram of a semiconductor device according to a first embodiment.

FIG. 2 is a schematic plan view of the semiconductor device of FIG. 1.

FIG. 3 is a schematic cross-sectional view of the semiconductor device taken along line F3-F3 in FIG. 2.

FIG. 4 is a schematic plan view of a first chip in the semiconductor device of FIG. 2.

FIG. 5 is a schematic cross-sectional view of the first chip taken along line F5-F5 in FIG. 4.

FIG. 6 is a schematic plan view of a second chip in the semiconductor device of FIG. 2.

FIG. 7 is a schematic cross-sectional view of the second chip taken along line F7-F7 in FIG. 6.

FIG. 8 is a schematic plan view of a transformer chip in the semiconductor device of FIG. 2.

FIG. 9 is a schematic cross-sectional view of the transformer chip taken along line F9-F9 in FIG. 8.

FIG. 10 is a schematic cross-sectional view of the transformer chip taken along line F10-F10 in FIG. 8.

FIG. 11 is an enlarged schematic cross-sectional view of the first chip, the second chip, the transformer chip, and their periphery in the semiconductor device of FIG. 3.

FIG. 12 is a schematic cross-sectional view of a transformer chip in a semiconductor device according to a second embodiment.

FIG. 13 is a schematic circuit diagram of a semiconductor device according to a third embodiment.

FIG. 14 is a schematic plan view of the semiconductor device of FIG. 13.

FIG. 15 is a schematic plan view of a transformer chip in the semiconductor device of FIG. 14.

FIG. 16 is a schematic cross-sectional view of the transformer chip and a first chip taken along line F16-F16 in FIG. 15.

FIG. 17 is a schematic cross-sectional view of the transformer chip and the first chip taken along line F17-F17 in FIG. 15.

FIG. 18 is a schematic cross-sectional view of a transformer chip in a first modification of the semiconductor device according to the first embodiment.

FIG. 19 is a schematic cross-sectional view of a transformer chip in a second modification of the semiconductor device according to the first embodiment.

FIG. 20 is an exploded perspective view of a portion of the transformer chip in the second modification of the semiconductor device according to the first embodiment.

FIG. 21 is a schematic cross-sectional view of a transformer chip in a third modification of the semiconductor device according to the first embodiment.

FIG. 22 is a schematic cross-sectional view of a transformer chip in a fourth modification of the semiconductor device according to the first embodiment.

FIG. 23 is a schematic cross-sectional view of a portion of a transformer chip in a modification of the semiconductor device according to the second embodiment.

FIG. 24 is a schematic cross-sectional view of a transformer chip in a first modification of the semiconductor device according to the third embodiment.

FIG. 25 is a schematic cross-sectional view of a transformer chip in a second modification of the semiconductor device according to the third embodiment.

FIG. 26 is an exploded perspective view of a portion of the transformer chip in the second modification of the semiconductor device according to the third embodiment.

FIG. 27 is a schematic cross-sectional view of a transformer chip in a third modification of the semiconductor device according to the third embodiment.

FIG. 28 is a schematic cross-sectional view of a transformer chip in a fourth modification of the semiconductor device according to the third embodiment.

FIG. 29 is a schematic plan view of a transformer chip in a fifth modification of the semiconductor device according to the third embodiment.

FIG. 30 is a schematic plan view of a transformer chip in the fifth modification of the semiconductor device according to the third embodiment.

FIG. 31 is a schematic cross-sectional view of a portion of a transformer chip in a modification of the semiconductor device according to the third embodiment.

FIG. 32 is a schematic cross-sectional view of a portion of the transformer chip in the modification of the semiconductor device according to the third embodiment.

FIG. 33 is a schematic cross-sectional view of a portion of a transformer chip in a modification of the semiconductor device according to the third embodiment.

FIG. 34 is a schematic cross-sectional view of a portion of the transformer chip in the modification of the semiconductor device according to the third embodiment.

FIG. 35 is a schematic cross-sectional view of a first chip, a transformer chip, and their periphery in a modification of the semiconductor device.

FIG. 36 is a schematic cross-sectional view of a first chip, a second chip, a transformer chip, and their periphery in a modification of the semiconductor device.

FIG. 37 is a schematic plan view of a modification of the semiconductor device.

FIG. 38 is a schematic plan view of a modification of the semiconductor device.

FIG. 39 is a schematic circuit diagram of a modification of the semiconductor device.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, some embodiments of a semiconductor device according to the present disclosure are described with reference to the accompanying drawings. It should be noted that, for simplicity and clarity of explanation, the constituent elements shown in the drawings are not necessarily drawn to scale. Further, in order to facilitate understanding, hatching lines may be omitted in cross-sectional views. The accompanying drawings merely illustrate embodiments of the present disclosure and should not be considered as limiting the present disclosure. The terms such as “first,” “second,” and “third” in the present disclosure are used merely to distinguish between objects and are not intended to rank the objects.

The following detailed description includes devices, systems, and methods embodying exemplary embodiments of the present disclosure. This detailed description is for illustrative purposes only and is not intended to limit the embodiments of the present disclosure or the applications and uses of such embodiments.

The expression “at least one” as used in the present disclosure means “one or more” of desired options. As an example, if there are two options, the expression “at least one” as used in the present disclosure means “only one option” or “both of the two options.” As another example, if there are three or more options, the expression “at least one” as used in the present disclosure means “only one option” or “any combination of two or more options.”

“The length (dimension) of A is equal to the length (dimension) of B” or “the length (dimension) of A and the length (dimension) of B are equal to each other” as used in the present disclosure also includes a relationship in which a difference between the length (dimension) of A and the length (dimension) of B is, for example, within 10% of the length (dimension) of A.

### First Embodiment

### Schematic Configuration of Semiconductor Device

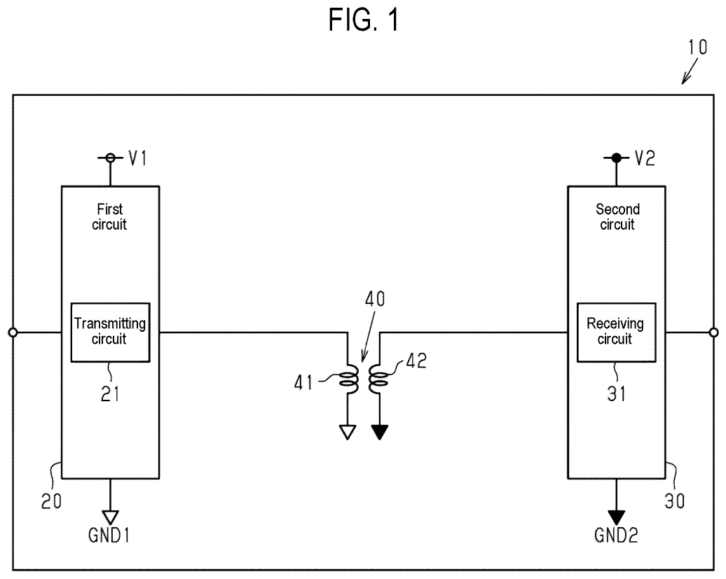

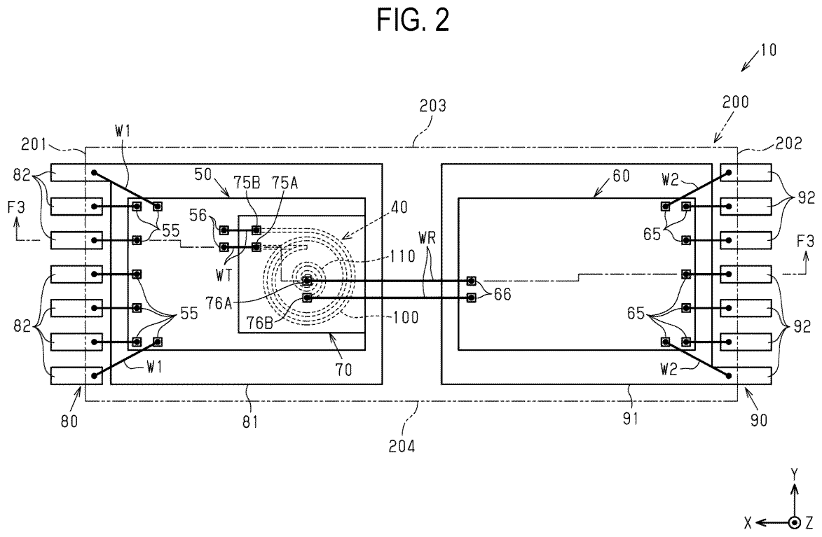

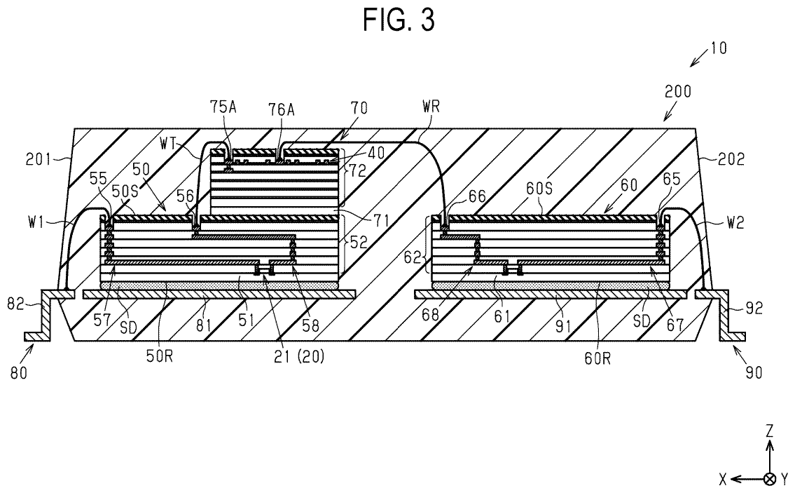

A schematic configuration of a semiconductor device 10 according to a first embodiment is described with reference to FIGS. 1 to 3. FIG. 1 shows a schematic circuit configuration of the semiconductor device 10 according to the first embodiment. FIG. 2 shows an example of a schematic internal configuration (planar structure) of the semiconductor device 10. In FIG. 2, a sealing resin 200 to be described later is shown by a two-dot chain line to show the internal configuration of the semiconductor device 10. FIG. 3 is a schematic diagram of a cross-sectional structure of the semiconductor device 10 of FIG. 2 taken along line F3-F3.

Further, FIG. 1 shows a simplified circuit configuration of the semiconductor device 10, so the number of external terminals of the semiconductor device 10 of FIG. 2 is larger than the number of external terminals of the semiconductor device 10 of FIG. 1. Herein, the number of external terminals of the semiconductor device 10 refers to the number of external electrodes that are capable of connecting the semiconductor device 10 to electronic components outside the semiconductor device 10.

### Circuit Configuration of Semiconductor Device

As shown in FIG. 1, the semiconductor device 10 includes a first circuit 20, a second circuit 30, and a transformer 40. The transformer 40 is configured to electrically insulate the first circuit 20 from the second circuit 30.

The first circuit 20 is configured to operate with a first voltage V1. In one example, the first circuit 20 includes a transmitting circuit or a receiving circuit. In the first embodiment, the first circuit 20 includes a transmitting circuit 21. The transmitting circuit 21 includes at least one transistor. The second circuit 30 is configured to operate with a second voltage V2. In one example, the second circuit 30 includes a transmitting circuit or a receiving circuit. In the first embodiment, the second circuit 30 includes a receiving circuit 31. The receiving circuit 31 includes at least one transistor. The first voltage VI and the second voltage V2 may be the same as each other or may be different from each other. In one example, the second voltage V2 is equal to the first voltage V1. The semiconductor device 10 may be called a digital isolator. Therefore, the semiconductor device 10 may also be called a signal transmission device that transmits a signal from the first circuit 20 to the second circuit 30.

The transformer 40 includes a first coil 41 and a second coil 42. The first coil 41 is electrically connected to the transmitting circuit 21 of the first circuit 20. The second coil 42 is electrically connected to the receiving circuit 31 of the second circuit 30.

The transmitting circuit 21 of the first circuit 20 receives an input signal and pulse-drives the transformer 40. A pulse signal excited in the first coil 41 of the transformer 40 is transmitted through the second coil 42 and is input to the receiving circuit 31 of the second circuit 30. The receiving circuit 31 outputs an output signal based on the input pulse signal.

### Internal Configuration of Semiconductor Device

As shown in FIG. 2, the semiconductor device 10 includes a first chip 50, a second chip 60, a transformer chip 70, a first lead frame 80, a second lead frame 90, and a sealing resin 200. The sealing resin 200 is configured to seal the first chip 50, the second chip 60, and the transformer chip 70, and to partially seal the first lead frame 80 and the second lead frame 90. Further, in FIG. 2, the sealing resin 200 is shown by a two-dot chain line for the convenience of explaining the internal configuration of the semiconductor device 10.

In this way, in the semiconductor device 10, the first chip 50, the second chip 60, and the transformer chip 70 are packaged as a plurality of semiconductor chips by the sealing resin 200.

A package format of the semiconductor device 10 is a SO (Small Outline) type, and in the first embodiment, it is a SOP (Small Outline Package). Further, the package format of the semiconductor device 10 may be changed arbitrarily. The package format is not limited to SOP, and may be QFN (Quad For Non Lead Package), DFP (Dual Flat Package), DIP (Dual Inline Package), QFP (Quad Flat Package), SIP (Single Inline Package), or SOJ (Small Outline J-leaded Package), or various package structures similar to these.

The sealing resin 200 is made of a resin material having electrical insulation properties. This resin material includes, for example, black epoxy resin. The sealing resin 200 is formed in a rectangular plate shape with a thickness direction being in a Z direction. The sealing resin 200 has four sealing side surfaces 201 to 204. More specifically, the sealing resin 200 has sealing side surfaces 201 and 202 as both end surfaces facing in an X direction and sealing side surfaces 203 and 204 as both end surfaces facing in a Y direction. The X direction and the Y direction are orthogonal to the Z direction. The X direction and the Y direction are orthogonal to each other when viewed from the Z direction. The sealing resin 200 has a rectangular shape with the X direction being a direction along a long side and the Y direction being a direction along a short side when viewed from the Z direction. Herein, the X direction corresponds to a “first direction.” In the following description, “plan view” means that the semiconductor device 10 or a component of the semiconductor device 10 is viewed from the Z direction.

Each of the first lead frame 80 and the second lead frame 90 is a conductor and is made of a material containing, for example, Cu (copper), Fe (iron), Al (aluminum), etc. Each of the lead frames 80 and 90 is provided across an inside and outside of the sealing resin 200. The first lead frame 80 and the second lead frame 90 are arranged to be spaced apart from each other in the X direction.

The first lead frame 80 includes a first die pad 81 disposed in the sealing resin 200 and a plurality of first leads 82 disposed across the inside and outside of the sealing resin 200. Each of the first leads 82 constitutes an external terminal that electrically connects to an electronic apparatus outside the semiconductor device 10.

The first chip 50 is mounted on the first die pad 81. In a plan view, the first die pad 81 is disposed so that its center in the X direction is closer to the sealing side surface 201 than a center of the sealing resin 200 in the X direction. In the first embodiment, the first die pad 81 is not exposed from the sealing resin 200. In one example, a shape of the first die pad 81 in a plan view is a rectangle with the X direction being a direction along a long side direction and the Y direction being a direction along a short side.

The plurality of first leads 82 are arranged to be spaced apart from each other in the Y direction. Among the plurality of first leads 82, a first lead 82 disposed at an end portion near the sealing side surface 203 in the Y direction is integrated with the first die pad 81. The remaining first leads 82 are disposed to be spaced apart from the first die pad 81 in the X direction. A portion of each of the first leads 82 protrudes from the sealing side surface 201 toward the outside of the sealing resin 200.

The second lead frame 90 includes a second die pad 91 disposed in the sealing resin 200 and a plurality of second leads 92 disposed across the inside and outside of the sealing resin 200. Each of the second leads 92 constitutes an external terminal that electrically connects to an electronic apparatus outside the semiconductor device 10.

The second chip 60 is mounted on the second die pad 91. It may be said that the second die pad 91 supports the second chip 60. In a plan view, the second die pad 91 is disposed to be closer to the sealing side surface 202 than the first die pad 81 in the X direction. That is, the first die pad 81 and the second die pad 91 are disposed to be spaced apart from each other in the X direction. Therefore, the X direction may also be said to be a disposition direction of both die pads 81 and 91. The second chip 60 is disposed to be spaced apart from the first chip 50 in the X direction. In the first embodiment, the second die pad 91 is not exposed from the sealing resin 200. In one example, a shape of the second die pad 91 in a plan view is a rectangle with the X direction being a direction along a long side and the Y direction being a direction along a short side. Also, the shape of the second die pad 91 in a plan view may be changed arbitrarily depending on the number and shape of semiconductor chips mounted on the second die pad 91.

The plurality of second leads 92 are arranged to be spaced apart from each other in the Y direction. Among the plurality of second leads 92, a second lead 92 disposed at an end portion near the sealing side surface 204 in the Y direction is integrated with the second die pad 91. The remaining second leads 92 are disposed to be spaced apart from the second die pad 91 in the X direction. A portion of each of the second leads 92 protrudes from the sealing side surface 202 toward the outside of the sealing resin 200.

In the first embodiment, the number of second leads 92 is the same as the number of first leads 82. As shown in FIG. 2, the plurality of first leads 82 and the plurality of second leads 92 are arranged in a direction (Y direction) orthogonal to the arrangement direction (X direction) of the first die pad 81 and the second die pad 91 in a plan view. The number of second leads 92 and the number of first leads 82 may be changed arbitrarily. In one example, the number of first leads 82 and the number of second leads 92 may be different from each other.

In the first embodiment, the first die pad 81 is supported by the first lead 82 integrated with the first die pad 81. The second die pad 91 is supported by the second lead 92 integrated with the second die pad 91. Therefore, each of the die pads 81 and 91 does not have a hanging lead exposed from each of the sealing side surfaces 203 and 204. Therefore, an insulation distance (creepage distance) between the first lead frame 80 and the second lead frame 90 may be made large.

The first chip 50 mounted on the first die pad 81 includes the first circuit 20 of FIG. 1. The first chip 50 is formed in a rectangular shape having short and long sides in a plan view. In a plan view, the first chip 50 is mounted on the first die pad 81 so that a long side is aligned along the X direction and a short side is aligned along the Y direction. As shown in FIG. 3, the first chip 50 is bonded to the first die pad 81 by a conductive bonding material SD. The conductive bonding material SD is, for example, a solder paste, an Ag (silver) paste, etc.

The first chip 50 includes a plurality of first pads 55. The plurality of first pads 55 are electrically connected to the first circuit 20. Further, the plurality of first pads 55 are individually connected to the plurality of first leads 82 by wires W1. Each of the first pads 55 is made of, for example, a material containing one or more appropriately selected from the group of Ti (titanium), TiN (titanium nitride), Au (gold), Ag, Cu, Al (aluminum), and W (tungsten). Each of the wires W1 is a bonding wire formed by a wire bonding device and is made of a conductor including, for example, Au, Al, Cu, etc.

As shown in FIG. 2, the second chip 60 mounted on the second die pad 91 includes the second circuit 30 of FIG. 1. The second chip 60 is formed in a rectangular shape having short and long sides in a plan view. In a plan view, the second chip 60 is mounted on the second die pad 91 so that a long side is aligned along the X direction and a short side is aligned along the Y direction. As shown in FIG. 3, the second chip 60 is bonded to the second die pad 91 by a conductive bonding material SD.

As shown in FIG. 2, the second chip 60 includes a plurality of second pads 65. The plurality of second pads 65 are electrically connected to the second circuit 30. Further, the plurality of second pads 65 are individually connected to the plurality of second leads 92 by wires W2. Each of the second pads 65 is made of, for example, a material containing one or more appropriately selected from the group of Ti, TiN, Au, Ag, Cu, Al, and W. Each of the wires W2 is a bonding wire formed by a wire bonding device and is made of a conductor containing, for example, Au, Al, Cu, etc.

As shown in FIGS. 2 and 3, in the first embodiment, the transformer chip 70 is disposed over the first chip 50. The transformer chip 70 includes the transformer 40 of FIG. 1. The transformer chip 70 is formed in a rectangular shape having short sides and long sides in a plan view. In a plan view, the transformer chip 70 is disposed over the first chip 50 so that a long side is aligned along the X direction and a short side is aligned along the Y direction. As shown in FIG. 2, in the first embodiment, a dimension of the transformer chip 70 in the Y direction is smaller than both a dimension of the first chip 50 in the Y direction and a dimension of the second chip 60 in the Y direction. Also, the dimension of the transformer chip 70 in the Y direction may be changed arbitrarily. In one example, the dimension of the transformer chip 70 in the Y direction may be equal to the dimension of the first chip 50 in the Y direction. In one example, the dimension of the transformer chip 70 in the Y direction may be equal to the dimension of the second chip 60 in the Y direction. An electrical connection structure of the transformer chip 70 with the first chip 50 and the second chip 60 is described later.

Further, the configuration of the semiconductor device 10 shown in FIGS. 1 to 3 is an example, and circuit configurations included in the first chip 50 and the second chip 60 may be changed as appropriate. The first circuit 20 may include a circuit other than the transmitting circuit 21. The second circuit 30 may include a circuit other than the receiving circuit 31. For example, the first circuit 20 may include an analog-digital conversion circuit. In this case, the semiconductor device 10 is configured as an insulated A/D conversion device.

Further, for example, the second circuit 30 may include a driver circuit that drives a gate of a switching element. The driver circuit may also be connected to an external terminal (for example, the second lead 92 shown in FIG. 2) of the semiconductor device 10. In this case, the semiconductor device 10 is configured as an insulated gate driver that drives the switching element. The switching element is a power semiconductor element such as a SiMOSFET (Si Metal-Oxide-Semiconductor Field-Effect Transistor), a SiCMOSFET, or an IGBT (Insulated Gate Bipolar Transistor). The driver circuit is generally a half-bridge circuit in which a low-side switching element and a high-side switching element are connected in a totem pole shape.

The semiconductor device 10 used as the insulated gate driver applies a drive voltage signal to a control terminal of the switching element. In this case, the transmitting circuit 21 of the first circuit 20 converts a control signal input from, for example, a control device, into a pulse signal. The driver circuit of the second circuit 30 outputs the drive voltage signal to the control terminal of the switching element in response to a signal received by the receiving circuit 31 through the transformer 40.

In this way, in the semiconductor device 10 used as the insulated gate driver, a power supply voltage of the first circuit 20 that receives a signal from the control device is 5 V, 3.3 V, etc. with respect to a ground potential. On the other hand, in the case of the second circuit 30 connected to the high-side switching element, a voltage (for example, 600 V or higher) equivalent to a voltage applied to a drain of the high-side switching element is applied transiently. For this reason, the semiconductor device 10 is required to have a dielectric breakdown voltage between the first circuit 20 and the second circuit 30, more specifically between the first coil 41 and the second coil 42 of the transformer 40. This dielectric breakdown voltage is, for example, 2,500 Vrms or higher and 7,500 Vrms or lower. In one example, the dielectric breakdown voltage of the semiconductor device 10 is about 5,000 Vrms. However, the specific value of the dielectric breakdown voltage of the semiconductor device 10 is not limited thereto and is arbitrary.

### Configuration of First Chip

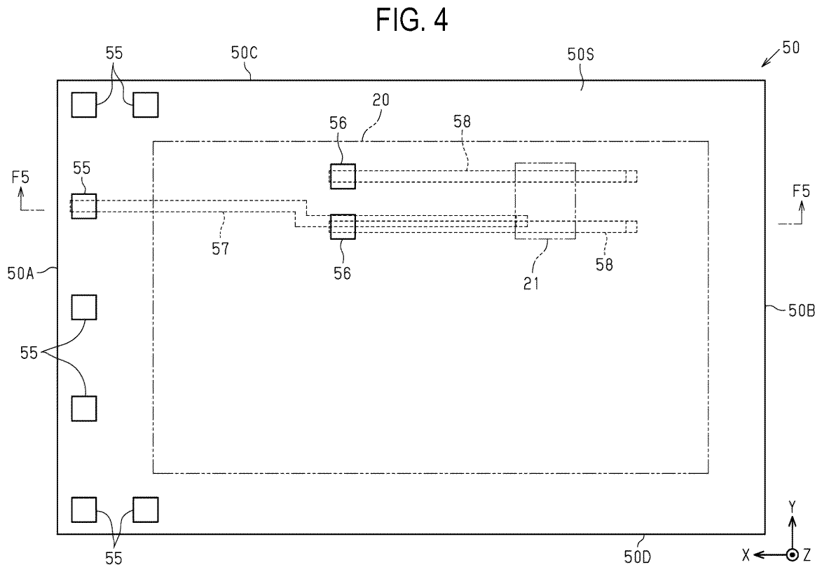

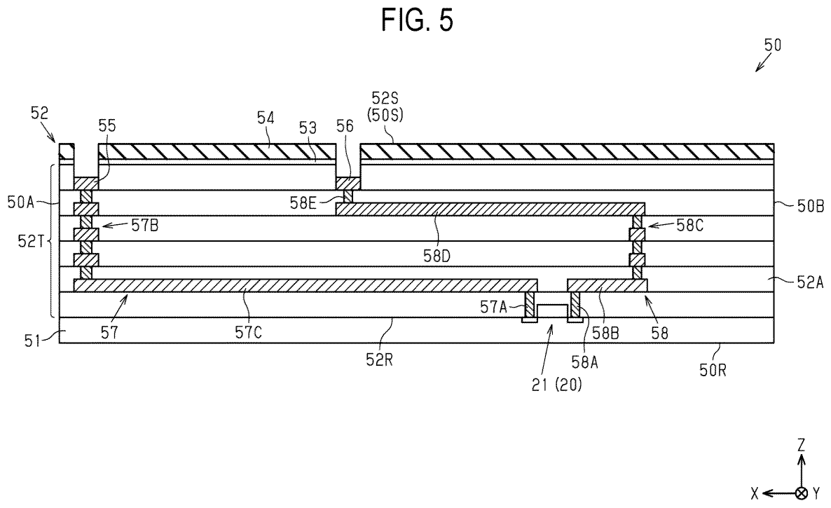

An example of a configuration of the first chip 50 is described with reference to FIGS. 3 to 5. FIG. 4 shows a schematic planar structure of the first chip 50. FIG. 5 shows a schematic cross-sectional structure of the first chip 50 taken along line F5-F5 in FIG. 4. Further, in FIG. 5, one transistor of the transmitting circuit 21 is shown as the transmitting circuit 21.

As shown in FIGS. 4 and 5, the first chip 50 having a rectangular flat plate shape includes a chip front surface 50S and a chip back surface 50R facing opposite sides to each other in the Z direction, and four chip side surfaces 50A to 50D connecting the chip front surface 50S and the chip back surface 50R. The chip front surface 50S of the first chip 50 is, for example, a surface that contacts the transformer chip 70 (see FIG. 3). The chip back surface 50R is a surface that faces the first die pad 81 (see FIG. 3). The chip side surfaces 50A and 50B constitute both end surfaces of the first chip 50 in the X direction, and the chip side surfaces 50C and 50D constitute both end surfaces of the first chip 50 in the Y direction.

As shown in FIG. 3, the first chip 50 includes a first semiconductor substrate 51 and a first element insulating layer 52 formed over the first semiconductor substrate 51. The first semiconductor substrate 51 constitutes the chip back surface 50R of the first chip 50. The chip back surface 50R (the first semiconductor substrate 51) is bonded to the first die pad 81 by a conductive bonding material SD. The first semiconductor substrate 51 is made of a material containing, for example, Si. In the first embodiment, the first semiconductor substrate 51 is a Si substrate. Further, a wide band gap semiconductor or a compound semiconductor may be used for the first semiconductor substrate 51. The wide band gap semiconductor is a semiconductor substrate having a band gap of 2.0 eV or higher. The wide band gap semiconductor may be SiC (silicon carbide). The compound semiconductor may be a Group III-V compound semiconductor. The compound semiconductor may include at least one selected from the group of AlN (aluminum nitride), InN (indium nitride), GaN (gallium nitride), and GaAs (gallium arsenide).

As shown in FIG. 5, the first element insulating layer 52 includes a first element front surface 52S facing the transformer chip 70 (see FIG. 3) and a first element back surface 52R opposite to the first element front surface 52S. The first element back surface 52R is in contact with the first semiconductor substrate 51. The first element front surface 52S constitutes the chip front surface 50S of the first chip 50.

The first element insulating layer 52 includes an insulator 52T in which a plurality of insulating films 52A are stacked in the Z direction. Therefore, the Z direction may be said to be a thickness direction of the first element insulating layer 52. Each insulating film 52A is an oxide film made of a material containing, for example, SiO₂ (silicon oxide). Each insulating film 52A has a thickness of, for example, 500 nm or more and 5,000 nm or less. In the first embodiment, each insulating film 52A has a thickness of about 3,000 nm. Further, the number of stacked insulating films 52A is not limited to the example shown in FIG. 5 and may be changed arbitrarily.

The first element insulating layer 52 includes a first protective film 53 and a first passivation film 54. The first protective film 53 is a film that protects the insulator 52T. The first protective film 53 is formed over the insulator 52T. The first protective film 53 is formed of a material containing, for example, SiO₂. In one example, the first protective film 53 is formed over an entire surface of the insulator 52T in a plan view. Further, the material constituting the first protective film 53 may be changed arbitrarily. The first protective film 53 may be made of a material containing, for example, SiN (silicon nitride).

The first passivation film 54 is a surface protective film for the first chip 50. The first passivation film 54 is formed over the first protective film 53. The first passivation film 54 constitutes the first element front surface 52S of the first element insulating layer 52. The first passivation film 54 is made of a material containing at least one selected from the group of, for example, PI (polyimide), SiN, and SiO₂. In one example, the first passivation film 54 is made of a material containing SiO₂. In one example, the first passivation film 54 is formed over an entire surface of the first protective film 53 in a plan view. Further, the material constituting the first passivation film 54 may be changed arbitrarily. The first passivation film 54 may be made of a same material as the first protective film 53, or may be made of a material different from the first protective film 53.

As shown in FIG. 4, the plurality of first pads 55 are disposed at an end portion, which is closer to the chip side surface 50A, of both end portions of the chip front surface 50S in the X direction. Herein, the chip side surface 50A is a side surface of the first chip 50 that is closer to the plurality of first leads 82 (see FIG. 2).

The first chip 50 includes a plurality of intermediate pads 56 (two intermediate pads 56 in the first embodiment) that are electrically connected to the transformer chip 70. The plurality of intermediate pads 56 are disposed at a same position in the X direction and are spaced apart from each other in the Y direction. The plurality of intermediate pads 56 are disposed to be closer to the chip side surface 50B than, for example, the plurality of first pads 55 in the X direction. As shown in FIG. 5, the plurality of intermediate pads 56 are disposed at a same position as the plurality of first pads 55 in the Z direction. Each intermediate pad 56 is made of, for example, a material containing one or more appropriately selected from the group of Ti, TiN, Au, Ag, Cu, Al, and W.

The first circuit 20, a first connection wiring 57 that connects the first circuit 20 and the first pads 55, and a second connection wiring 58 that connects the first circuit 20 and the intermediate pads 56 are provided within the first chip 50. In other words, the first circuit 20 and the first pads 55 are electrically connected within the first chip 50. The first circuit 20 and the intermediate pads 56 are electrically connected within the first chip 50.

As shown in FIG. 5, the first connection wiring 57 includes a first circuit side connection portion 57A that is electrically connected to the transmitting circuit 21, a first pad side connection portion 57B that is electrically connected to the first pads 55, and a first wiring 57C that connects the first circuit side connection portion 57A and the first pad side connection portion 57B.

The first circuit side connection portion 57A is configured, for example, by a via that penetrates a lowermost insulating film 52A of the insulator 52T in the Z direction. The first wiring 57C is a wiring layer formed over the lowermost insulating film 52A. For example, in a plan view, the first wiring 57C extends along the X direction from the first circuit side connection portion 57A toward the chip side surface 50A. The first pad side connection portion 57B includes a configuration in which a plurality of wiring layers and a plurality of vias are alternately stacked one by one in the Z direction. The first pad side connection portion 57B is provided at a position overlapping the first pads 55 in a plan view. Herein, the lowermost insulating film 52A is an insulating film that constitutes the first element back surface 52R of the first element insulating layer 52 and is in contact with the first semiconductor substrate 51.

The second connection wiring 58 includes a second circuit side connection portion 58A, a first intermediate wiring 58B, an intermediate connection portion 58C, a second intermediate wiring 58D, and a second pad side connection portion 58E. The second circuit side connection portion 58A is electrically connected to the transmitting circuit 21. The second circuit side connection portion 58A is configured, for example, by a via that penetrates the lowermost insulating film 52A of the insulator 52T in the Z direction. In one example, the second circuit side connection portion 58A is disposed to be closer to the chip side surface 50B in the X direction than the first circuit side connection portion 57A of the first connection wiring 57. The first intermediate wiring 58B electrically connects the second circuit side connection portion 58A and the intermediate connection portion 58C. For example, in a plan view, the first intermediate wiring 58B extends along the X direction from the second circuit side connection portion 58A toward the chip side surface 50B. The first intermediate wiring 58B is a wiring layer formed over the lowermost insulating film 52A. That is, the first intermediate wiring 58B is disposed at a same position as the first wiring 57C of the first connection wiring 57 in the Z direction. The intermediate connection portion 58C is electrically connected to the second intermediate wiring 58D. The intermediate connection portion 58C is provided to be closer to the chip side surface 50B than the transmitting circuit 21. The intermediate connection portion 58C includes a configuration in which a plurality of vias and a plurality of wiring layers are alternately stacked one by one. The second intermediate wiring 58D is electrically connected to the second pad side connection portion 58E. The second intermediate wiring 58D extends along the X direction from the second pad side connection portion 58E toward the chip side surface 50B in a plan view. The second intermediate wiring 58D is disposed between the first intermediate wiring 58B and the intermediate pads 56 in the Z direction. The second pad side connection portion 58E electrically connects the second intermediate wiring 58D and the intermediate pads 56. The second pad side connection portion 58E is disposed at a position overlapping the intermediate pads 56 in a plan view.

### Configuration of Second Chip

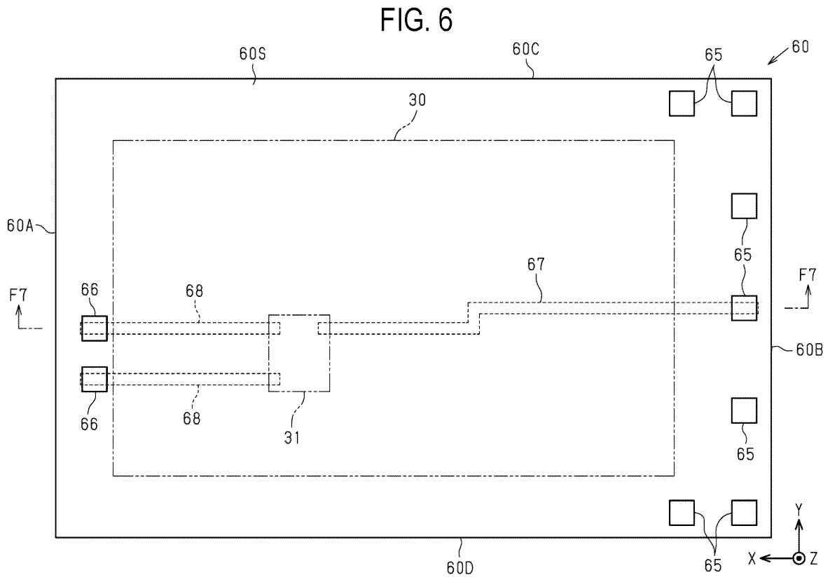

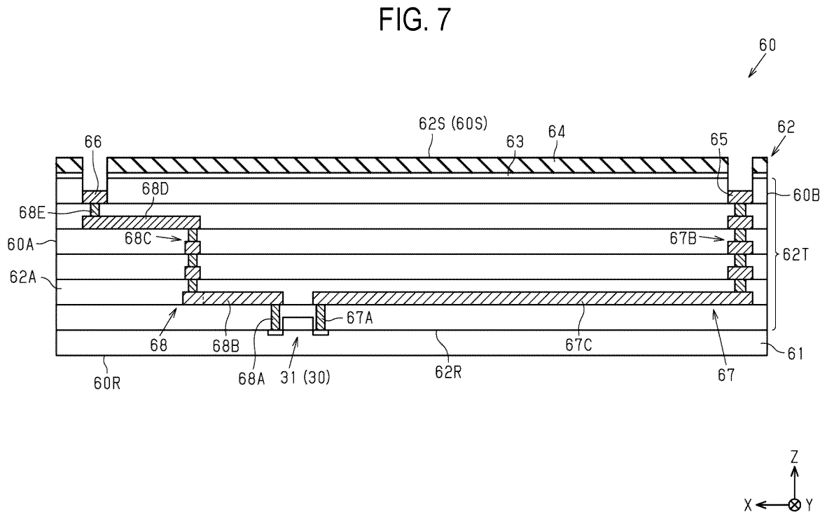

An example of the configuration of the second chip 60 is described with reference to FIGS. 3, 6, and 7. FIG. 6 shows a schematic planar structure of the second chip 60. FIG. 7 shows a schematic cross-sectional structure of the second chip 60 taken along line F7-F7 in FIG. 6. Further, in FIG. 7, one transistor of the receiving circuit 31 is shown as the receiving circuit 31.

As shown in FIGS. 6 and 7, the second chip 60 having a rectangular flat plate shape includes a chip front surface 60S and a chip back surface 60R facing opposite sides to each other in the Z direction, and four chip side surfaces 60A to 60D connecting the chip front surface 60S and the chip back surface 60R. The chip front surface 60S of the second chip 60 faces a same side as the chip front surface 50S of the first chip 50. The chip back surface 60R faces the second die pad 91 (see FIG. 3). The chip side surfaces 60A and 60B constitute both end surfaces of the second chip 60 in the X direction, and the chip side surfaces 60C and 60D constitute both end surfaces of the second chip 60 in the Y direction. The chip side surface 60A faces a same side as the chip side surface 50A (see FIG. 4) of the first chip 50, and the chip side surface 60B faces a same side as the chip side surface 50B (see FIG. 4) of the first chip 50. The chip side surface 60C faces a same side as the chip side surface 50C (see FIG. 4) of the first chip 50, and the chip side surface 60D faces a same side as the chip side surface 50D (see FIG. 4) of the first chip 50.

As shown in FIG. 3, the second chip 60 includes a second semiconductor substrate 61 and a second element insulating layer 62 formed over the second semiconductor substrate 61. The second semiconductor substrate 61 constitutes the chip back surface 60R of the second chip 60. The chip back surface 60R (the second semiconductor substrate 61) is bonded to the second die pad 91 by a conductive bonding material SD. The second semiconductor substrate 61 is made of a material containing, for example, Si. In the first embodiment, the second semiconductor substrate 61 is a Si substrate. Also, a wide band gap semiconductor or a compound semiconductor may be used for the second semiconductor substrate 61.

As shown in FIG. 7, the second element insulating layer 62 includes a second element front surface 62S facing an opposite side to the second die pad 91 (see FIG. 3) and a second element back surface 62R opposite to the second element front surface 62S. The second element back surface 62R is in contact with the second semiconductor substrate 61. The second element front surface 62S constitutes the chip front surface 60S of the second chip 60.

The second element insulating layer 62 includes an insulator 62T in which a plurality of insulating films 62A are stacked in the Z direction. Therefore, the Z direction may be said to be a thickness direction of the second element insulating layer 62. Each insulating film 62A is, for example, an oxide film made of a material containing SiO₂. A thickness of each insulating film 62A is the same as, for example, the thickness of each insulating film 52A of the first element insulating layer 52 (see FIG. 5 for both). Also, the number of stacked insulating films 62A is not limited to the example shown in FIG. 7 and may be changed arbitrarily. The number of stacked insulating films 62A may be the same as, for example, the number of stacked insulating films 52A. Further, the number of stacked insulating films 62A may be more or less than, for example, the number of stacked insulating films 52A.

The second element insulating layer 62 includes a second protective film 63 and a second passivation film 64. The second protective film 63 is a film that protects the insulator 62T. A configuration of the second protective film 63 is the same as, for example, the configuration of the first protective film 53 of the first chip 50.

The second passivation film 64 is a surface protective film of the second chip 60. The second passivation film 64 is formed over the second protective film 63. The second passivation film 64 constitutes the second element front surface 62S of the second element insulating layer 62. A configuration of the second passivation film 64 is the same as, for example, the configuration of the first passivation film 54 (see FIG. 5) of the first chip 50.

As shown in FIG. 6, the plurality of second pads 65 are disposed at an end portion, which is closer to the chip side surface 60B, of both end portions of the chip front surface 60S in the X direction. Herein, the chip side surface 60B is a side surface of the second chip 60 that is closer to the plurality of second leads 92 (see FIG. 2).

The second chip 60 includes a plurality of intermediate pads 66 (two intermediate pads 66 in the first embodiment) that are electrically connected to the transformer chip 70. The plurality of intermediate pads 66 are arranged at a same position in the X direction and are spaced apart from each other in the Y direction. The plurality of intermediate pads 66 are disposed to be closer to the chip side surface 60A than, for example, the plurality of second pads 65 in the X direction. In one example, the plurality of intermediate pads 66 are provided at an end portion, which is closer to the transformer chip 70 (the first chip 50), of both end portions of the chip front surface 60S in the X direction. Each intermediate pad 66 is made of, for example, a material containing one or more appropriately selected from the group of Ti, TiN, Au, Ag, Cu, Al, and W.

The second circuit 30, a third connection wiring 67 that connects the second circuit 30 and the second pads 65, and a fourth connection wiring 68 that connects the second circuit 30 and the intermediate pads 66 are provided within the second chip 60. In other words, the second circuit 30 and the second pads 65 are electrically connected within the second chip 60. The second circuit 30 and the intermediate pads 66 are electrically connected within the second chip 60.

As shown in FIG. 7, the third connection wiring 67 includes a third circuit side connection portion 67A that is electrically connected to the receiving circuit 31, a third pad side connection portion 67B that is electrically connected to the second pads 65, and a third wiring 67C that connects the third circuit side connection portion 67A and the third pad side connection portion 67B.

The third circuit side connection portion 67A is configured, for example, by a via that penetrates a lowermost insulating film 62A of the insulator 62T in the Z direction. The third wiring 67C is a wiring layer formed over the lowermost insulating film 62A. For example, in a plan view, the third wiring 67C extends along the X direction from the third circuit side connection portion 67A toward the chip side surface 60B. The third pad side connection portion 67B includes a configuration in which a plurality of wiring layers and a plurality of vias are alternately stacked one by one in the Z direction. The third pad side connection portion 67B is provided at a position overlapping the second pads 65 in a plan view. Herein, the lowermost insulating film 62A is an insulating film that constitutes the second element back surface 62R of the second element insulating layer 62 and is in contact with the second semiconductor substrate 61.

The fourth connection wiring 68 includes a fourth circuit side connection portion 68A, a first intermediate wiring 68B, an intermediate connection portion 68C, a second intermediate wiring 68D, and a fourth pad side connection portion 68E. The fourth circuit side connection portion 68A is electrically connected to the receiving circuit 31. The fourth circuit side connection portion 68A is configured, for example, by a via that penetrates the lowermost insulating film 62A of the insulator 62T in the Z direction. In one example, the fourth circuit side connection portion 68A is disposed to be closer to the chip side surface 60A in the X direction than the third circuit side connection portion 67A of the third connection wiring 67. The first intermediate wiring 68B electrically connects the fourth circuit side connection portion 68A and the intermediate connection portion 68C. In a plan view, for example, the first intermediate wiring 68B extends along the X direction from the fourth circuit side connection portion 68A toward the chip side surface 60A. The first intermediate wiring 68B is formed over the lowermost insulating film 62A. That is, the first intermediate wiring 68B is disposed at a same position as the third wiring 67C of the third connection wiring 67 in the Z direction. The intermediate connection portion 68C is electrically connected to the second intermediate wiring 68D. The intermediate connection portion 68C is provided to be closer to the chip side surface 60A than the receiving circuit 31. The intermediate connection portion 68C includes a configuration in which a plurality of vias and a plurality of wiring layers are alternately stacked one by one. The second intermediate wiring 68D is electrically connected to the fourth pad side connection portion 68E. The second intermediate wiring 68D extends along the X direction from the fourth pad side connection portion 68E toward the chip side surface 60B in a plan view. The second intermediate wiring 68D is disposed between the first intermediate wiring 68B and the intermediate pads 66 in the Z direction. The fourth pad side connection portion 68E electrically connects the second intermediate wiring 68D and the intermediate pads 66. The fourth pad side connection portion 68E is disposed at a position overlapping the intermediate pads 66 in a plan view.

### Configuration of Transformer Chip

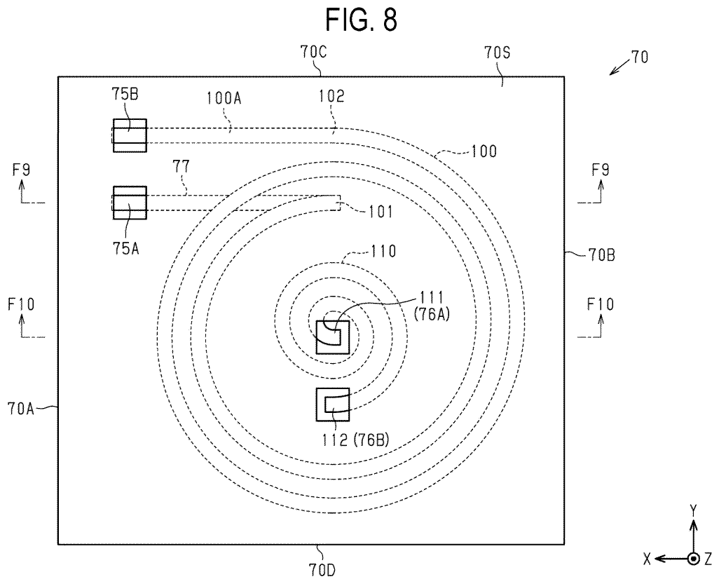

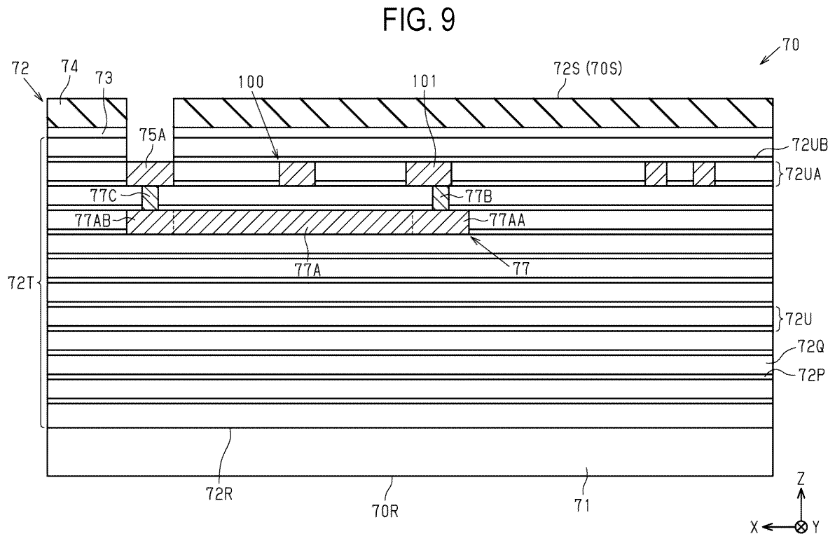

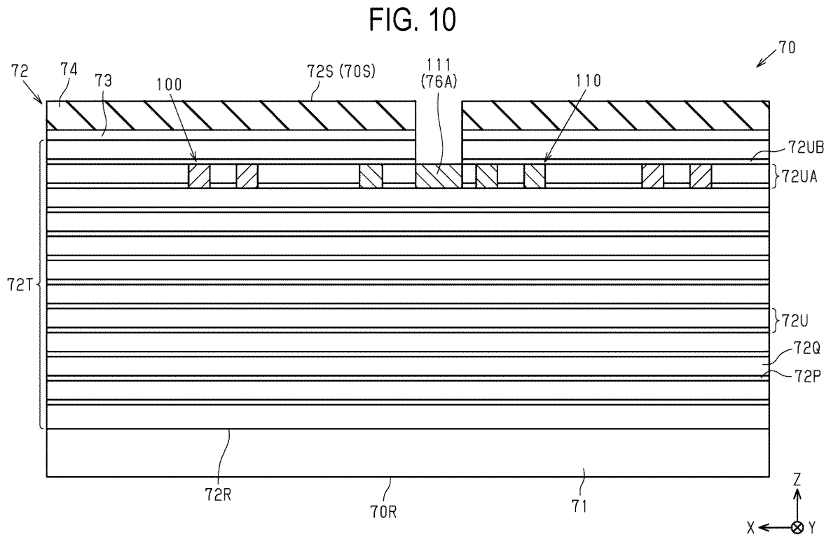

An example of the configuration of the transformer chip 70 is described with reference to FIG. 3 and FIGS. 8 to 10. FIG. 8 shows a schematic planar structure of the transformer chip 70. FIG. 9 shows a schematic cross-sectional structure of the transformer chip 70 taken along line F9-F9 in FIG. 8. FIG. 10 shows a schematic cross-sectional structure of the transformer chip 70 taken along line F10-F10 in FIG. 8.

As shown in FIGS. 8 to 10, the transformer chip 70 having a rectangular flat plate shape includes a chip front surface 70S and a chip back surface 70R (see FIG. 9) facing opposite sides to each other in the Z direction, and four chip side surfaces 70A to 70D connecting the chip front surface 70S and the chip back surface 70R. The chip front surface 70S of the transformer chip 70 faces a same side as the chip front surface 50S (see FIG. 3) of the first chip 50. The chip back surface 70R faces a same side as the chip back surface 50R (see FIG. 3). The chip side surfaces 70A and 70B constitute both end surfaces of the transformer chip 70 in the X direction, and the chip side surfaces 70C and 70D constitute both end surfaces of the transformer chip 70 in the Y direction. The chip side surface 70A faces a same side as the chip side surface 50A (see FIG. 3) of the first chip 50, and the chip side surface 70B faces a same side as the chip side surface 50B (see FIG. 3) of the first chip 50. The chip side surface 70C faces a same side as the chip side surface 50C (see FIG. 4) of the first chip 50, and the chip side surface 70D faces a same side as the chip side surface 50D (see FIG. 4) of the first chip 50.

As shown in FIG. 8, the transformer chip 70 includes first transformer pads 75A and 75B and second transformer pads 76A and 76B exposed from the chip front surface 70S in the Z direction. The first transformer pads 75A and 75B are pads electrically connected to the first chip 50 (see FIG. 3). The first transformer pads 75A and 75B are disposed near the chip side surface 70A and near the chip side surface 70C in a plan view. The first transformer pads 75A and 75B are arranged at a same position in the X direction and spaced apart from each other in the Y direction.

The second transformer pads 76A and 76B are pads electrically connected to the second chip 60 (see FIG. 3). The second transformer pads 76A and 76B are arranged in an approximate center in the X direction and near the chip side surface 70D in the Y direction in a plan view. The second transformer pads 76A and 76B are arranged at a same position in the X direction and spaced apart from each other in the Y direction.

As shown in FIG. 9, the transformer chip 70 includes a third semiconductor substrate 71 and a third element insulating layer 72 formed over the third semiconductor substrate 71. The third semiconductor substrate 71 constitutes the chip back surface 70R of the transformer chip 70. The third semiconductor substrate 71 is made of a material containing, for example, Si. In the first embodiment, the third semiconductor substrate 71 is a Si substrate. Further, a wide band gap semiconductor or a compound semiconductor may be used for the third semiconductor substrate 71.

A dimension (thickness) of the third semiconductor substrate 71 in the Z direction may be the same as, for example, a dimension (thickness) of the first semiconductor substrate 51 (see FIG. 5) in the Z direction. A dimension (thickness) of the third element insulating layer 72 in the Z direction may be larger than, for example, a dimension (thickness) of the first element insulating layer 52 (see FIG. 5) in the Z direction. Therefore, a dimension of the transformer chip 70 in the Z direction may be larger than a dimension of the first chip 50 in the Z direction.

Herein, the dimension of the third semiconductor substrate 71 in the Z direction may be changed arbitrarily. In one example, the dimension of the third semiconductor substrate 71 in the Z direction may be smaller than the dimension of the first semiconductor substrate 51 in the Z direction. Further, the dimension of the third element insulating layer 72 in the Z direction may be changed arbitrarily. In one example, the dimension of the third element insulating layer 72 in the Z direction may be equal to the dimension of the first element insulating layer 52 in the Z direction.

The third element insulating layer 72 includes a third element front surface 72S and a third element back surface 72R facing opposite sides to each other. The third element front surface 72S constitutes the chip front surface 70S of the transformer chip 70. The third element back surface 72R is in contact with the third semiconductor substrate 71.

The third element insulating layer 72 includes a plurality of first insulating films 72P and a plurality of second insulating films 72Q. In other words, the third element insulating layer 72 includes an insulating layer stack structure 72T, which is a stacked body of the plurality of first insulating films 72P and the plurality of second insulating films 72Q. The insulating layer stack structure 72T is configured by alternately stacking the plurality of first insulating films 72P and the plurality of second insulating films 72Q one by one in the Z direction. Herein, if a stacked body of one first insulating film 72P and one second insulating film 72Q is defined as an insulator 72U, the insulating layer stack structure 72T may be said to be a structure in which a plurality of insulators 72U are stacked. In this way, the Z direction may also be said to be a thickness direction of the third element insulating layer 72.

The first insulating film 72P is an etching stopper film and is made of, for example, a material containing at least one selected from the group of SiN, SiC, and SiCN (nitrogen-doped silicon carbide). The first insulating film 72P may also have a function of, for example, preventing the diffusion of Cu. In other words, the first insulating film 72P may be a Cu diffusion prevention film.

The second insulating film 72Q is an interlayer insulating film and is, for example, an oxide film made of a material containing SiO₂. The second insulating film 72Q has a thickness thicker than the first insulating film 72P. The first insulating film 72P has a thickness of, for example, 50 nm or more and less than 1,000 nm. The second insulating film 72Q has a thickness of, for example, 500 nm or more and 5,000 nm or less. In the first embodiment, the first insulating film 72P has a thickness of approximately 300 nm, and the second insulating film 72Q has a thickness of approximately 2,000 nm. In one example, both uppermost and lowermost insulating films of the insulating layer stack structure 72T are composed of the second insulating film 72Q. In order to facilitate understanding of the figure, a ratio of the film thickness of the first insulating film 72P to the film thickness of the second insulating film 72Q in the figure is different from an actual ratio of the film thickness of the first insulating film 72P to the film thickness of the second insulating film 72Q.

The third element insulating layer 72 includes a third protective film 73 and a third passivation film 74. The third protective film 73 is a film that protects the insulating layer stack structure 72T. The third protective film 73 is formed over the insulating layer stack structure 72T. The third protective film 73 is made of, for example, a material containing SiO₂. In one example, the third protective film 73 is formed over an entire surface of the insulating layer stack structure 72T in a plan view. Further, the material constituting the third protective film 73 may be changed arbitrarily. In one example, the third protective film 73 may be made of a material containing SiN.

The third passivation film 74 is a surface protective film of the transformer chip 70. The third passivation film 74 is formed over the third protective film 73. The third passivation film 74 constitutes the third element front surface 72S of the third element insulating layer 72. The third passivation film 74 is made of, for example, a material containing at least one selected from the group of PI, SiN, and SiO₂. In one example, the third passivation film 74 is made of a material containing SiO₂. In one example, the third passivation film 74 is formed over an entire surface of the third protective film 73 in a plan view. Also, the material constituting the third passivation film 74 may be changed arbitrarily. The third passivation film 74 may be made of a same material as the third protective film 73, or may be made of a material different from the third protective film 73.

As shown in FIG. 8, the transformer chip 70 includes an outer coil 100 and an inner coil 110. As shown in FIGS. 9 and 10, both the outer coil 100 and the inner coil 110 are embedded in the third element insulating layer 72. The outer coil 100 corresponds to the first coil 41 of the transformer 40 in FIG. 1, and the inner coil 110 corresponds to the second coil 42 of the transformer 40.

In one example, the outer coil 100 and the inner coil 110 are disposed at a same position in the Z direction. It may be said that the outer coil 100 and the inner coil 110 are disposed over a same plane orthogonal to the Z direction. Specifically, the outer coil 100 and the inner coil 110 are provided to penetrate a specific insulator 72UA which is one specific insulator 72U. In the example shown in FIGS. 9 and 10, the specific insulator 72UA is an insulator 72U immediately below an uppermost insulator 72U of the insulating layer stack structure 72T. In other words, the specific insulator 72UA is a second insulator 72U from the third element front surface 72S in the insulating layer stack structure 72T. That is, in the example shown in FIGS. 9 and 10, the outer coil 100 and the inner coil 110 are disposed to be closer to the third element front surface 72S than a center of the third element insulating layer 72 in the Z direction. Also, the specific insulator 72UA in the insulating layer stack structure 72T is arbitrary. In one example, the specific insulator 72UA may be the uppermost insulator 72U of the insulating layer stack structure 72T.

In a plan view, the inner coil 110 is disposed inside the outer coil 100. The inner coil 110 is disposed so as not to overlap the outer coil 100 in a plan view. In other words, the inner coil 110 is disposed to be spaced apart from the outer coil 100 in a direction orthogonal to the Z direction. Therefore, the specific insulator 72UA is disposed between the inner coil 110 and the outer coil 100 in the direction orthogonal to the Z direction. In this way, the outer coil 100 and the inner coil 110 are electrically insulated from each other and are configured to be magnetically coupled. In the transformer 40 of the first embodiment, the outer coil 100 and the inner coil 110 are configured to be capable of being magnetically coupled in the direction orthogonal to the Z direction. Therefore, a current flows in the inner coil 110 in a direction corresponding to a direction of a magnetic flux generated by a current flowing in the outer coil 100.

As shown in FIG. 8, the outer coil 100 includes a first end 101 and a second end 102 opposite to the first end 101. The outer coil 100 is formed in a circular spiral shape in a plan view. In the spiral-shaped outer coil 100, the first end 101 is disposed inside the spiral, and the second end 102 is disposed outside the spiral. That is, the outer coil 100 is wound in a spiral shape with the first end 101 as an inner peripheral end and the second end 102 as an outer peripheral end. The outer coil 100 includes a lead wire 100A extending along the X direction from the second end 102 toward the chip side surface 70A. The lead wire 100A is disposed at a same position as the outer coil 100 in the Z direction. In one example, the lead wire 100A is formed to be integrated with the outer coil 100.

A tip of the lead wire 100A constitutes the first transformer pad 75B. In one example, the third element insulating layer 72 is provided with a second outer opening that exposes the tip of the lead wire 100A in the Z direction. The tip of the lead wire 100A exposed by the second outer opening constitutes the first transformer pad 75B.

The inner coil 110, which is disposed inside the outer coil 100, includes a first end 111 and a second end 112 opposite to the first end 111. The inner coil 110 is formed in a circular spiral shape in a plan view. In the spiral-shaped inner coil 110, the first end 111 is disposed inside the spiral, and the second end 112 is disposed outside the spiral. That is, the inner coil 110 is wound in a spiral shape with the first end 111 as an inner peripheral end and the second end 112 as an outer peripheral end.

The first end 111 constitutes the second transformer pad 76A, and the second end 112 constitutes the second transformer pad 76B. In one example, the third element insulating layer 72 is provided with a first inner opening that exposes the first end 111 in the Z direction, and a second inner opening that exposes the second end 112 in the Z direction. The first end 111 exposed by the first inner opening constitutes the second transformer pad 76A, and the second end 112 exposed by the second inner opening constitutes the second transformer pad 76B.

Both the outer coil 100 and the inner coil 110 are made of a material containing one or more appropriately selected from the group of Ti (titanium), TiN (titanium nitride), Au, Ag, Cu, Al, and W (tungsten). In one example, the outer coil 100 and the inner coil 110 may be made of a same material. In one example, the outer coil 100 and the inner coil 110 may be made of a material containing Cu.

As shown in FIG. 8, the transformer chip 70 includes a wiring portion 77 that electrically connects the first end 101 of the outer coil 100 and the first transformer pad 75A. The wiring portion 77 is made of, for example, a material containing one or more appropriately selected from the group of Ti, TiN, Au, Ag, Cu, Al, and W.

As shown in FIG. 9, the wiring portion 77 includes a connection wiring 77A and vias 77B and 77C. The connection wiring 77A is disposed to be closer to the third semiconductor substrate 71 than the outer coil 100 is disposed in the Z direction. The connection wiring 77A extends along the X direction from the first end 101 of the outer coil 100 toward the chip side surface 70A in a plan view. The connection wiring 77A includes a first end 77AA and a second end 77AB which are both ends in the X direction. The first end 77AA of the connection wiring 77A is electrically connected to the first end 101 of the outer coil 100 by the via 77B. The second end 77AB of the connection wiring 77A is electrically connected to the first transformer pad 75A by the via 77C. The first transformer pad 75A is exposed in the Z direction by a first outer opening provided in the third element insulating layer 72.

Configuration of State in Which Transformer Chip is Disposed over First Chip

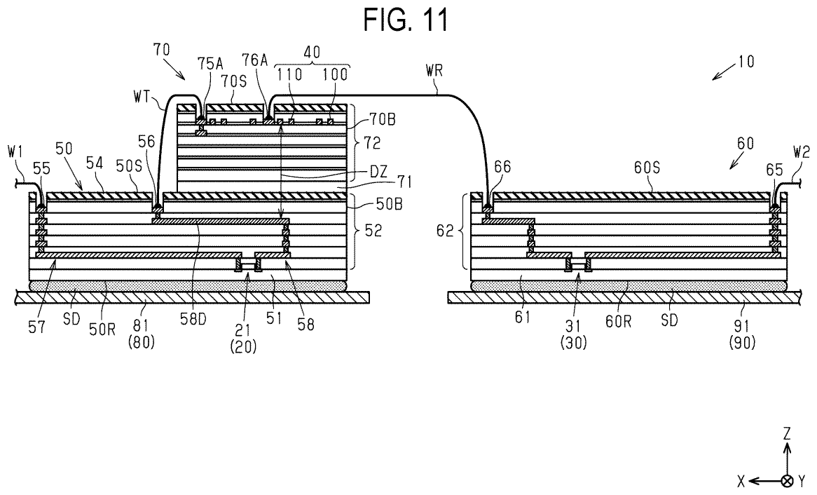

A configuration of a state in which the transformer chip 70 is disposed over the first chip 50 (hereinafter, a “chip disposition state”) is described with reference to FIGS. 2 and 11. FIG. 11 is an enlarged view of the first chip 50, the second chip 60, the transformer chip 70, and peripheries of these chips in FIG. 3. In FIG. 11, the sealing resin 200 is omitted in order to facilitate understanding of the figure.

As shown in FIG. 2, the transformer chip 70 is smaller than the first chip 50 in a plan view. In one example, a dimension of the transformer chip 70 in the X direction is smaller than a dimension of the first chip 50 in the X direction. The dimension of the transformer chip 70 in the Y direction is smaller than the dimension of the first chip 50 in the Y direction. The transformer chip 70 is disposed to be biased toward the chip side surface 50B with respect to the first chip 50 in the X direction. The transformer chip 70 is disposed to be closer to the chip side surface 50B than the intermediate pads 56 of the first chip 50. In one example, the transformer chip 70 is disposed over the first chip 50 so that the chip side surface 70B of the transformer chip 70 and the chip side surface 50B of the first chip 50 are in a same position in a plan view.

In one example, in the chip disposition state, the first transformer pads 75A and 75B and two intermediate pads 56 of the first chip 50 are in a same position in the Y direction. In one example, in the chip disposition state, the second transformer pads 76A and 76B and two intermediate pads 66 of the second chip 60 are in a same position in the Y direction.

Further, in the chip disposition state, the first transformer pads 75A and 75B may be disposed to be shifted toward the sealing side surface 203 or the sealing side surface 204 of the sealing resin 200 with respect to the two intermediate pads 56. Further, in the chip disposition state, the second transformer pads 76A and 76B may be disposed to be shifted toward the sealing side surface 203 or the sealing side surface 204 with respect to the two intermediate pads 66.

As shown in FIG. 11, in the chip disposition state, the transformer chip 70 is disposed over the first chip 50 so that the third semiconductor substrate 71 is closer to the first chip 50 with respect to the third element insulating layer 72. In other words, in the chip disposition state, the third semiconductor substrate 71 is interposed between the third element insulating layer 72 and the first chip 50. The third semiconductor substrate 71 is in contact with the first element insulating layer 52 of the first chip 50. In the first embodiment, the third semiconductor substrate 71 is in contact with the first element insulating layer 52 but is not bonded thereto.

The first transformer pads 75A and 75B and the two intermediate pads 56 of the first chip 50 are individually connected by two transmitting side wires WT. The first transformer pads 75A and 75B are electrically connected to the outer coil 100, and one of the two intermediate pads 56 is electrically connected to the transmitting circuit 21, so that, for example, the first end 101 of the outer coil 100 is electrically connected to the transmitting circuit 21. The other of the two intermediate pads 56 is connected to the ground GND1 (see FIG. 1). Therefore, for example, the second end 102 of the outer coil 100 is electrically connected to the ground GND1. In one example, lengths of the two transmitting side wires WT are equal to each other in a plan view.

The second transformer pads 76A and 76B and the two intermediate pads 66 of the second chip 60 are individually connected by two receiving side wires WR. The second transformer pads 76A and 76B are electrically connected to the inner coil 110, and one of the two intermediate pads 66 is electrically connected to the receiving circuit 31, so that, for example, the first end 111 of the inner coil 110 is electrically connected to the receiving circuit 31. The other of the two intermediate pads 66 is connected to the ground GND2 (see FIG. 1). Therefore, for example, the second end 112 of the inner coil 110 is electrically connected to the ground GND2. In one example, lengths of the two receiving side wires WR are equal to each other in a plan view.

The dielectric breakdown voltage of the semiconductor device 10 is determined by, for example, a distance DZ between the second intermediate wiring 58D of the second connection wiring 58 of the first chip 50 and the inner coil 110 of the transformer chip 70 in the Z direction. Herein, although different from FIG. 11, a distance between the inner coil 110 and the outer coil 100 in a plane direction orthogonal to the Z direction is equal to or larger than the distance DZ.

### Method of Manufacturing Semiconductor Device

Next, an example of a method of manufacturing the semiconductor device 10 according to the first embodiment is described. In the following description, reference numerals related to the components of the semiconductor device 10 are referred from FIGS. 1 to 11.

The method of manufacturing the semiconductor device 10 includes a step of preparing the first chip 50, a step of preparing the second chip 60, a step of preparing the transformer chip 70, and a step of preparing the first lead frame 80 and the second lead frame 90.

The step of preparing the first chip 50 includes a step of forming the first element insulating layer 52, the plurality of first pads 55, the plurality of intermediate pads 56, the first connection wiring 57, and the second connection wiring 58 over the first semiconductor substrate 51 at which the first circuit 20 is formed. The plurality of first pads 55, the plurality of intermediate pads 56, the first connection wiring 57, and the second connection wiring 58 are formed by etching and sputtering, using a metal mask, in a process of stacking the insulating films 52A of the first element insulating layer 52.

The step of preparing the second chip 60 includes a step of forming the second element insulating layer 62, the plurality of second pads 65, the plurality of intermediate pads 66, the third connection wiring 67, and the fourth connection wiring 68 over the second semiconductor substrate 61 at which the second circuit 30 is formed. The plurality of second pads 65, the plurality of intermediate pads 66, the third connection wiring 67, and the fourth connection wiring 68 are formed by etching and sputtering, using a metal mask, in a process of stacking the insulating film 62A of the second element insulating layer 62.

The step of preparing the transformer chip 70 includes a step of forming the third element insulating layer 72, the outer coil 100, the inner coil 110, the first transformer pads 75A and 75B, the second transformer pads 76A and 76B, and the wiring portion 77 over the third semiconductor substrate 71. The outer coil 100, the inner coil 110, the first transformer pads 75A and 75B, the second transformer pads 76A and 76B, and the wiring portion 77 are formed by etching and sputtering, using a metal mask, in a process of stacking the first insulating film 72P and the second insulating film 72Q of the third element insulating layer 72.

The method of manufacturing the semiconductor device 10 includes a step of mounting the first chip 50 on the first die pad 81 of the first lead frame 80, and a step of mounting the second chip 60 on the second die pad 91 of the second lead frame 90.

In the step of mounting the first chip 50 on the first die pad 81, first, a conductive bonding material SD is applied to the first die pad 81. Then, the first chip 50 is disposed over the conductive bonding material SD. Then, the first chip 50 is bonded to the first die pad 81 by melting and solidifying the conductive bonding material SD.

In the step of mounting the second chip 60 on the second die pad 91, first, a conductive bonding material SD is applied to the second die pad 91. Then, the second chip 60 is disposed over the conductive bonding material SD. Then, the second chip 60 is bonded to the second die pad 91 by melting and solidifying the conductive bonding material SD. Herein, the conductive bonding material SD applied to the first die pad 81 and the conductive bonding material SD applied to the second die pad 91 may be melted and solidified at the same time.

The method of manufacturing the semiconductor device 10 includes a step of forming the plurality of wires W1 and the plurality of wires W2. The plurality of wires WI are formed using a wire bonding device to individually connect the plurality of first pads 55 of the first chip 50 to the plurality of first leads 82 of the first lead frame 80. The plurality of wires W2 are formed using a wire bonding device to individually connect the plurality of second pads 65 of the second chip 60 to the plurality of second leads 92 of the second lead frame 90.

The method of manufacturing the semiconductor device 10 includes a step of disposing the transformer chip 70 over the first chip 50. By disposing the transformer chip 70 over the first chip 50, the third semiconductor substrate 71 of the transformer chip 70 contacts the first element insulating layer 52 of the first chip 50.

The method of manufacturing the semiconductor device 10 includes a step of forming the plurality of transmitting side wires WT and the plurality of receiving side wires WR. The plurality of transmitting side wires WT are formed using a wire bonding device to individually connect the first transformer pads 75A and 75B to the two intermediate pads 56 of the first chip 50. The plurality of receiving side wires WR are formed using a wire bonding device to individually connect the second transformer pads 76A and 76B to the two intermediate pads 66 of the second chip 60.

The method of manufacturing the semiconductor device 10 includes a step of forming the sealing resin 200. In this step, the sealing resin 200 is formed by, for example, transfer molding. As a result, the sealing resin 200 seals the first chip 50, the second chip 60, the transformer chip 70, the first die pad 81, the second die pad 91, the plurality of wires W1 and W2, the plurality of transmitting side wires WT, and the plurality of receiving side wires WR. Through the above steps, the semiconductor device 10 is manufactured.

Additionally, in the method of manufacturing the semiconductor device 10, the order of the step of forming the plurality of wires W1 and W2 may be changed arbitrarily. In one example, the step of forming the plurality of wires W1 and W2 may be performed simultaneously with the step of forming the plurality of transmitting side wires WT and the plurality of receiving side wires WR. In other words, in the chip disposition state, the plurality of wires W1 and W2, the plurality of transmitting side wires WT, and the plurality of receiving side wires WR may be continuously formed by a wire bonding device.

### Operation of First Embodiment

An operation of the semiconductor device 10 according to the first embodiment is described. In the following description, a transformer chip in which two coils are disposed to face each other in the Z direction in the third element insulating layer 72 is referred to as a “transformer chip of a comparative example.” The transformer chip of the comparative example is bonded to the first die pad 81 by a conductive bonding material SD, not on the first chip 50.

In the transformer chip of the comparative example, a dielectric breakdown voltage of a semiconductor device is determined based on a distance between the two coils disposed to face each other in the Z direction. Therefore, in order to improve the dielectric breakdown voltage of the semiconductor device, it is needed to increase the distance between the two coils disposed to face each other in the Z direction by increasing the thickness of the third element insulating layer 72. However, if the thickness of the third element insulating layer 72 is increased, the third semiconductor substrate 71 becomes more likely to warp during the manufacture of the transformer chip of the comparative example. The thicker the third element insulating layer 72, the greater the warping that occurs in the third semiconductor substrate 71.

In the first embodiment, as the transformer chip 70 is disposed over the first chip 50, the dielectric breakdown voltage of the semiconductor device 10 is determined based on the distance DZ between the second intermediate wiring 58D of the second connection wiring 58 in the first chip 50 and the inner coil 110 of the transformer chip 70 in the Z direction. In other words, the dielectric breakdown voltage of the semiconductor device 10 is determined not only by the thickness of the third element insulating layer 72, but also by a distance between the second intermediate wiring 58D of the first chip 50 and the chip front surface 50S, and the thickness of the third semiconductor substrate 71. Therefore, in the first embodiment, the dielectric breakdown voltage of the semiconductor device 10 may be improved without increasing the thickness of the third element insulating layer 72.

In addition, the inner coil 110 and the outer coil 100 are disposed to face each other in the direction orthogonal to the Z direction. Therefore, by increasing a size of the transformer chip 70 in the X direction and the Y direction, the distance between the inner coil 110 and the outer coil 100 in the direction orthogonal to the Z direction may be made equal to or larger than the distance DZ. In other words, the distance between the inner coil 110 and the outer coil 100 in the direction orthogonal to the Z direction may be made equal to or larger than the distance DZ without increasing the thickness of the third element insulating layer 72. Therefore, it is possible to improve the dielectric breakdown voltage of the semiconductor device 10.

Further, wiring resistance values of the outer coil 100 and the inner coil 110 affect an amount of current flowing through the outer coil 100 and the inner coil 110, respectively, and a degree of magnetic coupling. The wiring resistance value of the outer coil 100 may be reduced by widening a wiring width of the outer coil 100 and reducing an aspect ratio of a wiring thickness to the wiring width. Similarly, the wiring resistance value of the inner coil 110 may be reduced by widening a wiring width of the inner coil 110 and reducing an aspect ratio of a wiring thickness to the wiring width.

Herein, in the transformer chip of the comparative example, since the two coils are disposed to face each other in the Z direction, if the wiring widths of these coils are increased, a facing area between the two coils increases, which increases a capacitance value of a parasitic capacitor.

In the first embodiment, the outer coil 100 and the inner coil 110 face each other in the direction orthogonal to the Z direction. Therefore, even if the wiring width of each of the outer coil 100 and the inner coil 110 is increased, the facing area between the outer coil 100 and the inner coil 110 does not change. In other words, the capacitance value of the parasitic capacitor between the outer coil 100 and the inner coil 110 does not change. That is, as compared to the transformer chip of the comparative example, the wiring resistance value of each coil may be reduced without increasing the capacitance value of the parasitic capacitor between the coils. As a result, a current flows more easily in the outer coil 100 and the inner coil 110, so that an amount of magnetic flux generated in the transformer 40 may be increased. This may improve efficiency of the magnetic coupling between the outer coil 100 and the inner coil 110 and thus improve transmission characteristics.

### Effects of First Embodiment

The semiconductor device 10 according to the first embodiment provides the following effects.
(1-1) The semiconductor device 10 includes the first chip 50 including the first circuit 20, the second chip 60 disposed to be spaced apart from the first chip 50 in the X direction and including the second circuit 30, and the transformer chip 70 disposed over the first chip 50 and including the transformer 40. The first circuit 20 and the second circuit 30 are configured to transmit signals via the transformer 40. The transformer chip 70 includes the third element insulating layer 72 and the outer coil 100 and the inner coil 110 disposed as the transformer 40 in the third element insulating layer 72. In a plan view, the inner coil 110 is disposed inside the outer coil 100 so as not to overlap with the outer coil 100.

With this configuration, as the transformer chip 70 is disposed over the first chip 50, a distance between the transformer 40 in the transformer chip 70 and the first circuit 20, which contributes to the dielectric breakdown voltage of the semiconductor device 10, may be increased. Further, since the inner coil 110 and the outer coil 100 are disposed to be spaced apart from each other in the direction orthogonal to the Z direction, the distance between the inner coil 110 and the outer coil 100, which contributes to the dielectric breakdown voltage of the semiconductor device 10, may be increased without increasing the thickness of the third element insulating layer 72. In other words, the distance between the inner coil 110 and the outer coil 100 may be increased by increasing a size of the third element insulating layer 72 in the direction orthogonal to the Z direction. Therefore, the dielectric breakdown voltage of the semiconductor device 10 may be improved without increasing the thickness of the third element insulating layer 72.
(1-2) The transformer chip 70 includes the third semiconductor substrate 71 that contacts the third element insulating layer 72. In the chip disposition state in which the transformer chip 70 is disposed over the first chip 50, the third semiconductor substrate 71 is interposed between the third element insulating layer 72 and the first chip 50.

With this configuration, the distance between the transformer 40 in the transformer chip 70 and the first circuit 20, which contributes to the dielectric breakdown voltage of the semiconductor device 10, may be increased by the thickness of the third semiconductor substrate 71. Therefore, the dielectric breakdown voltage of the semiconductor device 10 may be improved.
(1-3) The third element insulating layer 72 includes the third element front surface 72S and the third element back surface 72R opposite to the third element front surface 72S. The outer coil 100 is electrically connected to the first circuit 20. The inner coil 110 is disposed to be closer to the third element front surface 72S than the third element back surface 72R in the third element insulating layer 72.

With this configuration, as the transformer chip 70 is disposed over the first chip 50, the distance between the inner coil 110 in the transformer chip 70 and the first circuit 20, which contributes to the dielectric breakdown voltage of the semiconductor device 10, may be increased. Therefore, the dielectric breakdown voltage of the semiconductor device 10 may be improved.
(1-4) The first circuit 20 includes the transmitting circuit 21. The second circuit 30 includes the receiving circuit 31. The outer coil 100 and the transmitting circuit 21 are electrically connected via the transmitting side wire WT. The inner coil 110 and the receiving circuit 31 are electrically connected via the receiving side wire WR. The length of the transmitting side wire WT is shorter than the length of the receiving side wire WR.

With this configuration, by lengthening the length of the receiving side wire WR which has a greater influence on the transfer characteristics than the transmitting side wire WT, the transfer characteristics of the semiconductor device 10 may be improved as compared to when the length of the transmitting side wire WT is longer than the receiving side wire WR.

In addition, since the outer coil 100 and the transmitting circuit 21 are connected by the transmitting side wire WT, the connection structure between the outer coil 100 and the transmitting circuit 21 may be simplified as compared to, for example, a configuration in which the outer coil 100 and the transmitting circuit 21 are connected by a wiring provided in the transformer chip 70 and a wiring provided in the first chip 50. In addition, since there is no need to determine a disposition position of the transformer chip 70 relative to the first chip 50 with high precision, the semiconductor device 10 may be easily manufactured.
(1-5) The inner coil 110 and the outer coil 100 are disposed at a same position in the Z direction. With this configuration, the inner coil 110 and the outer coil 100 may be formed by using a common mask when manufacturing the transformer chip 70. Therefore, as compared to a configuration in which the inner coil 110 and the outer coil 100 are disposed at different positions in the Z direction, a process of manufacturing the transformer chip 70 may be simplified, and thus a manufacturing cost of the transformer chip 70 may be reduced.
(1-6) The transformer chip 70 is smaller than the first chip 50 in a plan view. The transformer chip 70 is disposed to be biased toward the second chip 60 with respect to the first chip 50 in the X direction.

With this configuration, a distance between the transformer chip 70 and the second chip 60 in the X direction is reduced in a plan view. Therefore, the length of the receiving side wire WR connecting the transformer chip 70 and the second chip 60 may be shortened.
(1-7) The transformer chip 70 includes the chip side surfaces 70A and 70B which are both end surfaces in the X direction. The first chip 50 includes the chip side surfaces 50A and 50B which are both end surfaces in the X direction. The chip side surface 70A faces a same side as the chip side surface 50A, and the chip side surface 70B faces a same side as the chip side surface 50B. The chip side surfaces 70B and 50B are chip side surfaces closer to the second chip 60. The transformer chip 70 is disposed over the first chip 50 so that the chip side surface 70B is at a same position as the chip side surface 50B of the first chip 50 in a plan view.

With this configuration, the distance between the transformer chip 70 and the second chip 60 in the X direction is further reduced in a plan view. Therefore, the length of the receiving side wire WR connecting the transformer chip 70 and the second chip 60 may be further shortened.
(1-8) Both the inner coil 110 and the outer coil 100 are disposed to be closer to the third element front surface 72S of the third element insulating layer 72 in the Z direction. With this configuration, a distance in the Z direction between the outer coil 100/the inner coil 110 and the third semiconductor substrate 71 may be increased as compared to a configuration in which two coils are disposed to face each other in the Z direction. This makes it difficult for the magnetic flux generated in the outer coil 100 and the inner coil 110 to pass through the third semiconductor substrate 71. Therefore, it is possible to suppress the generation of an eddy current caused by the magnetic flux penetrating the third semiconductor substrate 71. This makes it possible to suppress a decrease in the efficiency of magnetic coupling caused by the eddy current.

### Second Embodiment

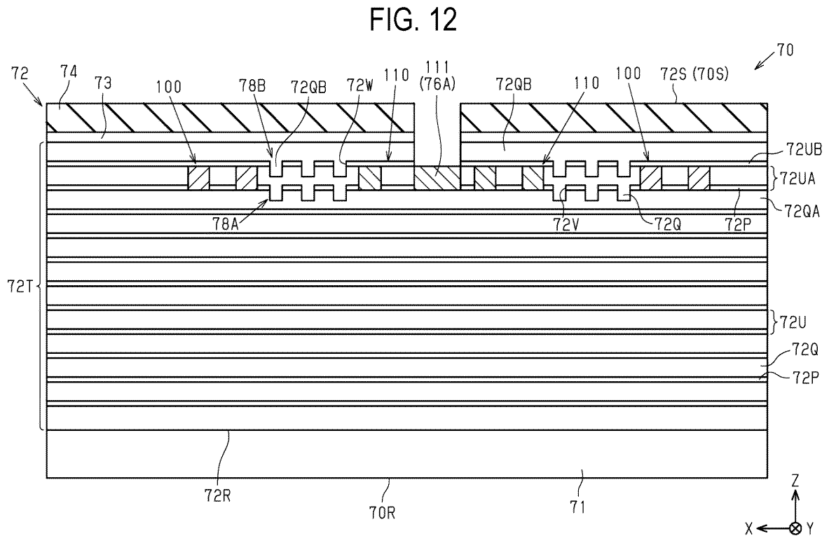

A semiconductor device 10 according to a second embodiment is described with reference to FIG. 12. The semiconductor device 10 according to the second embodiment is mainly different from the semiconductor device 10 according to the first embodiment in terms of the configuration of the third element insulating layer 72 of the transformer chip 70. Hereinafter, differences from the first embodiment are described in detail, and the same constituent elements as those in the first embodiment are denoted by the same reference numerals and explanation thereof are omitted.

FIG. 12 shows a cross-sectional structure of a specific insulator 72UA and its periphery in the third element insulating layer 72 of the transformer chip 70. The cross-sectional position in FIG. 12 is the same as the cross-sectional position in FIG. 10 of the first embodiment.

As shown in FIG. 12, the third element insulating layer 72 of the transformer chip 70 includes a specific insulator 72UA at which the outer coil 100 and the inner coil 110 are provided, and a cover insulating film 72UB that covers the outer coil 100 and the inner coil 110 from the Z direction.

The cover insulating film 72UB includes a first insulating film 72P. The cover insulating film 72UB is in contact with a second insulating film 72Q of the specific insulator 72UA. In one example, the cover insulating film 72UB is in contact with the outer coil 100 and the inner coil 110.

The third element insulating layer 72 includes a plurality of isolation insulating films 78A and a plurality of cover side isolation insulating films 78B. Herein, the second insulating film 72Q immediately below the specific insulator 72UA is referred to as a “second insulating film 72QA,” and the second insulating film 72Q formed over the cover insulating film 72UB is referred to as a “second insulating film 72QB.”

In a direction orthogonal to the Z direction, a plurality of grooves 72V are formed at the first insulating film 72P of the specific insulator 72UA between the outer coil 100 and the inner coil 110. In the second embodiment, each groove 72V is a rectangular groove that penetrates the first insulating film 72P of the specific insulator 72UA in the Z direction and forms a concave shape in the second insulating film 72QA. Each groove 72V is formed in an annular shape in a plan view. In one example, the plurality of grooves 72V are formed in a concentric shape in a plan view. In one example, centers of the plurality of grooves 72V are concentric with centers of the outer coil 100 and the inner coil 110. In this way, the plurality of grooves 72V allow the first insulating films 72P of the specific insulator 72UA to be spaced apart from each other in the direction orthogonal to the Z direction between the outer coil 100 and the inner coil 110.

The second insulating film 72Q of the specific insulator 72UA is embedded in the plurality of grooves 72V. This forms the plurality of isolation insulating films 78A. That is, each isolation insulating film 78A is formed of the second insulating film 72Q containing SiO₂. In this way, between the outer coil 100 and the inner coil 110, the first insulating film 72P made of SiN is isolated by the isolation insulating film 78A made of SiO₂. That is, the first insulating film 72P between the outer coil 100 and the inner coil 110 is isolated by the second insulating film 72Q (the isolation insulating film 78A) having a smaller dielectric constant than the first insulating film 72P. The first insulating film 72P between the outer coil 100 and the inner coil 110 is provided in plural to be spaced apart from each other in a plane direction orthogonal to the Z direction. The isolation insulating films 78A (the second insulating films 72Q) are interposed among the plurality of first insulating films 72P. Since each groove 72V is formed in an annular shape, each isolation insulating film 78A provided in each groove 72V is formed in an annular shape in a plan view. When the plurality of grooves 72V are formed in a concentric shape in a plan view, the plurality of isolation insulating films 78A are formed in a concentric shape in a plan view. In this way, the first insulating films 72P and the second insulating films 72Q are alternately disposed between the outer coil 100 and the inner coil 110 in the direction orthogonal to the Z direction.

In the plane direction orthogonal to the Z direction, a plurality of grooves 72W are formed at the cover insulating film 72UB between the outer coil 100 and the inner coil 110. In the second embodiment, each groove 72W is a rectangular groove that penetrates the cover insulating film 72UB in the Z direction and forms a concave shape in the second insulating film 72Q of the specific insulator 72UA. Each groove 72W is formed in an annular shape in a plan view. In one example, the plurality of grooves 72W are formed in a concentric shape in a plan view. In one example, centers of the plurality of grooves 72W are concentric with the centers of the outer coil 100 and the inner coil 110. In this way, the plurality of grooves 72W allow the cover insulating films 72UB to be spaced apart from each other in the direction orthogonal to the Z direction between the outer coil 100 and the inner coil 110.

In one example, a width dimension of each groove 72W is equal to a width dimension of each groove 72V. Further, the width dimensions of the plurality of grooves 72W are equal to each other. Further, the width dimensions of the plurality of grooves 72V are equal to each other. Herein, the width dimension of each of the grooves 72V and 72W may be defined by a distance between side surfaces constituting each of the grooves 72V and 72W in the direction orthogonal to the Z direction.

The second insulating film 72QB is embedded in the plurality of grooves 72W. This forms the plurality of cover side isolation insulating films 78B. In other words, each cover side isolation insulating film 78B is formed by the second insulating film 72QB containing SiO₂. In this way, between the outer coil 100 and the inner coil 110, the cover insulating film 72UB made of SiN is isolated by the cover side isolation insulating film 78B made of SiO₂. That is, the cover insulating film 72UB between the outer coil 100 and the inner coil 110 is isolated by the second insulating film 72Q (the cover side isolation insulating film 78B) having a smaller dielectric constant than the cover insulating film 72UB. The cover insulating film 72UB between the outer coil 100 and the inner coil 110 is provided in plural to be spaced apart from each other in the plane direction orthogonal to the Z direction. The cover side isolation insulating films 78B (the second insulating films 72QB) are interposed among the plurality of cover insulating films 72UB. Since each groove 72W is formed in an annular shape, each cover side isolation insulating film 78B provided in each groove 72W is formed in an annular shape in a plan view. When the plurality of grooves 72W are formed in a concentric shape in a plan view, the plurality of cover side isolation insulating films 78B are formed in a concentric shape in a plan view. In this way, the cover insulating films 72UB (the first insulating films 72P) and the cover side isolation insulating films 78B (the second insulating films 72Q) are alternately disposed between the outer coil 100 and the inner coil 110 among the cover insulating film 72UB in the direction orthogonal to the Z direction.

When the width dimension of each groove 72W is equal to the width dimension of each groove 72V, a width dimension of each cover side isolation insulating film 78B is equal to a width dimension of each isolation insulating film 78A. Further, when the width dimensions of the plurality of grooves 72W are equal to each other, the width dimensions of the plurality of cover side isolation insulating films 78B are equal to each other. Further, when the width dimensions of the plurality of grooves 72V are equal to each other, the width dimensions of the plurality of isolation insulating films 78A are equal to each other. Herein, the width dimension of the isolation insulating film 78A may be defined by a distance between side surfaces of the isolation insulating film 78A that contact the side surfaces constituting the grooves 72V in the direction orthogonal to the Z direction. Also, the width dimension of the cover side isolation insulating film 78B may be defined by a distance between side surfaces of the cover side isolation insulating film 78B that contact the side surfaces constituting the groove 72W in the direction orthogonal to the Z direction.

In addition, the number of grooves 72V and 72W may be changed arbitrarily. In the second embodiment, the grooves 72V and 72W are disposed at positions overlapping each other in a plan view, but are not limited thereto. The grooves 72V and 72W may be disposed at positions different from each other in a plan view. In other words, the number of isolation insulating films 78A and the number of cover side isolation insulating films 78B may be changed arbitrarily. In the second embodiment, the isolation insulating film 78A and the cover side isolation insulating film 78B are disposed at positions overlapping each other in a plan view, but are not limited thereto. The isolation insulating film 78A and the cover side isolation insulating film 78B may be disposed at positions different from each other in a plan view.

Further, the width dimensions of the grooves 72V and 72W may be changed arbitrarily. In one example, the width dimension of the groove 72V and the width dimension of the groove 72W may be different from each other. That is, the width dimension of the isolation insulating film 78A and the width dimension of the cover side isolation insulating film 78B may be different from each other. In one example, the width dimension of at least one selected from the group of the plurality of grooves 72V may be different from the width dimensions of the remaining grooves 72V. That is, the width dimension of at least one selected from the group of the plurality of isolation insulating films 78A may be different from the width dimensions of the remaining isolation insulating films 78A. In one example, the width dimension of at least one selected from the group of the plurality of grooves 72W may be different from the width dimensions of the remaining grooves 72W. That is, the width dimension of at least one selected from the group of the plurality of cover side isolation insulating films 78B may be different from the width dimensions of the remaining cover side isolation insulating films 78B. Additionally, shapes of the grooves 72V and 72W are not limited to a rectangular concave shape and may be changed arbitrarily. In one example, the grooves 72V and 72W may be V-shaped.

### Effects of Second Embodiment

The semiconductor device 10 according to the second embodiment provides the following effects.
(2-1) The third element insulating layer 72 includes the insulating layer stack structure 72T in which the plurality of insulators 72U are stacked, each of which includes the first insulating film 72P containing silicon nitride and the second insulating film 72Q containing silicon oxide stacked over the first insulating film 72P. The inner coil 110 and the outer coil 100 are provided so as to penetrate the specific insulator 72UA which is one specific insulator 72U. The third element insulating layer 72 includes the cover insulating film 72UB which is constituted by the first insulating film 72P and contacts the second insulating film 72Q of the specific insulator 72UA so as to cover the inner coil 110 and the outer coil 100. A portion of the first insulating film 72P of the specific insulator 72UA between the inner coil 110 and the outer coil 100 includes the plurality of isolation insulating films 78A that are provided to be spaced apart from each other in the direction orthogonal to the Z direction. A portion of the cover insulating film 72UB between the inner coil 110 and the outer coil 100 includes the plurality of cover side isolation insulating films 78B that are provided to be spaced apart from each other in the direction orthogonal to the Z direction. Each of the plurality of isolation insulating films 78A and cover side isolation insulating films 78B is constituted by the second insulating film 72Q.

With this configuration, the plurality of isolation insulating films 78A and second insulating films 72Q are alternately disposed in the portion of the first insulating film 72P of the specific insulator 72UA between the inner coil 110 and the outer coil 100. Therefore, a creepage distance between the inner coil 110 and the outer coil 100 may be increased. Further, the plurality of cover side isolation insulating films 78B and second insulating films 72Q are alternately disposed in the portion of the cover insulating film 72UB between the inner coil 110 and the outer coil 100. Therefore, the creepage distance between the inner coil 110 and the outer coil 100 may be increased. Therefore, it is possible to improve the dielectric breakdown voltage of the semiconductor device 10 while suppressing the increase in size of the transformer chip 70.
(2-2) Each of the plurality of isolation insulating films 78A and cover side isolation insulating films 78B is formed in an annular shape. With this configuration, the second insulating films 72Q interposed among the plurality of isolation insulating films 78A are formed in an annular shape, and the second insulating films 72Q interposed among the plurality of cover side isolation insulating films 78B are formed in an annular shape. Therefore, in the portion between the inner coil 110 and the outer coil 100, the insulation distance (creepage distance) between the inner coil 110 and the outer coil 100 may be increased over an entire circumference of the inner coil 110.

### Third Embodiment

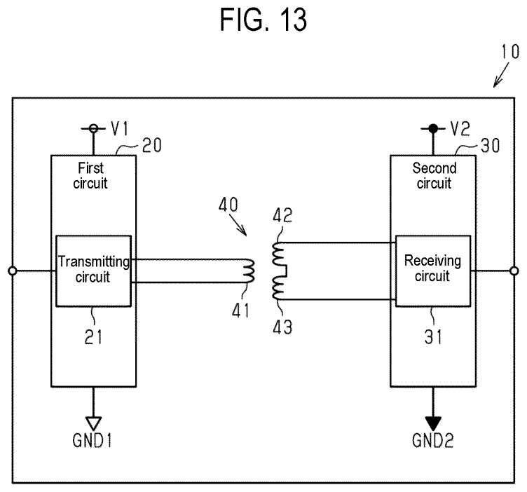

A semiconductor device 10 according to a third embodiment is described with reference to FIGS. 13 to 17. The semiconductor device 10 according to the third embodiment is mainly different from the semiconductor device 10 according to the first embodiment in terms of the configuration of the transformer chip 70. Hereinafter, differences from the first embodiment are described in detail, and the same constituent elements as those in the first embodiment are denoted by the same reference numerals and explanation thereof is omitted.

### Circuit Configuration of Semiconductor Device

FIG. 13 shows a schematic circuit configuration of the semiconductor device 10 according to the third embodiment. As shown in FIG. 13, in the semiconductor device 10, the transformer 40 provided between the transmitting circuit 21 of the first circuit 20 and the receiving circuit 31 of the second circuit 30 includes first to third coils 41 to 43. The first coil 41 is electrically connected to the transmitting circuit 21, as in the first embodiment. The second coil 42 and the third coil 43 are electrically connected to each other. The second coil 42 and the third coil 43 are electrically connected to the receiving circuit 31. The first coil 41, the second coil 42, and the third coil 43 are electrically insulated from each other and are configured to be magnetically coupled.

### Configuration of Semiconductor Device

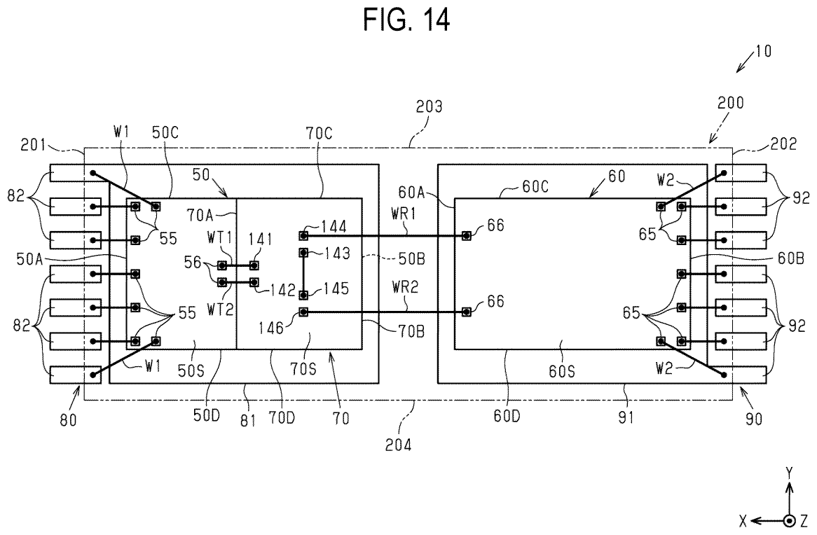

FIG. 14 shows a schematic example of a planar structure of the semiconductor device 10 according to FIG. 13. As shown in FIG. 14, the semiconductor device 10 includes a first chip 50 including the first circuit 20 shown in FIG. 13, a second chip 60 including the second circuit 30 shown in FIG. 13, and a transformer chip 70 including the first to third coils 41 to 43 shown in FIG. 13. The transformer chip 70 is disposed over the first chip 50, as in the first embodiment. Further, the semiconductor device 10 includes a first lead frame 80, a second lead frame 90, and a sealing resin 200, as in the first embodiment.

Two intermediate pads 56 of the first chip 50 are disposed at a center of the chip front surface 50S of the first chip 50 in the Y direction, unlike the first embodiment. The two intermediate pads 56 are disposed at a same position in the X direction and spaced apart from each other in the Y direction.

Two intermediate pads 66 of the second chip 60 are disposed toward the chip side surfaces 60C and 60D, respectively, from a center of the chip front surface 60S of the second chip 60 in the Y direction, unlike the first embodiment. The two intermediate pads 66 are disposed at an end portion, which is closer to the chip side surface 60A, of both end portions of the chip front surface 60S in the X direction. The two intermediate pads 66 are disposed at a same position in the X direction and spaced apart from each other in the Y direction.

The transformer chip 70 includes first to sixth transformer pads 141 to 146. Both the first transformer pad 141 and the second transformer pad 142 are disposed to be closer to the chip side surface 70A than the third to sixth transformer pads 143 to 146 in a plan view. In one example, both the first transformer pad 141 and the second transformer pad 142 are disposed at an end portion, which is closer to the chip side surface 70A, of both end portions of the chip front surface 70S in the X direction. Both the first transformer pad 141 and the second transformer pad 142 are disposed at a center of the chip front surface 70S in the Y direction. In one example, the first transformer pad 141 and the second transformer pad 142 are disposed at the same position in the Y direction as the two intermediate pads 56 of the first chip 50 in a plan view.

The third to sixth transformer pads 143 to 146 are disposed at a center of the chip front surface 70S in the X direction. The third to sixth transformer pads 143 to 146 are disposed at a same position in the X direction and spaced apart from each other in the Y direction. Both the third transformer pad 143 and the fourth transformer pad 144 are disposed over the chip front surface 70S so as to be closer to the chip side surface 70C in the Y direction. Both the fifth transformer pad 145 and the sixth transformer pad 146 are disposed over the chip front surface 70S so as to be closer to the chip side surface 70D in the Y direction. Electrical connection structures among the first to sixth transformer pads 141 to 146, the first chip 50, and the second chip 60 are described later.

### Internal Configuration of Transformer Chip

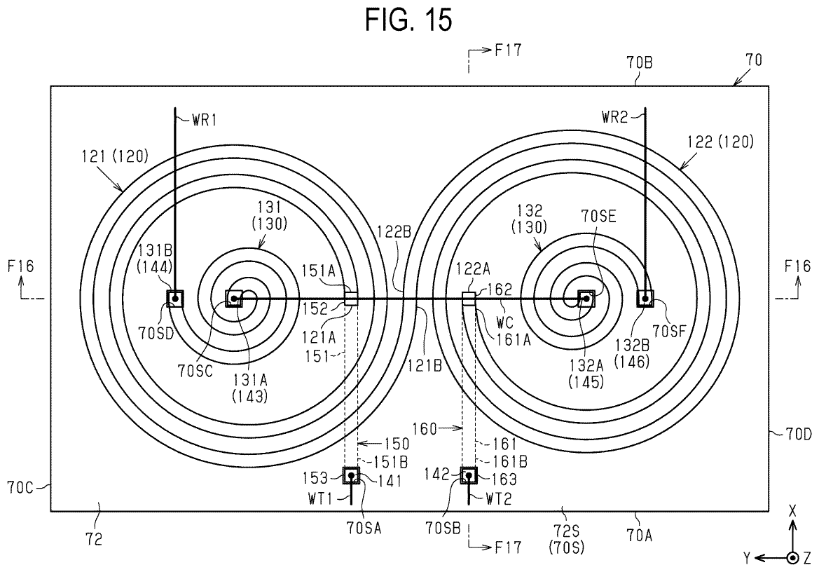

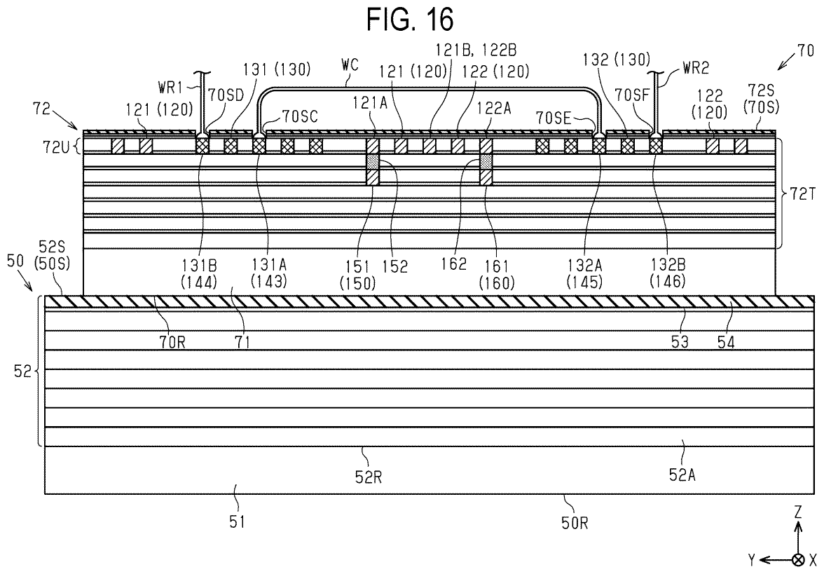

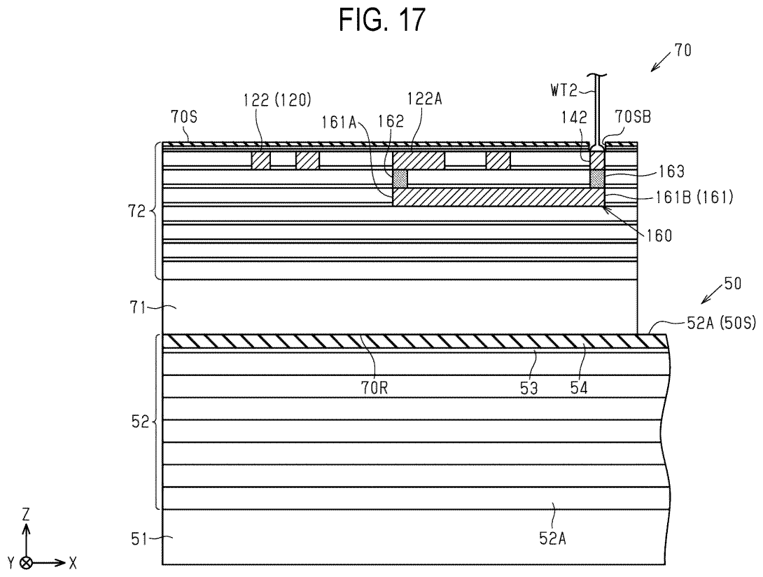

An example of an internal configuration of the transformer chip 70 is described with reference to FIGS. 15 to 17. FIG. 15 shows a schematic planar structure of the inside of the transformer chip 70. FIG. 16 shows a schematic cross-sectional structure taken along line F16-F16 in FIG. 15. FIG. 17 shows a schematic cross-sectional structure taken along line F17-F17 in FIG. 15. For the sake of convenience, an outer coil 120 and an inner coil 130, which are described below, are shown by solid lines in FIG. 15.

As shown in FIG. 15, the transformer chip 70 includes the outer coil 120 and the inner coil 130. The outer coil 120 corresponds to the first coil 41 shown in FIG. 13. The inner coil 130 includes a first inner coil 131 corresponding to the second coil 42 shown in FIG. 13 and a second inner coil 132 corresponding to the third coil 43 shown in FIG. 13. As shown in FIG. 16, each of the outer coil 120, the first inner coil 131, and the second inner coil 132 is embedded in the third element insulating layer 72.

As shown in FIG. 15, the outer coil 120 includes a first outer coil 121 and a second outer coil 122. The first outer coil 121 includes a first end 121A and a second end 121B opposite to the first end 121A. The second outer coil 122 includes a first end 122A and a second end 122B opposite to the first end 122A. The second end 121B of the first outer coil 121 and the second end 122B of the second outer coil 122 are electrically connected to each other.

Each of the first outer coil 121 and the second outer coil 122 is formed in a circular spiral shape in a plan view. The first outer coil 121 and the second outer coil 122 are wound so that when a current flows from a first end of one of the first outer coil 121 and the second outer coil 122 to a first end of the other outer coil, magnetic fluxes in opposite directions are generated. In one example, the first outer coil 121 and the second outer coil 122 are symmetrical in a plan view. In the third embodiment, the first outer coil 121 and the second outer coil 122 are point-symmetrical in a plan view.

In the first outer coil 121 of a spiral shape, the first end 121A is disposed inside the spiral, and the second end 121B is disposed outside the spiral. In other words, the first outer coil 121 is wound in the spiral shape with the first end 121A as an inner peripheral end and the second end 121B as an outer peripheral end. Similarly, in the second outer coil 122 of a spiral shape, the first end 122A is disposed inside the spiral, and the second end 122B is disposed outside the spiral. In other words, the second outer coil 122 is wound in the spiral shape with the first end 122A as an inner peripheral end and the second end 122B as an outer peripheral end. The first outer coil 121 and the second outer coil 122 have their respective second ends 121B and 122B, which are the outer peripheral ends, electrically connected to each other. In one example, the first outer coil 121 and the second outer coil 122 are integrated.

As shown in FIG. 16, the first outer coil 121 and the second outer coil 122 of the outer coil 120 are disposed at a same position in the Z direction. Both the first outer coil 121 and the second outer coil 122 are disposed to be closer to the third element front surface 72S than the center of the third element insulating layer 72 in the Z direction. In the third embodiment, both the first outer coil 121 and the second outer coil 122 are provided at the uppermost insulator 72U of the insulating layer stack structure 72T of the third element insulating layer 72. The outer coil 120 is made of a material containing one or more appropriately selected from the group of Ti, TiN, Au, Ag, Cu, Al, and W. The outer coil 120 of the third embodiment is made of a material containing Cu. Also, the first outer coil 121 and the second outer coil 122 may be provided at, rather than the uppermost insulator 72U of the insulating layer stack structure 72T of the third element insulating layer 72, for example, the insulator 72U immediately below the uppermost insulator 72U.

As shown in FIG. 15, the first inner coil 131 is disposed inside the first outer coil 121. The first inner coil 131 is disposed to be spaced apart from the first outer coil 121 in a plane direction orthogonal to the Z direction. In one example, a winding center of the first inner coil 131 and a winding center of the first outer coil 121 are concentric.

The second inner coil 132 is disposed inside the second outer coil 122. The second inner coil 132 is disposed to be spaced apart from the second outer coil 122 in the plane direction orthogonal to the Z direction. In one example, a winding center of the second inner coil 132 and a winding center of the second outer coil 122 are concentric. The first inner coil 131 and the second inner coil 132 are disposed at a same position in the X direction and spaced apart from each other in the Y direction.

Each of the first inner coil 131 and the second inner coil 132 is formed in a circular spiral shape in a plan view. In one example, the first inner coil 131 and the second inner coil 132 are symmetrical in a plan view. In the third embodiment, the first inner coil 131 and the second inner coil 132 are point-symmetrical in a plan view.

A current flows in the first inner coil 131 in a direction corresponding to a direction of a magnetic flux generated by a current flowing in the first outer coil 121. Similarly, a current flows in the second inner coil 132 in a direction corresponding to a direction of a magnetic flux generated by a current flowing in the second outer coil 122.

The first inner coil 131 includes a first end 131A and a second end 131B opposite to the first end 131A. In the first inner coil 131 of a spiral shape, the first end 131A is disposed inside the spiral, and the second end 131B is disposed outside the spiral. In other words, the first inner coil 131 is wound in the spiral shape with the first end 131A as an inner peripheral end and the second end 131B as an outer peripheral end.

The second inner coil 132 includes a first end 132A and a second end 132B opposite to the first end 132A. In the second inner coil 132 of a spiral shape, the first end 132A is disposed inside the spiral, and the second end 132B is disposed outside the spiral. In other words, the second inner coil 132 is wound in the spiral shape with the first end 132A as an inner peripheral end and the second end 132B as an outer peripheral end.

As shown in FIGS. 16 and 17, the first inner coil 131 and the second inner coil 132 are disposed at a same position in the Z direction. Both the first inner coil 131 and the second inner coil 132 are disposed to be closer to the third element front surface 72S than the center of the third element insulating layer 72 in the Z direction. In the third embodiment, both the first inner coil 131 and the second inner coil 132 are provided at the uppermost insulator 72U of the insulating layer stack structure 72T of the third element insulating layer 72. In this way, both the first inner coil 131 and the second inner coil 132 are disposed at the same position in the Z direction as both the first outer coil 121 and the second outer coil 122. The inner coil 130 is made of a material containing one or more appropriately selected from the group of Ti, TiN, Au, Ag, Cu, Al, and W. In one example, the inner coil 130 is made of a same material as the outer coil 120. The inner coil 130 of the third embodiment is made of a material containing Cu. Also, the first inner coil 131 and the second inner coil 132 may be provided at, rather than the uppermost insulator 72U of the insulating layer stack structure 72T of the third element insulating layer 72, for example, the insulator 72U immediately below the uppermost insulator 72U.

As shown in FIG. 15, the transformer chip 70 includes first to sixth openings 70SA to 70SF. The first to sixth openings 70SA to 70SF are provided at the third element insulating layer 72. The first opening 70SA is an opening that exposes the first transformer pad 141. The second opening 70SB is an opening that exposes the second transformer pad 142. The third opening 70SC is an opening that exposes the first end 131A of the first inner coil 131. The fourth opening 70SD is an opening that exposes the second end 131B of the first inner coil 131. The fifth opening 70SE is an opening that exposes the first end 132A of the second inner coil 132. The sixth opening 70SF is an opening that exposes the second end 132B of the second inner coil 132.

The first transformer pad 141 and the second transformer pad 142 are pads that are electrically connected to the outer coil 120. The first transformer pad 141 is electrically connected to the first end 121A of the first outer coil 121 of the outer coil 120. The second transformer pad 142 is electrically connected to the first end 122A of the second outer coil 122 of the outer coil 120. In one example, the first transformer pad 141 and the second transformer pad 142 are disposed at a same position as the outer coil 120 in the Z direction.

The third to sixth transformer pads 143 to 146 may be pads that are electrically connected to the inner coil 130. In the third embodiment, the third to sixth transformer pads 143 to 146 are constituted by a portion of the inner coil 130. More specifically, the third transformer pad 143 is constituted by exposing the first end 131A of the first inner coil 131 of the inner coil 130 in the Z direction from the third opening 70SC of the third element insulating layer 72. The fourth transformer pad 144 is constituted by exposing the second end 131B of the first inner coil 131 in the Z direction from the fourth opening 70SD of the third element insulating layer 72. The fifth transformer pad 145 is constituted by exposing the first end 132A of the second inner coil 132 of the inner coil 130 in the Z direction from the fifth opening 70SE of the third element insulating layer 72. The sixth transformer pad 146 is constituted by exposing the second end 132B of the second inner coil 132 in the Z direction from the sixth opening 70SF of the third element insulating layer 72.

As shown in FIGS. 15 and 17, the transformer chip 70 includes a first wiring portion 150 and a second wiring portion 160. The first wiring portion 150 is a wiring that electrically connects the first end 121A of the first outer coil 121 and the first transformer pad 141. The second wiring portion 160 is a wiring that electrically connects the first end 122A of the second outer coil 122 and the second transformer pad 142. The first wiring portion 150 and the second wiring portion 160 are made of a material containing one or more appropriately selected from the group of Ti, TiN, Au, Ag, Cu, Al, and W.

As shown in FIGS. 15 and 16, the first wiring portion 150 includes a connection wiring 151 and vias 152 and 153. The connection wiring 151 is disposed to be closer to the third semiconductor substrate 71 than the first outer coil 121 is disposed in the Z direction. The connection wiring 151 extends in the X direction. The connection wiring 151 includes a first end 151A and a second end 151B as both ends in the X direction. The connection wiring 151 extends from the first end 121A of the first outer coil 121 to the first transformer pad 141 in a plan view. The first end 151A of the connection wiring 151 is disposed at a position overlapping the first end 121A of the first outer coil 121 in a plan view. The first end 151A is electrically connected to the first end 121A of the first outer coil 121 by the via 152. The second end 151B of the connection wiring 151 is disposed at a position overlapping the first transformer pad 141 in a plan view. The second end 151B is electrically connected to the first transformer pad 141 by the via 153.

As shown in FIGS. 15 and 17, the second wiring portion 160 includes a connection wiring 161 and vias 162 and 163. The connection wiring 161 and the vias 162 and 163 are disposed in the same manner as the connection wiring 151 and the vias 152 and 153 of the first wiring portion 150. The connection wiring 161 includes a first end 161A and a second end 161B in the same manner as the connection wiring 151. The first end 161A of the connection wiring 161 is electrically connected to the first end 122A of the second outer coil 122 by the via 162, and the second end 161B of the connection wiring 161 is electrically connected to the second transformer pad 142 by the via 163.

As shown in FIGS. 14 and 15, the first transformer pad 141 and the second transformer pad 142 are individually connected to two intermediate pads 56 of the first chip 50 by a first transmitting side wire WT1 and a second transmitting side wire WT2. Each of the first transmitting side wire WT1 and the second transmitting side wire WT2 is provided outside the transformer chip 70. In one example, in a plan view, a length of the first transmitting side wire WT1 and a length of the second transmitting side wire WT2 are equal to each other.

Since one of the two intermediate pads 56 is electrically connected to the transmitting circuit 21, the first transformer pad 141, for example, constituted by the first end 121A of the first outer coil 121 of the outer coil 120, is electrically connected to the transmitting circuit 21 (see FIG. 13) by the first transmitting side wire WT1. Therefore, it may be said that the first outer coil 121 is electrically connected to the first chip 50 by the first transmitting side wire WT1. The other of the two intermediate pads 56 is connected to the ground GND1 (see FIG. 13). Therefore, the second transformer pad 142, for example, constituted by the first end 122A of the second outer coil 122 of the outer coil 120, is electrically connected to the ground GND1 by the second transmitting side wire WT2. Therefore, it may be said that the second outer coil 122 is electrically connected to the first chip 50 by the second transmitting side wire WT2. Herein, the first transmitting side wire WT1 is an example of a “first chip connecting wire,” and the second transmitting side wire WT2 is an example of a “second chip connecting wire.”

The first end 131A of the first inner coil 131 and the first end 132A of the second inner coil 132 of the inner coil 130 are electrically connected by a wire WC. As a result, when a current generated in the first inner coil 131 flows through the wire WC to the second inner coil 132, a direction of the current and a direction of a current generated in the second inner coil 132 become the same. Herein, the wire WC is an example of a “coil connecting wire.”

The fourth transformer pad 144 and the sixth transformer pad 146 are individually connected to the two intermediate pads 66 of the second chip 60 by a first receiving side wire WR1 and a second receiving side wire WR2. Each of the first receiving side wire WR1 and the second receiving side wire WR2 is provided outside the transformer chip 70. In one example, in a plan view, a length of the first receiving side wire WR1 and a length of the second receiving side wire WR2 are equal to each other.

Since one of the two intermediate pads 66 is electrically connected to the receiving circuit 31, the fourth transformer pad 144, for example, constituted by the second end 131B of the first inner coil 131, is electrically connected to the receiving circuit 31 (see FIG. 13) by the first receiving side wire WR1. Therefore, it may be said that the first inner coil 131 is electrically connected to the second chip 60 by the first receiving side wire WR1. The other of the two intermediate pads 66 is connected to the ground GND2 (see FIG. 13). Therefore, the sixth transformer pad 146, for example, constituted by the second end 132B of the second inner coil 132, is electrically connected to the ground GND2. Therefore, it may be said that the second inner coil 132 is electrically connected to the second chip 60 by the second receiving side wire WR2. Herein, the first receiving side wire WR1 is an example of a “third chip connecting wire,” and the second receiving side wire WR2 is an example of a “fourth chip connecting wire.”

### Effects of Third Embodiment

The semiconductor device 10 according to the third embodiment provides the following effects.
(3-1) The outer coil 120 includes the first outer coil 121 and the second outer coil 122 including the first ends 121A and 122A and the second ends 121B and 122B, respectively. The second end 121B of the first outer coil 121 and the second end 122B of the second outer coil 122 are connected to each other. The first outer coil 121 and the second outer coil 122 are configured so that when a current flows from a first end of one of the first outer coil 121 and the second outer coil 122 to a first end of the other outer coil, magnetic fluxes in opposite directions are generated. The inner coil 130 includes the first inner coil 131 and the second inner coil 132 including the first ends 131A and 132A and the second ends 131B and 132B, respectively. In a plan view, the first inner coil 131 is disposed inside the first outer coil 121 so as not to overlap with the first outer coil 121, and the second inner coil 132 is disposed inside the second outer coil 122 so as not to overlap with the second outer coil 122.

With this configuration, the magnetic flux generated by the outer coil 120 may be suppressed from spreading. This allows an increased amount of magnetic flux to cross the inner coil 130. Therefore, it is possible to improve the efficiency of magnetic coupling between the outer coil 120 and the inner coil 130. As a result, it is possible to improve transfer characteristics between the outer coil 120 and the inner coil 130.
(3-2) The first inner coil 131 and the second inner coil 132 are connected by the wire WC provided outside the transformer chip 70. With this configuration, the configuration of the transformer chip 70 may be simplified as compared to a configuration in which the first inner coil 131 and the second inner coil 132 are electrically connected by a wiring provided inside the transformer chip 70. In other words, since a layer for providing the wiring in the third element insulating layer 72 is not required, a dedicated mask for providing the wiring is not required when manufacturing the third element insulating layer 72. Therefore, since a process of manufacturing the transformer chip 70 may be simplified, the manufacturing cost of the transformer chip 70 may be reduced.
(3-3) The first outer coil 121 is electrically connected to the first chip 50 by the first transmitting side wire WT1 provided outside the transformer chip 70. The second outer coil 122 is electrically connected to the first chip 50 by the second transmitting side wire WT2 provided outside the transformer chip 70.

With this configuration, a connection structure between the first outer coil 121 and the first chip 50 may be simplified, for example, as compared to a configuration in which the first outer coil 121 and the first chip 50 are connected by a wiring provided in the transformer chip 70. Further, a connection structure between the second outer coil 122 and the first chip 50 may be simplified, for example, as compared to a configuration in which the second outer coil 122 and the first chip 50 are connected by a wiring provided in the transformer chip 70. In addition, since there is no need to determine the disposition position of transformer chip 70 relative to the first chip 50 with high precision, the semiconductor device 10 may be easily manufactured.
(3-4) Each of the first outer coil 121, the second outer coil 122, the first inner coil 131, and the second inner coil 132 is disposed near the third element front surface 72S of the third element insulating layer 72 in the Z direction.

With this configuration, as compared to a configuration in which two coils are disposed opposite to each other in the Z direction, a distance between each of the first outer coil 121, the second outer coil 122, the first inner coil 131, and the second inner coil 132 and the third semiconductor substrate 71 in the Z direction may be increased. Therefore, the magnetic flux generated in the first outer coil 121, the second outer coil 122, the first inner coil 131, and the second inner coil 132 is less likely to pass through the third semiconductor substrate 71. This makes it possible to suppress the generation of an eddy current caused by the magnetic flux penetrating the third semiconductor substrate 71. Therefore, it is possible to suppress a decrease in efficiency of magnetic coupling caused by the eddy current.
(3-5) The first outer coil 121, the second outer coil 122, the first inner coil 131, and the second inner coil 132 are disposed at a same position in the Z direction. With this configuration, when manufacturing the transformer chip 70, the first outer coil 121, the second outer coil 122, the first inner coil 131, and the second inner coil 132 may be formed using a common mask. Therefore, as compared to a configuration in which the first outer coil 121, the second outer coil 122, the first inner coil 131, and the second inner coil 132 are disposed at different positions in the Z direction, a process of manufacturing the transformer chip 70 may be simplified, thus reducing the manufacturing cost of the transformer chip 70.

### Modifications

The above-described embodiments may be modified as follows. The following modifications may be combined with each other unless technically contradictory.

### Combination of Embodiments

The first and second embodiments may be implemented in combination with each other.
The second and third embodiments may be implemented in combination with each other.

### Modifications of First Embodiment

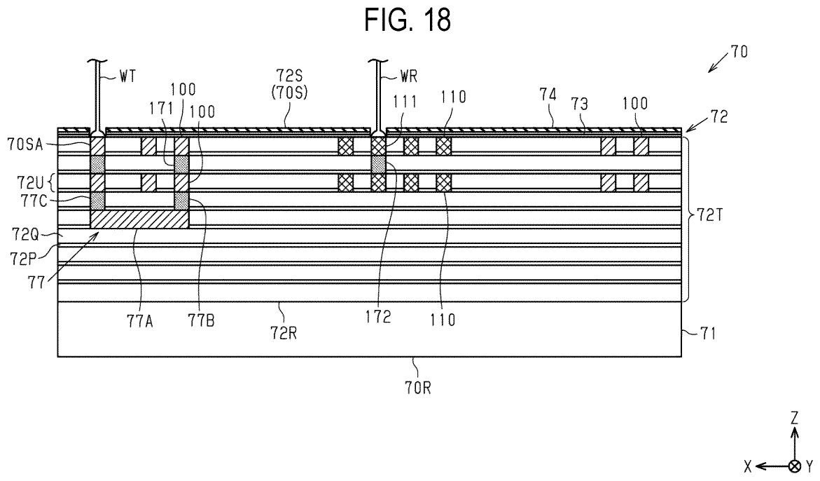

In the first embodiment, the configuration of the transformer chip 70 may be modified as desired. The transformer chip 70 may be modified, for example, as transformer chips 70 of first to fourth modifications shown in FIGS. 18 to 22.

### First Modification

As shown in FIG. 18, the transformer chip 70 of the first modification includes two outer coils 100 disposed in the third element insulating layer 72 to be spaced apart from each other in the Z direction, and a via 171 connecting the two outer coils 100. The two outer coils 100 are connected in parallel by the via 171. The two outer coils 100 are disposed at a position overlapping each other in a plan view. The wiring portion 77 is disposed to be closer to the third semiconductor substrate 71 than the two outer coils 100 are disposed.

With this configuration, the wiring resistance value of the outer coils 100 may be reduced by connecting the two outer coils 100 in parallel. The number of outer coils 100 may be three or more.

Further, the transformer chip 70 of the first modification includes two inner coils 110 disposed in the third element insulating layer 72 to be spaced apart from each other in the Z direction, and a via 172 connecting the two inner coils 110. The two inner coils 110 are connected in parallel by the via 172. The two inner coils 110 are disposed at a position overlapping each other in a plan view. With this configuration, the wiring resistance value of the inner coils 110 may be reduced by connecting the two inner coils 110 in parallel. The number of inner coils 110 may be three or more.

### Second Modification

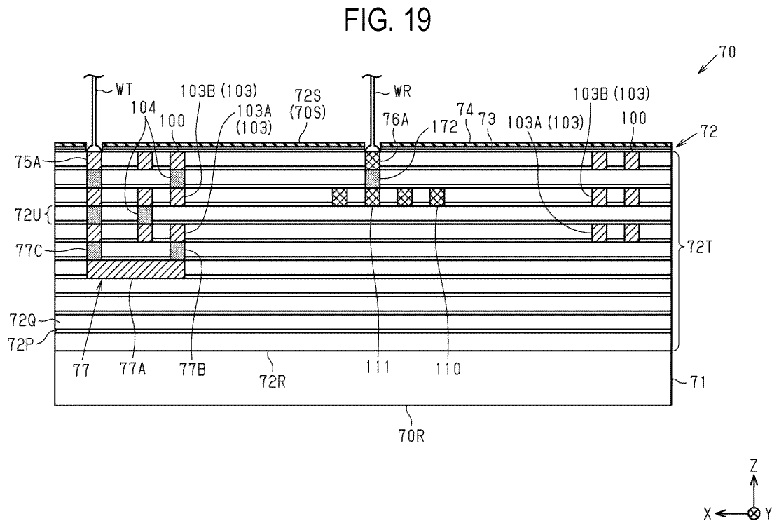

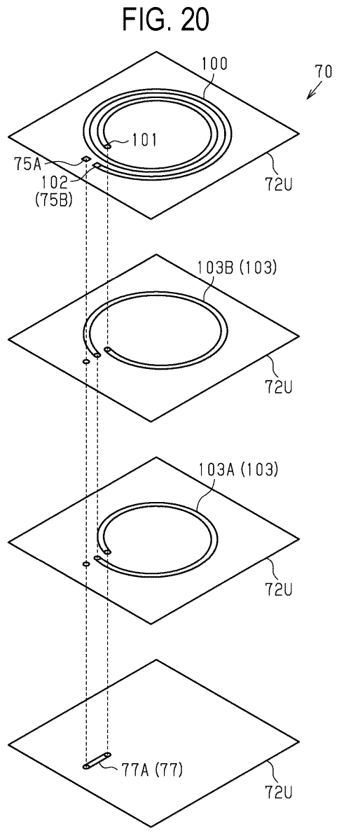

As shown in FIGS. 19 and 20, the transformer chip 70 of the second modification includes an outer coil 100, an outer coil 103 connected to the outer coil 100, and a via 104 connecting these outer coils 100 and 103. The outer coil 103 is disposed so as to overlap with the outer coil 100 in a plan view. The outer coil 103 includes coil portions 103A and 103B disposed to be spaced apart from each other in the Z direction. The coil portions 103A and 103B are connected in series between the outer coil 100 and the wiring portion 77 by the via 104. More specifically, the coil portion 103B is disposed to be closer to the outer coil 100 than the coil portion 103A is disposed in the Z direction. The coil portion 103B is connected in series with the outer coil 100. The coil portion 103B is electrically connected to the first end 101 of the outer coil 100 by the via 104. The coil portion 103A is connected in series with the coil portion 103B. The coil portion 103A is electrically connected to the wiring portion 77. That is, the coil portion 103A is electrically connected to the first transformer pad 75A. On the other hand, the second end 102 of the outer coil 100 constitutes the first transformer pad 75B.

In the transformer chip 70 of the second modification, the outer coil 103 is connected between the wiring portion 77 and the outer coil 100. Therefore, the number of turns of the outer coil consisting of the outer coil 100 and the outer coil 103 may be increased. This increases the amount of magnetic flux generated by the outer coil.

Further, the coil portions 103A and 103B of the outer coil 103 may be connected in parallel. Further, the outer coil 100 may be provided in plural as in the first modification shown in FIG. 18. In this case, the plurality of outer coils 100 may be connected in parallel. In this way, by connecting the outer coil 100 and the outer coil 103 in parallel, the number of turns may be increased and an increase in the wiring resistance value may be suppressed.

As shown in FIG. 19, in the transformer chip 70 of the second modification, the inner coil 110 is disposed at a same position as the coil portion 103B of the outer coil 103 in the Z direction. Further, the configuration of the inner coil 110 may be changed arbitrarily. The position of the inner coil 110 in the Z direction may also be changed arbitrarily. In one example, the inner coil 110 may be disposed at a same position as the outer coil 100 in the Z direction. In one example, the inner coil 110 may be disposed at a same position as the coil portion 103A of the outer coil 103 in the Z direction.

The first end 111 of the inner coil 110 is electrically connected to the second transformer pad 76A by the via 172. The second transformer pad 76A is disposed to be closer to the chip front surface 70S than the inner coil 110 is disposed in the Z direction. In one example, the second transformer pad 76A is disposed at a same position as the outer coil 100.

### Third Modification

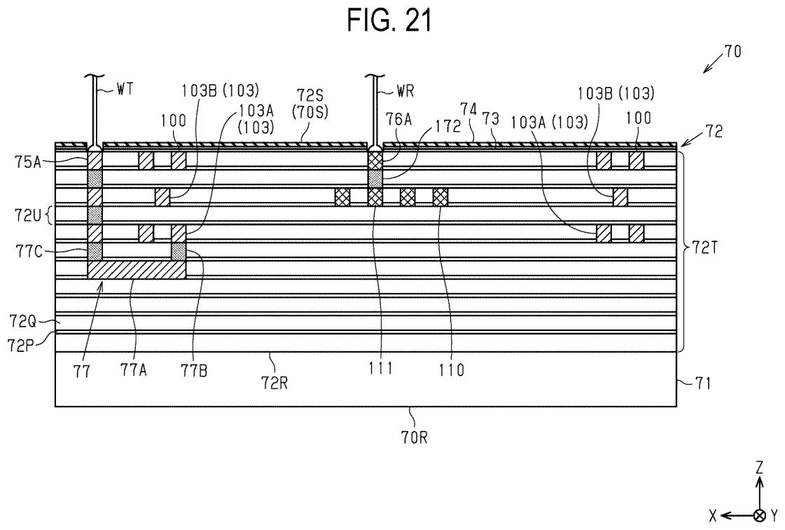

As shown in FIG. 21, the transformer chip 70 of the third modification is disposed so that the coil portion 103B of the outer coil 103 does not overlap with both the outer coil 100 and the coil portion 103A in a plan view, unlike the transformer chip 70 of the second modification shown in FIG. 19. By disposing the outer coil 100 and the coil portions 103A and 103B in this way, a facing area between the outer coil 100/the coil portion 103A and the coil portion 103B in the Z direction is reduced. Therefore, a capacitance of a parasitic capacitor caused by this facing area may be reduced.

### Fourth Modification

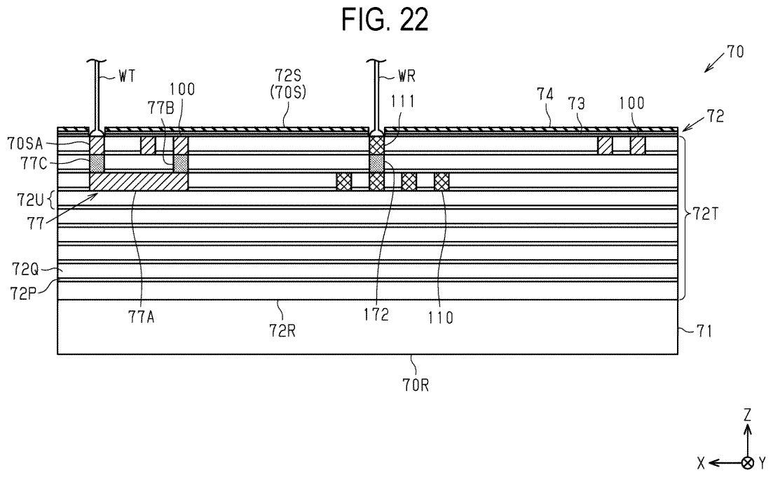

As shown in FIG. 22, in the transformer chip 70 of the fourth modification, the inner coil 110 may be disposed at a position different from the outer coil 100 in the Z direction. In the example shown in FIG. 22, the inner coil 110 is disposed to be closer to the third semiconductor substrate 71 than the outer coil 100 is disposed in the Z direction. With this configuration, a facing area between the outer coil 100 and the inner coil 110 in the direction orthogonal to the Z direction is reduced. Therefore, a capacitance of a parasitic capacitor caused by this facing area may be reduced.

Further, in the transformer chip 70 of the fourth modification, the outer coil 100 may be disposed to be closer to the third semiconductor substrate 71 than the inner coil 110 is disposed in the Z direction. In this case, the inner coil 110 is disposed, for example, on the uppermost insulator 72U of the insulating layer stack structure 72T of the third element insulating layer 72. The inner coil 110 may also be disposed, for example, on the insulator 72U immediately below the uppermost insulator 72U of the insulating layer stack structure 72T.

The shapes of the outer coil 100 and the inner coil 110 in a plan view may be changed arbitrarily. In one example, the outer coil 100 and the inner coil 110 may be formed in a square shape in a plan view. In one example, the outer coil 100 and the inner coil 110 may be formed in a square shape with corners rounded in an arc shape in a plan view. In one example, the outer coil 100 and the inner coil 110 may be formed in an elliptical shape in a plan view.

### Modifications of Second Embodiment

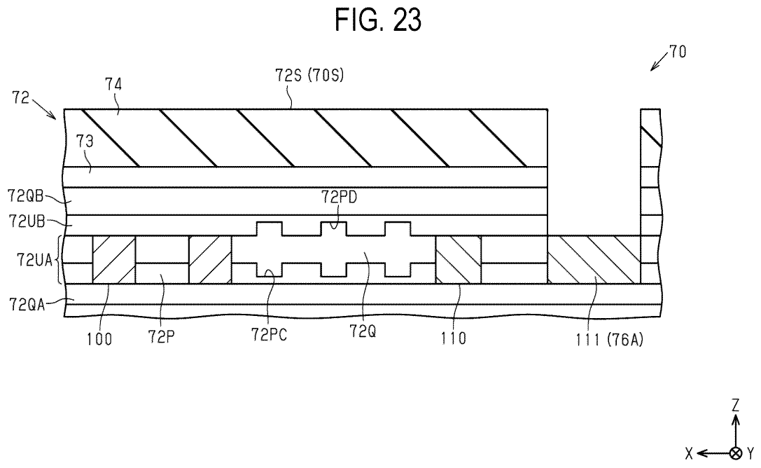

In the second embodiment, the configuration of the third element insulating layer 72 of the transformer chip 70 may be changed arbitrarily. In one example, as shown in FIG. 23, the first insulating film 72P of the specific insulator 72UA includes a plurality of concave portions 72PC that open toward the cover insulating film 72UB. The plurality of concave portions 72PC are disposed to be spaced apart from each other in a direction orthogonal to the Z direction. In one example, each concave portion 72PC is formed in an annular shape in a plan view. In one example, the plurality of concave portions 72PC are formed in a concentric shape in a plan view. In one example, centers of the plurality of concave portions 72PC are concentric with, for example, the center of the outer coil 100 and the center of the inner coil 110. The second insulating film 72Q of the specific insulator 72UA is embedded in the plurality of concave portions 72PC. The cover insulating film 72UB includes a plurality of cover side concave portions 72PD that open toward the first insulating film 72P of the specific insulator 72UA. The plurality of cover side concave portions 72PD are disposed to be spaced apart from each other in a plane direction orthogonal to the Z direction. In one example, the plurality of cover side concave portions 72PD are formed in a concentric shape in a plan view. Centers of the plurality of cover side concave portions 72PD are concentric with, for example, the center of the outer coil 100 and the center of the inner coil 110. The second insulating film 72Q of the specific insulator 72UA is embedded in the plurality of cover side concave portions 72PD. With this configuration, the same effects as those of (2-1) and (2-2) in the second embodiment may be obtained.

In the second embodiment, the number of isolation insulating films 78A and the number of cover side isolation insulating films 78B may be changed arbitrarily. In one example, the number of isolation insulating films 78A may be one. In one example, the number of cover side isolation insulating films 78B may be one. In another example, the number of isolation insulating films 78A may be different from the number of cover side isolation insulating films 78B.

In the second embodiment, the plurality of isolation insulating films 78A may be disposed at positions different from the positions of the plurality of cover side isolation insulating films 78B. That is, in a plan view, the plurality of isolation insulating films 78A may be disposed at positions where they do not overlap with the plurality of cover side isolation insulating films 78B. Further, in one example, in a plan view, the plurality of isolation insulating films 78A may be disposed at positions partially overlapping the plurality of cover side isolation insulating films 78B.

In the second embodiment, the isolation insulating film 78A only needs to penetrate the first insulating film 72P of the specific insulator 72UA in the Z direction, and the concave shape of the second insulating film 72Q may be omitted.

In the second embodiment, the cover side isolation insulating film 78B only needs to penetrate the cover insulating film 72UB in the Z direction, and the concave shape of the second insulating film 72Q of the specific insulator 72UA may be omitted.

### Modifications of Third Embodiment

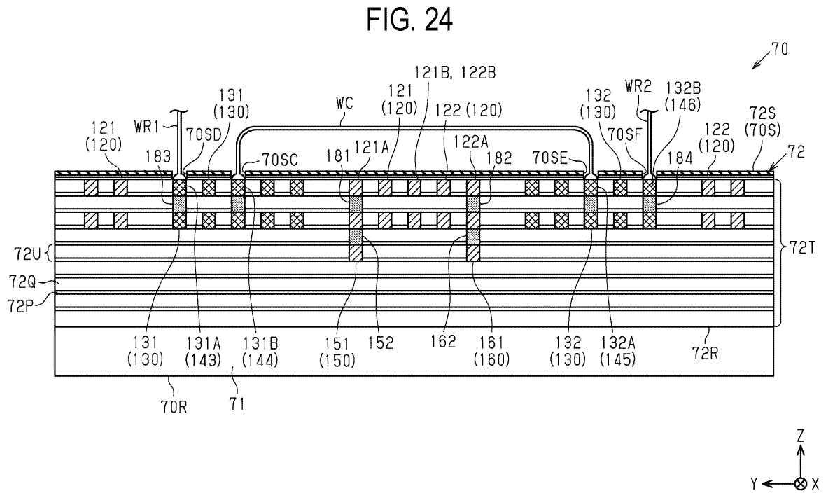

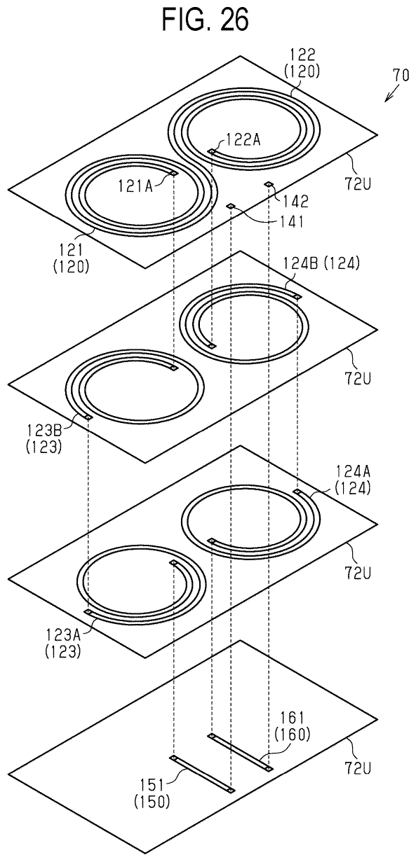

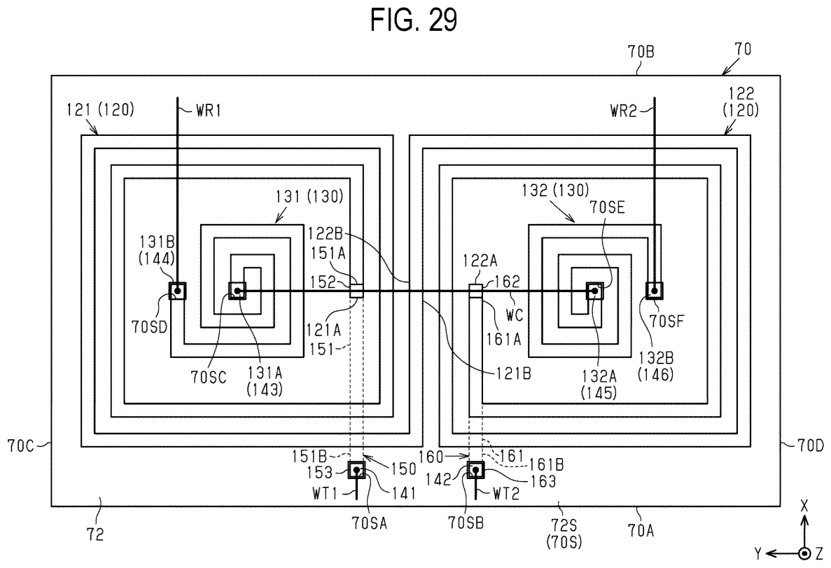

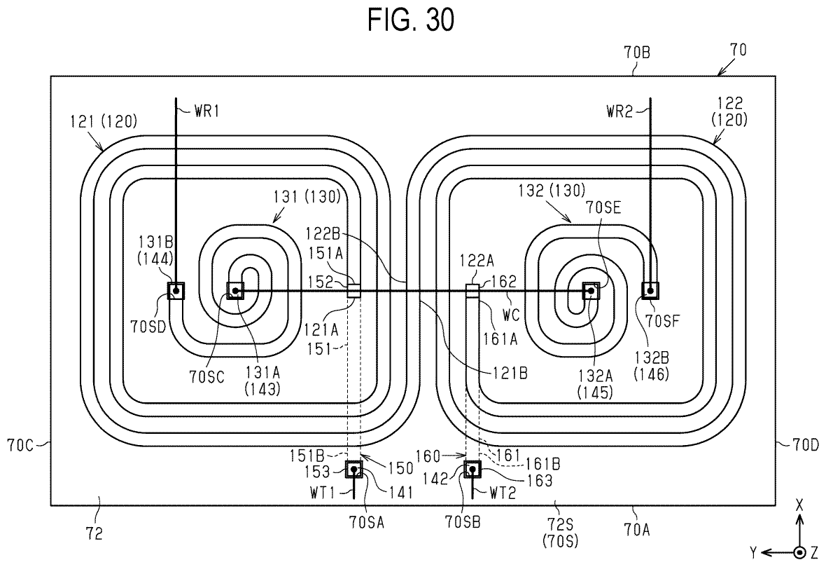

In the third embodiment, the configuration of the transformer chip 70 may be changed arbitrarily. The transformer chip 70 may be changed, for example, as in first to fifth modifications shown in FIGS. 24 to 30. FIGS. 24, 25, 27, and 28 show schematic cross-sectional structures of the transformer chip 70. Cross-sectional positions in FIGS. 24, 25, 27, and 28 are the same as the cross-sectional position of line F16-F16 in FIG. 15 of the third embodiment. FIG. 26 shows an exploded perspective structure of a portion of the transformer chip 70. FIGS. 29 and 30 show schematic planar structures of the transformer chip 70. For the sake of convenience, the outer coil 120 and the inner coil 130 are indicated by solid lines in FIGS. 29 and 30.

### First Modification

As shown in FIG. 24, the transformer chip 70 of the first modification includes two outer coils 120 disposed to be spaced apart from each other in the Z direction, and vias 181 and 182 connecting the two outer coils 120. Two first outer coils 121 disposed to be spaced apart from each other in the Z direction are connected in parallel by the via 181. Two second outer coils 122 disposed to be spaced apart from each other in the Z direction are connected in parallel by the via 182. With this configuration, as the two first outer coils 121 are connected in parallel and the two second outer coils 122 are connected in parallel, a wiring resistance value of the outer coil 120 may be reduced. Further, three or more outer coils 120 may be provided to be spaced apart from each other in the Z direction.

The inner coil 130 includes two inner coils 130 disposed to be spaced apart from each other in the Z direction, and vias 183 and 184 connecting the two inner coils 130. First inner coils 131 disposed to be spaced apart from each other in the Z direction are connected in parallel by the via 183. Second inner coils 132 disposed to be spaced apart from each other in the Z direction are connected in parallel by the via 184. With this configuration, as the two first inner coils 131 are connected in parallel and the two second inner coils 132 are connected in parallel, a wiring resistance value of the inner coil 130 may be reduced. Further, three or more inner coils 130 may be provided to be spaced apart from each other in the Z direction.

### Second Modification

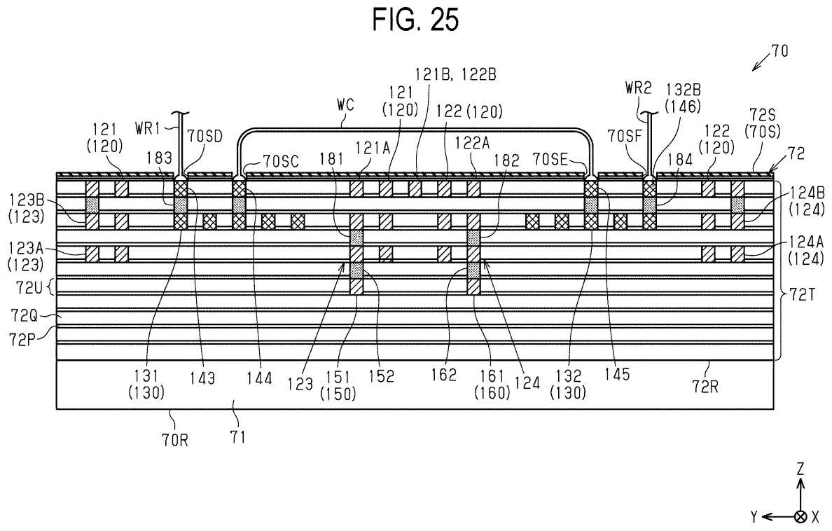

As shown in FIGS. 25 and 26, in the transformer chip 70 of the second modification, the outer coil 120 includes a first outer coil 121 and a second outer coil 122, a third outer coil 123 connected to the first outer coil 121, and a fourth outer coil 124 connected to the second outer coil 122.

The third outer coil 123 is disposed so as to overlap with the first outer coil 121 in a plan view. The third outer coil 123 includes coil portions 123A and 123B disposed to be spaced apart from each other in the Z direction. The coil portions 123A and 123B are connected in series between the first end 121A of the first outer coil 121 and the first wiring portion 150.

The fourth outer coil 124 is disposed so as to overlap with the second outer coil 122 in a plan view. The fourth outer coil 124 includes coil portions 124A and 124B disposed to be spaced apart from each other in the Z direction. The coil portions 124A and 124B are connected in series between the first end 122A of the second outer coil 122 and the second wiring portion 160.

In the transformer chip 70 of the second modification, the third outer coil 123 and the first outer coil 121 are connected in series between the first wiring portion 150 and the second outer coil 122. Further, the second outer coil 122 and the fourth outer coil 124 are connected in series between the first outer coil 121 and the second wiring portion 160. Therefore, the number of turns of the outer coil 120 disposed outside each of the first inner coil 131 and the second inner coil 132 may be increased. Therefore, an amount of magnetic flux generated by the outer coil 120 may be increased.

Further, the third outer coils 123 (the coil portions 123A and 123B) disposed to be spaced apart from each other in the Z direction may be connected in parallel. Similarly, the fourth outer coils 124 (the coil portions 124A and 124B) disposed to be spaced apart from each other in the Z direction may be connected in parallel. In this way, by connecting the third outer coils 123 and the fourth outer coils 124 in parallel, the number of turns of the outer coil 120 may be increased while suppressing an increase in the wiring resistance value.

As shown in FIG. 25, in the transformer chip 70 of the second modification, the inner coil 130 is disposed at a same position in the Z direction as the coil portion 123B of the third outer coil 123 and the coil portion 124B of the fourth outer coil 124. Also, the configuration of the inner coil 130 may be changed arbitrarily. The position of the inner coil 130 in the Z direction may also be changed arbitrarily. In one example, the inner coil 130 may be disposed at a same position as the outer coil 120 in the Z direction. In one example, the inner coil 130 may be disposed at a same position as the coil portion 123A of the third outer coil 123 and the coil portion 124A of the fourth outer coil 124 in the Z direction.

### Third Modification

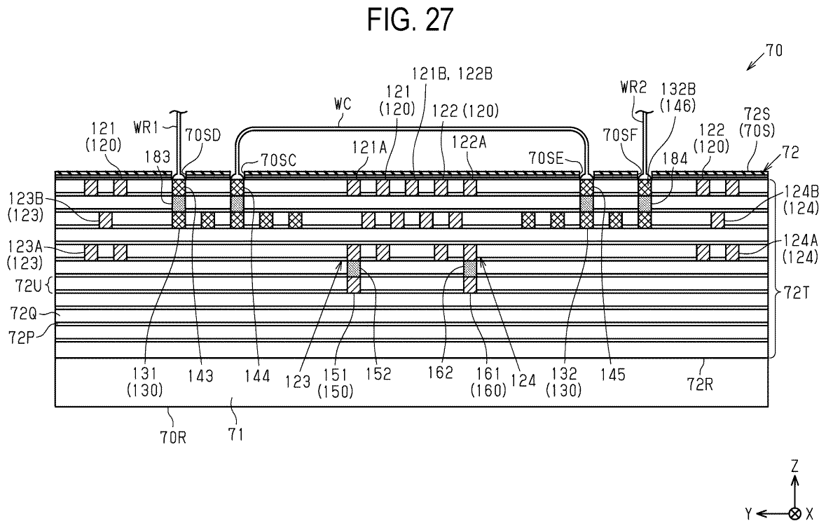

The transformer chip 70 of the third modification shown in FIG. 27 is different from the transformer chip 70 of the second modification shown in FIG. 25 in that the coil portion 123B of the third outer coil 123 is disposed so as not to overlap with the first outer coil 121, the second outer coil 122, and the coil portion 123A in a plan view. By disposing the first outer coil 121 and the third outer coil 123 in this way, a facing area between the coil portion 123B and the first outer coil 121/the second outer coil 122/the coil portion 123A in the Z direction is reduced. Therefore, a capacitance of a parasitic capacitor caused by this facing area may be reduced.

### Fourth Modification

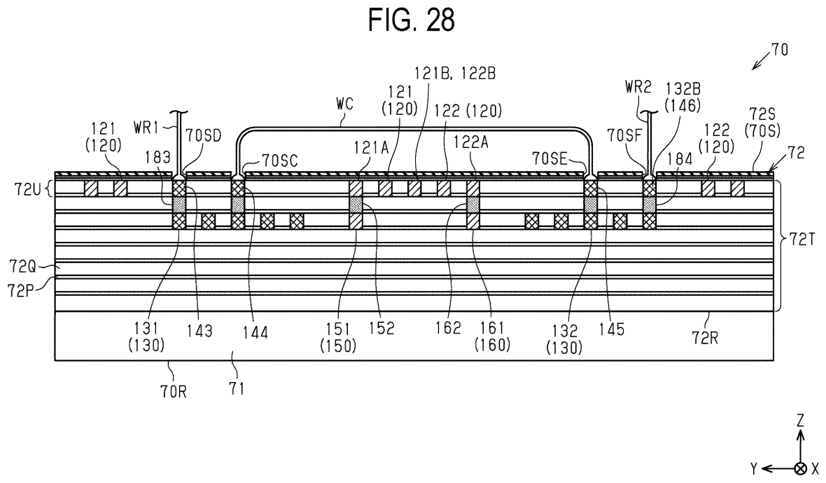

In the transformer chip 70 of the fourth modification shown in FIG. 28, the first inner coil 131 and the second inner coil 132 of the inner coil 130 are disposed at positions different from the first outer coil 121 and the second outer coil 122 of the outer coil 120 in the Z direction. In one example, the first inner coil 131 and the second inner coil 132 are disposed to be closer to the third semiconductor substrate 71 than the first outer coil 121 and the second outer coil 122 are disposed in the Z direction. With this configuration, a facing area between the inner coil 130 and the outer coil 120 in a direction orthogonal to the Z direction is reduced. Therefore, a capacitance of a parasitic capacitor caused by this facing area may be reduced.

Further, in the transformer chip 70 of the fourth modification, the outer coil 120 may be disposed to be closer to the third semiconductor substrate 71 than the inner coil 130 is disposed in the Z direction. In this case, the inner coil 130 is disposed, for example, at the uppermost insulator 72U of the insulating layer stack structure 72T of the third element insulating layer 72. The inner coil 130 may also be disposed, for example, at the insulator 72U immediately below the uppermost insulator 72U of the insulating layer stack structure 72T.

### Fifth Modification

The shapes of the outer coil 120 and the inner coil 130 in a plan view may be changed arbitrarily. In one example, as shown in FIG. 29, each of the outer coil 120 and the inner coil 130 may be formed in a square shape in a plan view. Further, in one example, as shown in FIG. 30, each of the outer coil 120 and the inner coil 130 may be formed in a square shape with corners rounded in an arc shape in a plan view. Further, although not shown, each of the outer coil 120 and the inner coil 130 may be formed in an elliptical shape in a plan view.

A positional relationship in the Z direction between the first outer coil 121 and the second outer coil 122 of the outer coil 120 may be changed arbitrarily. In one example, the first outer coil 121 and the second outer coil 122 may be disposed at different positions in the Z direction. In this case, the second end 121B of the first outer coil 121 and the second end 122B of the second outer coil 122 may be formed so as to overlap each other in a plan view. Then, the second end 121B of the first outer coil 121 and the second end 122B of the second outer coil 122 may be directly electrically connected.

A positional relationship in the Z direction between the first inner coil 131 and the second inner coil 132 of the inner coil 130 may be changed arbitrarily. In one example, the first inner coil 131 and the second inner coil 132 may be disposed at different positions in the Z direction.

The first end 131A of the first inner coil 131 and the first end 132A of the second inner coil 132 of the inner coil 130 may be connected to the second chip 60. The second chip 60 may include a pad connected to the first end 131A of the first inner coil 131 and a pad connected to the first end 132A of the second inner coil 132 of the inner coil 130. The second circuit 30 of the second chip 60 may include a first receiving circuit that receives a signal transmitted by the first inner coil 131 and a second receiving circuit that receives a signal transmitted by the second inner coil 132.

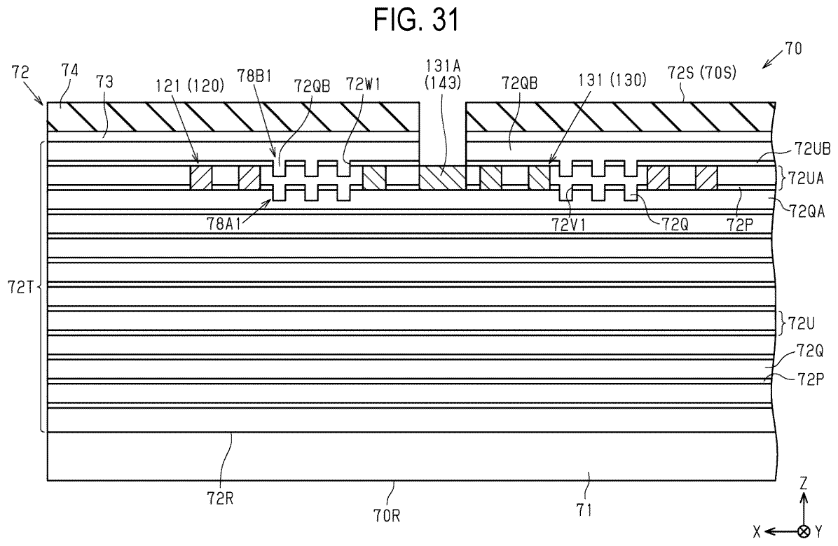

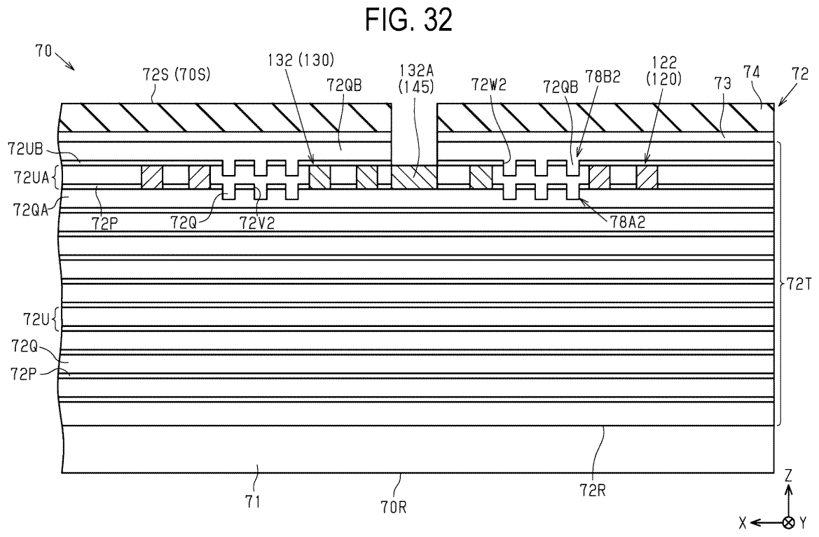

A configuration in a case where the third embodiment is combined with the second embodiment is described with reference to FIGS. 31 and 32. FIG. 31 shows an enlarged cross-sectional structure of the first outer coil 121, the first inner coil 131, and their periphery. FIG. 32 shows an enlarged cross-sectional structure of the second outer coil 122, the second inner coil 132, and their periphery.

As shown in FIG. 31, a plurality of first grooves 72V1 are provided in a portion of the first insulating film 72P of the specific insulator 72UA between the first inner coil 131 and the first outer coil 121. Herein, the specific insulator 72UA is provided with the first inner coil 131, the second inner coil 132 (see FIG. 32), the first outer coil 121, and the second outer coil 122 (see FIG. 32). The plurality of first grooves 72V1 are provided to be spaced apart from each other in a direction orthogonal to the Z direction. Each first groove 72V1 is formed in an annular shape in a plan view. In one example, the plurality of first grooves 72V1 are formed in a concentric shape in a plan view. In one example, centers of the plurality of first grooves 72V1 are concentric with the center of the first outer coil 121 and the center of the first inner coil 131. In this way, by the plurality of first grooves 72V1, the first insulating film 72P of the specific insulator 72UA is provided to be spaced apart in the direction orthogonal to the Z direction between the first outer coil 121 and the first inner coil 131.

Each first groove 72V1 is a rectangular groove that penetrates the first insulating film 72P of the specific insulator 72UA in the Z direction and forms a concave shape in the second insulating film 72QA immediately below the specific insulator 72UA. The second insulating film 72Q of the specific insulator 72UA enters each first groove 72V1. This forms a plurality of first isolation insulating films 78A1. In this way, a portion of the first insulating film 72P of the specific insulator 72UA between the first inner coil 131 and the first outer coil 121 includes the plurality of first isolation insulating films 78A1 that are provided to be spaced apart from each other in the direction orthogonal to the Z direction. That is, the first insulating film 72P between the first outer coil 121 and the first inner coil 131 is isolated by the second insulating film 72Q (the first isolation insulating film 78A1) having a smaller dielectric constant than the first insulating film 72P. Since each first groove 72V1 is formed in an annular shape, each first isolation insulating film 78A1 provided in each first groove 72V1 is formed in an annular shape in a plan view. When the plurality of first grooves 72V1 are formed in a concentric shape in a plan view, the plurality of first isolation insulating films 78A1 are formed in a concentric shape in a plan view. In this way, the first insulating film 72P and the second insulating film 72Q are alternately disposed between the first outer coil 121 and the first inner coil 131 in the direction orthogonal to the Z direction.

As shown in FIG. 32, a plurality of second grooves 72V2 are provided in a portion of the first insulating film 72P of the specific insulator 72UA between the second inner coil 132 and the second outer coil 122. The plurality of second grooves 72V2 are provided to be spaced apart from each other in a direction orthogonal to the Z direction. Each second groove 72V2 is formed in an annular shape in a plan view. In one example, the plurality of second grooves 72V2 are formed in a concentric shape in a plan view. In one example, centers of the plurality of second grooves 72V2 are concentric with the center of the second outer coil 122 and the center of the second inner coil 132. In this way, by the plurality of second grooves 72V2, the first insulating film 72P of the specific insulator 72UA is provided to be spaced apart in the direction orthogonal to the Z direction between the second outer coil 122 and the second inner coil 132.

Each second groove 72V2 is a rectangular groove that penetrates the first insulating film 72P of the specific insulator 72UA in the Z direction and forms a concave shape in the second insulating film 72QA immediately below the specific insulator 72UA. The second insulating film 72Q of the specific insulator 72UA enters each second groove 72V2. This forms a plurality of second isolation insulating films 78A2. In this way, a portion of the first insulating film 72P of the specific insulator 72UA between the second inner coil 132 and the second outer coil 122 includes the plurality of second isolation insulating films 78A2 that are provided to be spaced apart from each other in the direction orthogonal to the Z direction. That is, the first insulating film 72P between the second outer coil 122 and the second inner coil 132 is isolated by the second insulating film 72Q (the second isolation insulating film 78A2) having a smaller dielectric constant than the first insulating film 72P. Since each second groove 72V2 is formed in an annular shape, each second isolation insulating film 78A2 provided in each second groove 72V2 is formed in an annular shape in a plan view. When the plurality of second grooves 72V2 are formed in a concentric shape in a plan view, the plurality of second isolation insulating films 78A2 are formed in a concentric shape in a plan view. In this way, the first insulating film 72P and the second insulating film 72Q are alternately disposed between the second outer coil 122 and the second inner coil 132 in the direction orthogonal to the Z direction.

As shown in FIG. 31, a plurality of first grooves 72W1 are provided in a portion of the cover insulating film 72UB between the first inner coil 131 and the first outer coil 121, wherein the cover insulating film 72UB contacts the second insulating film 72Q of the specific insulator 72UA. The plurality of first grooves 72W1 are provided to be spaced apart from each other in a direction orthogonal to the Z direction. Each first groove 72W1 is formed in an annular shape in a plan view. In one example, the plurality of first grooves 72W1 are formed in a concentric shape in a plan view. In one example, centers of the plurality of first grooves 72W1 are concentric with the center of the first outer coil 121 and the center of the first inner coil 131. In this way, by the plurality of first grooves 72W1, the cover insulating film 72UB is provided to be spaced apart in the direction orthogonal to the Z direction between the first outer coil 121 and the first inner coil 131.

Each first groove 72W1 is a rectangular groove that penetrates the cover insulating film 72UB in the Z direction and forms a concave shape in the second insulating film 72Q of the specific insulator 72UA. The second insulating film 72QB on the cover insulating film 72UB enters each first groove 72W1. This forms a plurality of first cover side isolation insulating films 78B1. In this way, a portion of the cover insulating film 72UB between the first inner coil 131 and the first outer coil 121 includes the plurality of first cover side isolation insulating films 78B1 that are provided to be spaced apart from each other in the direction orthogonal to the Z direction. That is, the cover insulating film 72UB between the first outer coil 121 and the first inner coil 131 is isolated by the second insulating film 72Q (the first cover side isolation insulating film 78B1) having a smaller dielectric constant than the first insulating film 72P. Since each first groove 72W1 is formed in an annular shape, each first cover side isolation insulating film 78B1 provided in each first groove 72W1 is formed in an annular shape in a plan view. When the plurality of first grooves 72W1 are formed in a concentric shape in a plan view, the plurality of first cover side isolation insulating films 78B1 are formed in a concentric shape in a plan view. In this way, the first insulating film 72P and the second insulating film 72Q are alternately disposed between the first outer coil 121 and the first inner coil 131 in the direction orthogonal to the Z direction.

As shown in FIG. 32, a plurality of second grooves 72W2 are provided in a portion of the cover insulating film 72UB between the second inner coil 132 and the second outer coil 122, wherein the cover insulating film 72UB contacts the second insulating film 72Q of the specific insulator 72UA. The plurality of second grooves 72W2 are provided to be spaced apart from each other in a direction orthogonal to the Z direction. Each second groove 72W2 is formed in an annular shape in a plan view. In one example, the plurality of second grooves 72W2 are formed in a concentric shape in a plan view. In one example, centers of the plurality of second grooves 72W2 are concentric with the center of the second outer coil 122 and the center of the second inner coil 132. In this way, by the plurality of second grooves 72W2, the cover insulating film 72UB is provided to be spaced apart in the direction orthogonal to the Z direction between the second outer coil 122 and the second inner coil 132.

Each second groove 72W2 is a rectangular groove that penetrates the cover insulating film 72UB in the Z direction and forms a concave shape in the second insulating film 72Q of the specific insulator 72UA. The second insulating film 72QB on the cover insulating film 72UB enters each second groove 72W2. This forms a plurality of second cover side isolation insulating films 78B2. In this way, a portion of the cover insulating film 72UB between the second inner coil 132 and the second outer coil 122 includes the plurality of second cover side isolation insulating films 78B2 that are provided to be spaced apart from each other in the direction orthogonal to the Z direction. That is, the cover insulating film 72UB between the second outer coil 122 and the second inner coil 132 is isolated by the second insulating film 72Q (the second cover side isolation insulating film 78B2) having a smaller dielectric constant than the first insulating film 72P. Since each second groove 72W2 is formed in an annular shape, each second cover side isolation insulating film 78B2 provided in each second groove 72W2 is formed in an annular shape in a plan view. When the plurality of second grooves 72W2 are formed in a concentric shape in a plan view, the plurality of second cover side isolation insulating film 78B2 are formed in a concentric shape in a plan view. In this way, the first insulating film 72P and the second insulating film 72Q are alternately disposed between the second outer coil 122 and the second inner coil 132 in the direction orthogonal to the Z direction.

In one example, a width dimension of each first groove 72W1 is equal to a width dimension of each first groove 72V1. Further, the width dimensions of the plurality of first grooves 72W1 are equal to each other. Further, the width dimensions of the plurality of first grooves 72V1 are equal to each other. In one example, a width dimension of each second groove 72W2 is equal to a width dimension of each second groove 72V2. Further, the width dimensions of the plurality of second grooves 72W2 are equal to each other. Further, the width dimensions of the second grooves 72V2 are equal to each other. Herein, the width dimension of each of the first grooves 72V1 and 72W1 may be defined by a distance between side surfaces constituting each of the first grooves 72V1 and 72W1 in the direction orthogonal to the Z direction. The width dimension of each of the second grooves 72V2 and 72W2 may be defined by a distance between side surfaces constituting each of the second grooves 72V2 and 72W2 in the direction orthogonal to the Z direction.

When the width dimension of each first groove 72W1 and the width dimension of each first groove 72V1 are equal to each other, a width dimension of each first cover side isolation insulating film 78B1 is equal to a width dimension of each first isolation insulating film 78A1. Further, when the width dimensions of the plurality of first grooves 72W1 are equal to each other, the width dimensions of the plurality of first cover side isolation insulating films 78B1 are equal to each other. Further, when the width dimensions of the plurality of first grooves 72V1 are equal to each other, the width dimensions of the plurality of first isolation insulating films 78A1 are equal to each other. Herein, the width dimension of the first isolation insulating film 78A1 may be defined by a distance between side surfaces of the first isolation insulating film 78A1 that contact the side surfaces constituting the first groove 72V1 in the direction orthogonal to the Z direction. Further, the width dimension of the first cover side isolation insulating film 78B1 may be defined by a distance between side surfaces of the first cover side isolation insulating film 78B1 that contact the side surfaces constituting the first groove 72W1 in the direction orthogonal to the Z direction.

When the width dimension of each second groove 72W2 is equal to the width dimension of each second groove 72V2, a width dimension of each second cover side isolation insulating film 78B2 is equal to a width dimension of each second isolation insulating film 78A2. Further, when the width dimensions of the plurality of the second grooves 72W2 are equal to each other, the width dimensions of the plurality of second cover side isolation insulating films 78B2 are equal to each other. Further, when the width dimensions of the plurality of second grooves 72V2 are equal to each other, the width dimensions of the plurality of second isolation insulating films 78A2 are equal to each other. Herein, the width dimension of the second isolation insulating film 78A2 may be defined by a distance between side surfaces of the second isolation insulating film 78A2 that contact the side surfaces constituting the second groove 72V2 in the direction orthogonal to the Z direction. Further, the width dimension of the second cover side isolation insulating film 78B2 may be defined by a distance between side surfaces of the second cover side isolation insulating film 78B2 that contact the side surfaces constituting the second groove 72W2 in the direction orthogonal to the Z direction.

With this configuration, the plurality of first isolation insulating films 78A1 and second insulating films 72Q are alternately disposed in a portion of the first insulating film 72P of the specific insulator 72UA between the first inner coil 131 and the first outer coil 121. As a result, it is possible to increase a creepage distance between the first inner coil 131 and the first outer coil 121. The plurality of second isolation insulating films 78A2 and second insulating films 72Q are alternately disposed in a portion of the first insulating film 72P of the specific insulator 72UA between the second inner coil 132 and the second outer coil 122. As a result, it is possible to increase a creepage distance between the second inner coil 132 and the second outer coil 122.

Further, the plurality of first cover side isolation insulating films 78B1 and second insulating films 72Q are alternately disposed in a portion of the cover insulating film 72UB between the first inner coil 131 and the first outer coil 121. As a result, it is possible to increase the creepage distance between the first inner coil 131 and the first outer coil 121. The plurality of second cover side isolation insulating film 78B2 and second insulating film 72Q are alternately disposed in a portion of the cover insulating film 72UB between the second inner coil 132 and the second outer coil 122. As a result, it is possible to increase the creepage distance between the second inner coil 132 and the second outer coil 122. Therefore, it is possible to improve the dielectric breakdown voltage of the semiconductor device 10 while suppressing the increase in size of the transformer chip 70.

Further, the number of first grooves 72V1 and 72W1 may be changed arbitrarily. Further, in the modification shown in FIGS. 31 and 32, the first grooves 72V1 and 72W1 are disposed at positions overlapping each other in a plan view, but are not limited thereto. The first grooves 72V1 and 72W1 may be disposed at positions different from each other in a plan view. In other words, the number of first isolation insulating films 78A1 and the number of first cover side isolation insulating films 78B1 may be changed arbitrarily. Further, in the modification shown in FIGS. 31 and 32, the first isolation insulating film 78A1 and the first cover side isolation insulating film 78B1 are disposed at positions overlapping each other in a plan view, but are not limited thereto. The first isolation insulating film 78A1 and the first cover side isolation insulating film 78B1 may be disposed at positions different from each other in a plan view.

Further, the number of second grooves 72V2 and 72W2 may be changed arbitrarily. Further, in the modification shown in FIGS. 31 and 32, the second grooves 72V2 and 72W2 are disposed at positions overlapping each other in a plan view, but are not limited thereto. The second grooves 72V2 and 72W2 may be disposed at positions different from each other in a plan view. In other words, the number of second isolation insulating films 78A2 and the number of second cover side isolation insulating films 78B2 may be changed arbitrarily. Further, in the modification shown in FIGS. 31 and 32, the second isolation insulating film 78A2 and the second cover side isolation insulating film 78B2 are disposed at positions overlapping each other in a plan view, but are not limited thereto. The second isolation insulating film 78A2 and the second cover side isolation insulating film 78B2 may be disposed at positions different from each other in a plan view.

Further, the width dimensions of the first grooves 72V1 and 72W1 may be changed arbitrarily. In one example, the width dimension of the first groove 72V1 and the width dimension of the first groove 72W1 may be different from each other. That is, the width dimension of the first isolation insulating film 78A1 and the width dimension of the first cover side isolation insulating film 78B1 may be different from each other. In one example, the width dimension of at least one selected from the group of the plurality of first grooves 72V1 may be different from the width dimensions of the remaining first grooves 72V1. That is, the width dimension of at least one selected from the group of the plurality of first isolation insulating films 78A1 may be different from the width dimensions of the remaining first isolation insulating films 78A1. In one example, the width dimension of at least one selected from the group of the plurality of first grooves 72W1 may be different from the width dimensions of the remaining first grooves 72W1. That is, the width dimension of at least one selected from the group of the plurality of first cover side isolation insulating films 78B1 may be different from the width dimensions of the remaining first cover side isolation insulating films 78B1. Also, the shapes of the first grooves 72V1 and 72W1 are not limited to a rectangular concave shape and may be changed arbitrarily. In one example, the first grooves 72V1 and 72W1 may be V-shaped.

Further, the width dimensions of the second grooves 72V2 and 72W2 may be changed arbitrarily. In one example, the width dimension of the second groove 72V2 and the width dimension of the second groove 72W2 may be different from each other. That is, the width dimension of the second isolation insulating film 78A2 and the width dimension of the second cover side isolation insulating film 78B2 may be different from each other. In one example, the width dimension of at least one selected from the group of the plurality of second grooves 72V2 may be different from the width dimensions of the remaining second grooves 72V2. That is, the width dimension of at least one selected from the group of the plurality of second isolation insulating films 78A2 may be different from the width dimensions of the remaining second isolation insulating films 78A2. In one example, the width dimension of at least one selected from the group of the plurality of second grooves 72W2 may be different from the width dimensions of the remaining second grooves 72W2. That is, the width dimension of at least one selected from the group of the plurality of second cover side isolation insulating films 78B2 may be different from the width dimensions of the remaining second cover side isolation insulating films 78B2. Also, the shapes of the second grooves 72V2 and 72W2 are not limited to a rectangular concave shape and may be changed arbitrarily. In one example, the second grooves 72V2 and 72W2 may be V-shaped.

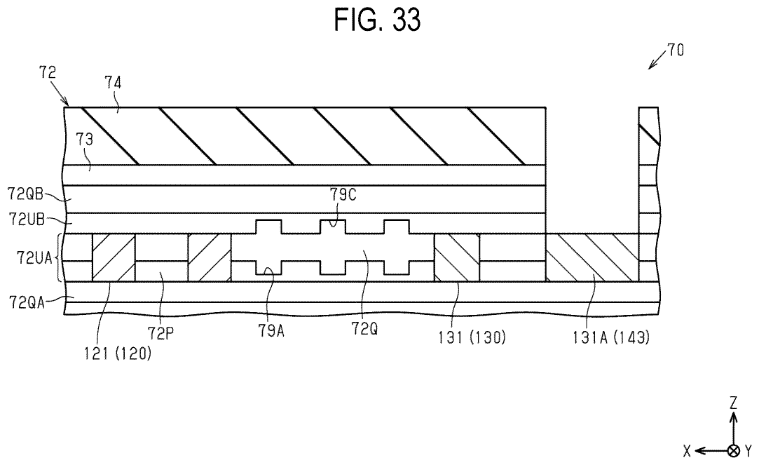

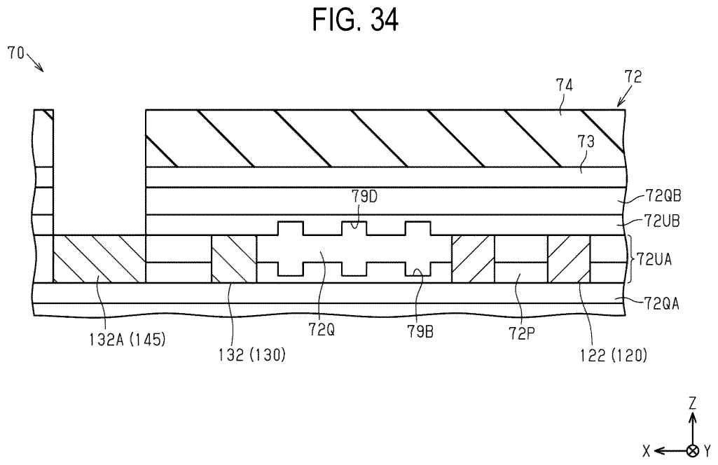

The first isolation insulating film 78A1, the second isolation insulating film 78A2, the first cover side isolation insulating film 78B1, and the second cover side isolation insulating film 78B2 in the modification shown in FIGS. 31 and 32 may be replaced with the configuration shown in FIGS. 33 and 34. FIG. 33 shows an enlarged cross-sectional structure of the first outer coil 121, the first inner coil 131, and their periphery. FIG. 34 shows an enlarged cross-sectional structure of the second outer coil 122, the second inner coil 132, and their periphery.

As shown in FIG. 33, a plurality of first concave portions 79A that open toward the cover insulating film 72UB are provided in a portion of the first insulating film 72P of the specific insulator 72UA between the first inner coil 131 and the first outer coil 121. Each first concave portion 79A is formed in an annular shape in a plan view. In one example, the plurality of first concave portions 79A are formed in a concentric shape in a plan view. In one example, centers of the plurality of first concave portions 79A are concentric with the center of the first inner coil 131 and the center of the first outer coil 121. The second insulating film 72Q of the specific insulator 72UA enters each first concave portion 79A. As shown in FIG. 34, a plurality of second concave portions 79B that open toward the cover insulating film 72UB are provided in a portion of the first insulating film 72P of the specific insulator 72UA between the second inner coil 132 and the second outer coil 122. Each second concave portion 79B is formed in an annular shape in a plan view. In one example, the plurality of second concave portions 79B are formed in a concentric circle shape in a plan view. In one example, centers of the plurality of second concave portions 79B are concentric with the center of the second inner coil 132 and the center of the second outer coil 122. The second insulating film 72Q of the specific insulator 72UA enters each second concave portion 79B.

As shown in FIG. 33, a plurality of first cover side concave portions 79C that open toward the first insulating film 72P of the specific insulator 72UA are provided in a portion of the cover insulating film 72UB between the first inner coil 131 and the first outer coil 121. Each first cover side concave portion 79C is formed in an annular shape in a plan view. In one example, the plurality of first cover side concave portions 79C are formed in a concentric shape in a plan view. In one example, centers of the plurality of first cover side concave portions 79C are concentric with the center of the first inner coil 131 and the center of the first outer coil 121. The second insulating film 72Q of the specific insulator 72UA enters each first cover side concave portion 79C. As shown in FIG. 34, a plurality of second cover side concave portions 79D that open toward the first insulating film 72P of the specific insulator 72UA are provided in a portion of the cover insulating film 72UB between the second inner coil 132 and the second outer coil 122. Each second cover side concave portion 79D is formed in an annular shape in a plan view. In one example, the plurality of second cover side concave portions 79D are formed in a concentric shape in a plan view. In one example, centers of the second cover side concave portions 79D are concentric with the center of the second inner coil 132 and the center of the second outer coil 122. The second insulating film 72Q of the specific insulator 72UA enters each second cover side concave portion 79D.

With this configuration, as in the modification shown in FIGS. 31 and 32, the plurality of first concave portions 79A and the plurality of first cover side concave portions 79C may increase the creepage distance between the first inner coil 131 and the first outer coil 121. Further, the plurality of second concave portions 79B and the plurality of second cover side concave portions 79D may increase the creepage distance between the second inner coil 132 and the second outer coil 122. Therefore, it is possible to improve the dielectric breakdown voltage of the semiconductor device 10 while suppressing the increase in size of the transformer chip 70.

### Modifications Common to First to Third Embodiments

In each embodiment, the configuration of the third element insulating layer 72 of the transformer chip 70 may be changed arbitrarily. In one example, the first insulating film 72P may be omitted from the third element insulating layer 72. That is, the insulating layer stack structure 72T of the third element insulating layer 72 may be configured by stacking a plurality of second insulating films 72Q.

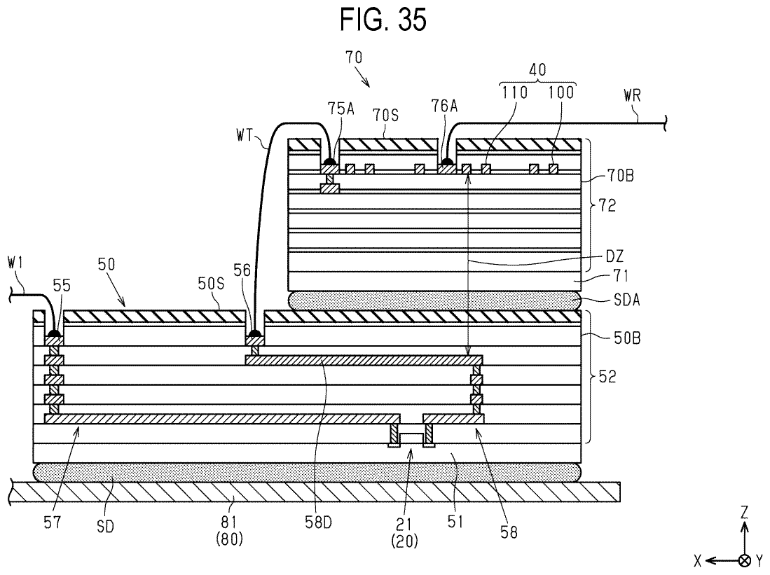

As shown in FIG. 35, the transformer chip 70 may be bonded onto the first chip 50 by an insulating bonding material SDA. That is, the insulating bonding material SDA may be interposed between the transformer chip 70 and the first chip 50 in the Z direction. With this configuration, the distance DZ between the second intermediate wiring 58D of the first chip 50 and the inner coil 110 of the transformer chip 70 in the Z direction may be increased by a thickness of the insulating bonding material SDA. Therefore, the dielectric breakdown voltage of the semiconductor device 10 may be improved.

The position of the second intermediate wiring 58D in the Z direction may be changed arbitrarily. In one example, the second intermediate wiring 58D may be disposed to be closer to the first semiconductor substrate 51 than a center of the insulator 52T in the Z direction. This makes it possible to increase a distance in the Z direction between the second intermediate wiring 58D and the inner coil 110. Therefore, the breakdown voltage of the semiconductor device 10 may be improved.

The disposition form of the transformer chip 70 over the first chip 50 may be changed arbitrarily. In one example, the transformer chip 70 may be disposed over the first chip 50 so that the third semiconductor substrate 71 is located on an opposite side of the third element insulating layer 72 from the first chip 50. In this case, the first transformer pads 75A and 75B and the second transformer pads 76A and 76B may be provided on the third semiconductor substrate 71.

The outer coil 100 (120) and the inner coil 110 (130) may be disposed at different positions in the Z direction. When the transformer chip 70 is disposed over the first chip 50, the outer coil 100 (120) may be disposed to be closer to the third element back surface 72R of the third element insulating layer 72 than the inner coil 110 (130) is disposed in the Z direction.

With this configuration, a facing area between the outer coil 100 (120) and the inner coil 110 (130) may be reduced while increasing the distance DZ between the inner coil 110 (130) and the second intermediate wiring 58D of the second connection wiring 58 of the first chip 50 in the Z direction. Therefore, a capacitance of a parasitic capacitor caused by this facing area may be reduced.

The position of the intermediate pad 56 of the first chip 50 may be changed arbitrarily. The intermediate pad 56 may be disposed at an end portion, which is closer to the chip side surface 50A, of both end portions of the chip front surface 50S in the X direction. As a result, the length of the transmitting side wire WT (WT1 and WT2) may be equal to or longer than the length of the receiving side wire WR (WR1 and WR2).

The third semiconductor substrate 71 may be omitted from the transformer chip 70.

The position of the transformer chip 70 in the X direction relative to the first chip 50 may be changed arbitrarily. In one example, the transformer chip 70 may be disposed over the first chip 50 such that the chip side surface 70B of the transformer chip 70 is closer to the chip side surface 50A of the first chip 50 than the chip side surface 50B of the first chip 50.

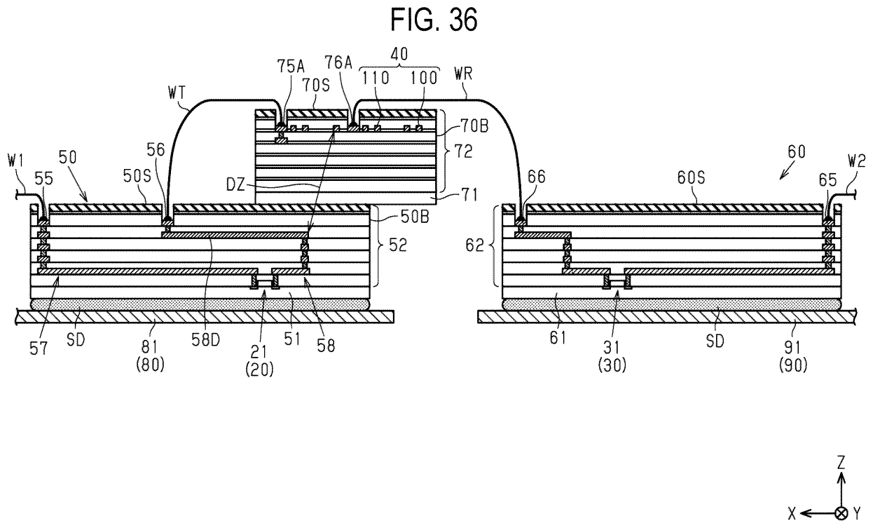

As shown in FIG. 36, the transformer chip 70 may be disposed toward the second chip 60, shifted from the first chip 50 in the X direction. That is, the chip side surface 70B of the transformer chip 70 is disposed to be closer to the second chip 60 than the chip side surface 50B of the first chip 50. In the example shown in FIG. 36, the inner coil 110 is disposed to be closer to the second chip 60 than the second intermediate wiring 58D of the second connection wiring 58. That is, the inner coil 110 does not face the second intermediate wiring 58D in the Z direction.

With this configuration, since the first chip 50 and the second chip 60 are closer to each other in a plan view, the length of the receiving side wire WR may be shortened. Further, the inner coil 110 may be disposed to face the second intermediate wiring 58D in the Z direction.

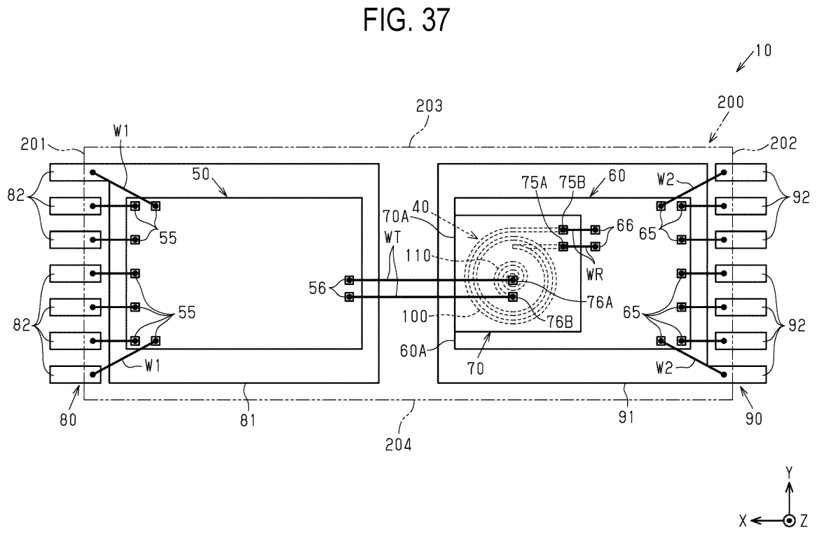

As shown in FIG. 37, the transformer chip 70 may be disposed over the second chip 60. With this configuration, the length of the receiving side wire WR may be shortened.

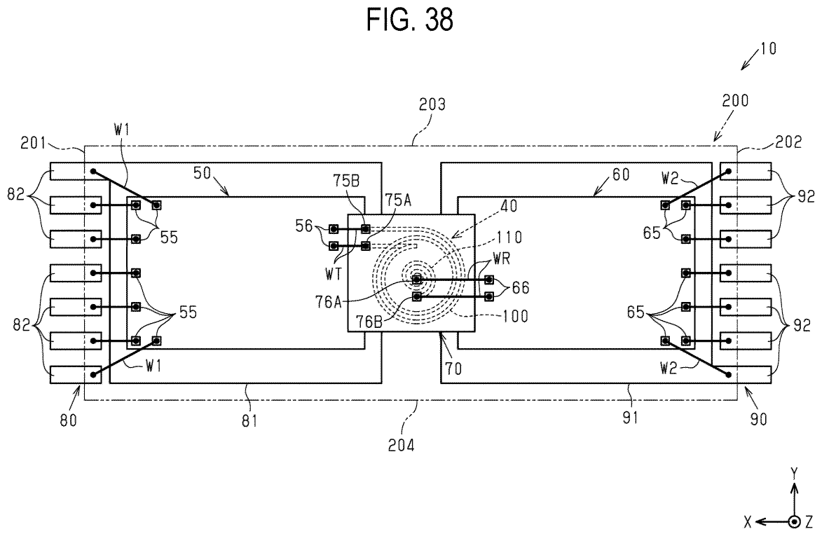

As shown in FIG. 38, the transformer chip 70 may be disposed over the first chip 50 and over the second chip 60 so as to straddle the first chip 50 and the second chip 60 in the X direction. With this configuration, the length of the receiving side wire WR may be shortened.

The semiconductor device 10 is not limited to a configuration as a signal transmission device that transmits a signal via the transformer 40, and may be configured as a power transmission device that transmits power via the transformer 40.

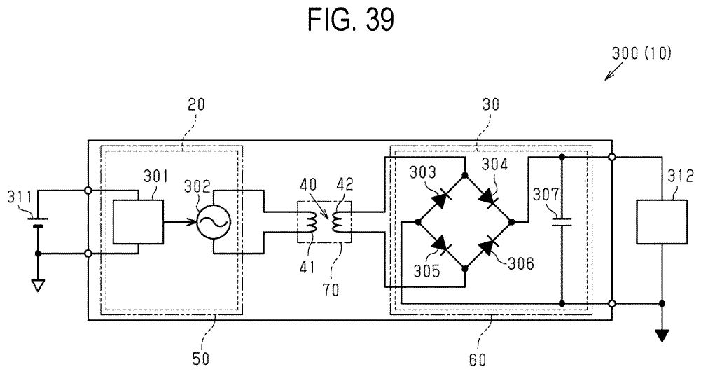

FIG. 39 shows an example of a circuit configuration of a power transmission device 300 as a modification of the semiconductor device 10. The power transmission device 300 may include a control circuit 301, an oscillator 302, a transformer 40, diodes 303 to 306, and a smoothing capacitor 307. The control circuit 301 and the oscillator 302 may be included in the first circuit 20. The first circuit 20 may include the oscillator 302 but may not include the control circuit 301. The diodes 303 to 306 and the smoothing capacitor 307 may be included in the second circuit 30. The second circuit 30 may include the diodes 303 to 306 but may not include the smoothing capacitor 307. Further, the number of diodes included in the second circuit 30 may be changed as appropriate depending on a configuration of a rectification circuit. In one example, the first chip 50 including the control circuit 301 and the oscillator 302, the transformer chip 70 including the transformer 40, and the second chip 60 including the diodes 303 to 306 and the smoothing capacitor 307 are sealed with the sealing resin 200, similar to the semiconductor device 10 according to the first embodiment.

The control circuit 301 is connected to a DC power supply 311. The oscillator 302 is controlled by the control circuit 301. The oscillator 302 outputs an AC signal. This AC signal is transmitted by the transformer 40. A DC voltage by the diodes 303 to 306 and the smoothing capacitor 307 is supplied to a load 312. In other words, the power transmission device 300 functions as a DC voltage conversion circuit (DC-DC converter) that converts a voltage of the DC power supply 311 into an operating voltage of the load 312.

The term “over” as used in the present disclosure includes the meanings of “on” and “above” unless clearly stated otherwise in the context. Therefore, for example, the expression “a first element is disposed over a second element” is intended that in some embodiments, the first element may be directly disposed on the second element in contact with the second element, while in other embodiments, the first element may be disposed above the second element without contacting the second element. That is, the term “over” does not exclude a structure in which other elements are formed between the first element and the second element.

The Z direction used in the present disclosure does not necessarily have to be a vertical direction, nor does it have to completely coincide with the vertical direction. Therefore, various structures according to the present disclosure are not limited to the Z direction “up” and “down” described herein being the vertical direction “up” and “down.” For example, the X direction may be the vertical direction, or the Y direction may be the vertical direction.

### Supplementary Notes

The technical ideas that may be understood from the present disclosure are described below. In addition, for the purpose of aiding understanding and not for the purpose of limitation, constituent elements described in supplementary notes are labeled with the reference numerals of the corresponding constituent elements in the above-described embodiments. The reference numerals are provided as examples to aid understanding, and the constituent elements described in supplementary notes should not be limited to the constituent elements indicated by the reference numerals.

### Supplementary Note 1

A semiconductor device (10) including:
a first chip (50) including a first circuit (20);
a second chip (60) disposed to be spaced apart from the first chip (50) in a first direction (X direction) and including a second circuit (30); and
a transformer chip (70) disposed over the first chip (50) and including a transformer (40),
wherein the first circuit (20) and the second circuit (30) are configured to transmit a signal or power via the transformer (40),
wherein the transformer chip (70) includes:
   a third element insulating layer (72); and
   an outer coil (100) and an inner coil (110) disposed as the transformer (40) in the third element insulating layer (72), and
wherein the inner coil (110) is disposed inside the outer coil (100) so as not to overlap the outer coil (100) when viewed from a thickness direction (Z direction) of the third element insulating layer (72).

### Supplementary Note 2

The semiconductor device of Supplementary Note 1, wherein the transformer chip (70) includes a third semiconductor substrate (71) in contact with the third element insulating layer (72), and
wherein in a chip disposition state in which the transformer chip (70) is disposed over the first chip (50), the third semiconductor substrate (71) is interposed between the third element insulating layer (72) and the first chip (50).

### Supplementary Note 3

The semiconductor device of Supplementary Note 2, wherein the third element insulating layer (72) includes a third element front surface (72S) and a third element back surface (72R) opposite to the third element front surface (72S),
wherein the outer coil (100) is electrically connected to the first circuit (20), and
wherein the inner coil (110) is disposed to be closer to the third element front surface (72S) than the third element back surface (72R) of the third element insulating layer (72).

### Supplementary Note 4

The semiconductor device of any one of Supplementary Notes 1 to 3, wherein the first circuit (20) includes a transmitting circuit (21), and the second circuit (30) includes a receiving circuit (31),
wherein the outer coil (100) and the transmitting circuit (21) are electrically connected via a transmitting side wire (WT), and the inner coil (110) and the receiving circuit (31) are electrically connected via a receiving side wire (WR), and
wherein a length of the transmitting side wire (WT) is shorter than a length of the receiving side wire (WR).

### Supplementary Note 5

The semiconductor device of any one of Supplementary Notes 1 to 4, wherein the inner coil (110) and the outer coil (100) are disposed at a same position in the thickness direction (Z direction).

### Supplementary Note 6

The semiconductor device of any one of Supplementary Notes 1 to 5, wherein the third element insulating layer (72) includes a structure in which a plurality of insulators (72U), each including a first insulating film (72P) containing silicon nitride and a second insulating film (72Q) containing silicon oxide stacked over the first insulating film (72P), are stacked,
wherein the inner coil (110) and the outer coil (100) are provided so as to penetrate a specific insulator (72UA) which is a specific one of the insulators (72U),
wherein the third element insulating layer (72) includes a cover insulating film (72UB) including the first insulating film (72P) and in contact with the second insulating film (72Q) of the specific insulator (72UA) so as to cover the inner coil (110) and the outer coil (100),
wherein a portion of the first insulating film (72P) of the specific insulator (72UA) between the inner coil (110) and the outer coil (100) includes a plurality of isolation insulating films (78A) provided to be spaced apart from each other in a direction orthogonal to the thickness direction (Z direction) of the third element insulating layer (72),
wherein a portion of the cover insulating film (72UB) between the inner coil (110) and the outer coil (100) includes a plurality of cover side isolation insulating films (78B) provided to be spaced apart from each other in the direction orthogonal to the thickness direction (Z direction), and wherein each of the plurality of isolation insulating films (78A) and the plurality of cover side isolation insulating films (78B) includes the second insulating film (72Q).

### Supplementary Note 7

The semiconductor device of Supplementary Note 6, wherein each of the plurality of isolation insulating films (78A) and the plurality of cover side isolation insulating films (78B) is formed in an annular shape.

### Supplementary Note 8

The semiconductor device of any one of Supplementary Notes 1 to 5, wherein the third element insulating layer (72) includes a structure in which a plurality of insulators (72U), each including a first insulating film (72P) containing silicon nitride and a second insulating film (72Q) containing silicon oxide stacked over the first insulating film (72P), are stacked,
wherein the inner coil (110) and the outer coil (100) are provided so as to penetrate a specific insulator (72UA) which is a specific one of the insulators (72U),
wherein the third element insulating layer (72) includes a cover insulating film (72UB) including the first insulating film (72P) and in contact with the second insulating film (72Q) of the specific insulator (72UA) so as to cover the inner coil (110) and the outer coil (100),
wherein a portion of the first insulating film (72P) of the specific insulator (72UA) between the inner coil (110) and the outer coil (100) includes a plurality of concave portions (72PC) that are provided to be spaced apart from each other in a direction orthogonal to the thickness direction (Z direction) of the third element insulating layer (72) and open toward the cover insulating film (72UB),
wherein a portion of the cover insulating film (72UB) between the inner coil (110) and the outer coil (100) includes a plurality of cover side concave portions (72PD) that are provided to be spaced apart from each other in the direction orthogonal to the thickness direction (Z direction) and open toward the first insulating film (72P) of the specific insulator (72UA), and
wherein the second insulating film (72Q) is embedded in each of the plurality of concave portions (72PC) and the plurality of cover side concave portions (72PD).

### Supplementary Note 9

The semiconductor device of Supplementary Note 8, wherein each of the plurality of concave portions (72PC) and the plurality of cover side concave portions (72PD) is formed in an annular shape.

### Supplementary Note 10

The semiconductor device of any one of Supplementary Notes 1 to 5, wherein the outer coil (120) includes a first outer coil (121) and a second outer coil (122), each including a first end (121A, 122A) and a second end (121B, 122B),
wherein the second end (121B) of the first outer coil (121) and the second end (122B) of the second outer coil (122) are connected to each other,
wherein the first outer coil (121) and the second outer coil (122) are configured to generate magnetic fluxes in opposite directions when a current flows from the first end of one of the first outer coil (121) and the second outer coil (122) to the first end of the other of the first outer coil (121) and the second outer coil (122),
wherein the inner coil (130) includes a first inner coil (131) and a second inner coil (132), each including a first end (131A, 132A) and a second end (131B, 132B), and
wherein when viewed from the thickness direction (Z direction) of the third element insulating layer (72), the first inner coil (131) is disposed inside the first outer coil (121) so as not to overlap the first outer coil (121), and the second inner coil (132) is disposed inside the second outer coil (122) so as not to overlap the second outer coil (122).

### Supplementary Note 11

The semiconductor device of Supplementary Note 10, wherein the first inner coil (131) and the second inner coil (132) are connected by a coil connecting wire (WC) provided outside the transformer chip (70).

### Supplementary Note 12

The semiconductor device of Supplementary Note 10 or 11, wherein the first outer coil (121) is electrically connected to the first chip (50) by a first chip connecting wire (WT1) provided outside the transformer chip (70), and
wherein the second outer coil (122) is electrically connected to the first chip (50) by a second chip connecting wire (WT2) provided outside the transformer chip (70).

### Supplementary Note 13

The semiconductor device of any one of Supplementary Notes 10 to 12, wherein the first inner coil (131) is electrically connected to the second chip (60) by a third chip connecting wire (WR1) provided outside the transformer chip (70), and
wherein the second inner coil (132) is electrically connected to the second chip (60) by a fourth chip connecting wire (WR2) provided outside the transformer chip (70).

### Supplementary Note 14

The semiconductor device of any one of Supplementary Notes 1 to 13, wherein when viewed in the thickness direction (Z direction), the transformer chip (70) is smaller than the first chip (50) and is disposed to be biased toward the second chip (60) with respect to the first chip (50) in the first direction (X direction).

### Supplementary Note 15

The semiconductor device of any one of Supplementary Notes 1 to 13, wherein the transformer chip (70) is disposed toward the second chip (60), shifted from the first chip (50) in the first direction (X direction).

### Supplementary Note 16

The semiconductor device of any one of Supplementary Notes 1 to 15, wherein an insulating bonding material (SDA) is interposed between the first chip (50) and the transformer chip (70).

### Supplementary Note 17

The semiconductor device of any one of Supplementary Notes 1 to 16, further including:
a first die pad (81) that supports the first chip (50);
a second die pad (91) that supports the second chip (60); and
a sealing resin (200) that seals the first chip (50), the second chip (60), the transformer chip (70), the first die pad (81), and the second die pad (91).

### Supplementary Note 18

A semiconductor device (10) including:
a first chip (50) including a first circuit (20);
a second chip (60) disposed to be spaced apart from the first chip (50) in a first direction (X direction) and including a second circuit (30); and
a transformer chip (70) disposed over the second chip (60) and including a transformer (40),
wherein the first circuit (20) and the second circuit (30) are connected via the transformer (40) and are configured to transmit a signal or power via the transformer (40),
wherein the transformer chip (70) includes:
   a third element insulating layer (72); and
   an outer coil (100) and an inner coil (110) disposed as the transformer (40) in the third element insulating layer (72), and
wherein the inner coil (110) is disposed inside the outer coil (100) so as not to overlap the outer coil (100) when viewed from a thickness direction (Z direction) of the third element insulating layer (72).

### Supplementary Note 19

The semiconductor device of any one of Supplementary Notes 1 to 13, wherein the transformer chip (70) is disposed over the first chip (50) and over the second chip (60) so as to straddle the first direction (X direction) between the first chip (50) and the second chip (60).

### Supplementary Note 20

The semiconductor device of any one of Supplementary Notes 10 to 13, wherein the first inner coil (131), the second inner coil (132), the first outer coil (121), and the second outer coil (122) are disposed at a same position in the thickness direction (Z direction).

### Supplementary Note 21

The semiconductor device of any one of Supplementary Notes 10 to 13, wherein the third element insulating layer (72) includes a structure in which a plurality of insulators (72U), each including a first insulating film (72P) containing silicon nitride and a second insulating film (72Q) containing silicon oxide stacked over the first insulating film (72P), are stacked,
wherein the first inner coil (131), the second inner coil (132), the first outer coil (121), and the second outer coil (122) are provided so as to penetrate a specific insulator (72UA) which is a specific one of the insulators (72U),
wherein the third element insulating layer (72) includes a cover insulating film (72UB) including the first insulating film (72P) and in contact with the second insulating film (72Q) of the specific insulator (72UA) so as to cover the first inner coil (131), the second inner coil (132), the first outer coil (121), and the second outer coil (122),
wherein a portion of the first insulating film (72P) of the specific insulator (72UA) between the first inner coil (131) and the first outer coil (121) includes a plurality of first isolation insulating films (78A1) provided to be spaced apart from each other in a direction orthogonal to the thickness direction (Z direction),
wherein a portion of the first insulating film (72P) of the specific insulator (72UA) between the second inner coil (132) and the second outer coil (122) includes a plurality of second isolation insulating films (78A2) provided to be spaced apart from each other in the direction orthogonal to the thickness direction (Z direction),
wherein a portion of the cover insulating film (72UB) between the first inner coil (131) and the first outer coil (121) includes a plurality of first cover side isolation insulating films (78B1) provided to be spaced apart from each other in the direction orthogonal to the thickness direction (Z direction),
wherein a portion of the cover insulating film (72UB) between the second inner coil (132) and the second outer coil (122) includes a plurality of second cover side isolation insulating films (78B2) provided to be spaced apart from each other in the direction orthogonal to the thickness direction (Z direction), and
wherein each of the plurality of first isolation insulating films (78A1), the plurality of second isolation insulating films (78A2), the plurality of first cover side isolation insulating films (78B1), and the plurality of second cover side isolation insulating films (78B2) includes the second insulating film (72Q).

### Supplementary Note 22

The semiconductor device of Supplementary Note 21, wherein each of the plurality of first isolation insulating films (78A1), the plurality of second isolation insulating films (78A2), the plurality of first cover side isolation insulating films (78B1), and the plurality of second cover side isolation insulating films (78B2) is formed in an annular shape.

### Supplementary Note 23

The semiconductor device of any one of Supplementary Notes 10 to 13, wherein the third element insulating layer (72) includes a structure in which a plurality of insulators (72U), each including a first insulating film (72P) containing silicon nitride and a second insulating film (72Q) containing silicon oxide stacked over the first insulating film (72P), are stacked,
wherein the first inner coil (131), the second inner coil (132), the first outer coil (121), and the second outer coil (122) are provided so as to penetrate a specific insulator (72UA) which is a specific one of the insulators (72U),
wherein the third element insulating layer (72) includes a cover insulating film (72UB) including the first insulating film (72P) and in contact with the second insulating film (72Q) of the specific insulator (72UA) so as to cover the first inner coil (131), the second inner coil (132), the first outer coil (121), and the second outer coil (122),
wherein a portion of the first insulating film (72P) of the specific insulator (72UA) between the first inner coil (131) and the first outer coil (121) includes a plurality of first concave portions (79A) that are provided to be spaced apart from each other in a direction orthogonal to the thickness direction (Z direction) and open toward the cover insulating film (72UB),
wherein a portion of the first insulating film (72P) of the specific insulator (72UA) between the second inner coil (132) and the second outer coil (122) includes a plurality of second concave portions (79B) that are provided to be spaced apart from each other in the direction orthogonal to the thickness direction (Z direction) and open toward the cover insulating film (72UB),
wherein a portion of the cover insulating film (72UB) between the first inner coil (131) and the first outer coil (121) includes a plurality of first cover side concave portions (79C) that are provided to be spaced apart from each other in the direction orthogonal to the thickness direction (Z direction) and open toward the first insulating film (72P) of the specific insulator (72UA),
wherein a portion of the cover insulating film (72UB) between the second inner coil (132) and the second outer coil (122) includes a plurality of second cover side concave portions (79D) that are provided to be spaced apart from each other in the direction orthogonal to the thickness direction (Z direction) and open toward the first insulating film (72P) of the specific insulator (72UA), and
wherein the second insulating film (72Q) is embedded in each of the plurality of first concave portions (79A), the plurality of second concave portions (79B), the plurality of first cover side concave portions (79C), and the plurality of second cover side concave portions (79D).

### Supplementary Note 24

The semiconductor device of Supplementary Note 23, wherein each of the plurality of first concave portions (79A), the plurality of second concave portions (79B), the plurality of first cover side concave portions (79C), and plurality of the second cover side concave portions (79D) is formed in an annular shape.

### Supplementary Note 25

A semiconductor device (10) including:
a first chip (50) including a first circuit (20);
a second chip (60) disposed to be spaced apart from the first chip (50) in a first direction (X direction) and including a second circuit (30); and
a transformer chip (70) disposed over the first chip (50) and over the second chip (60) so as to straddle between the first chip (50) and the second chip (60) in the first direction (X direction) and including a transformer (40),
wherein the first circuit (20) and the second circuit (30) are connected via the transformer and are configured to transmit a signal or power via the transformer (40),
wherein the transformer chip (70) includes:
   a third element insulating layer (72); and
   an outer coil (100) and an inner coil (110) disposed as the transformer (40) in the third element insulating layer (72), and
wherein the inner coil (110) is disposed inside the outer coil (100) so as not to overlap the outer coil (100) when viewed from a thickness direction (Z direction) of the third element insulating layer (72).

The above description is merely an example. Those skilled in the art will appreciate that more possible combinations and substitutions are possible beyond the constituent elements and methods (manufacturing processes) listed for the purposes of illustrating the techniques of the present disclosure. The present disclosure is intended to cover all alternatives, modifications, and changes that fall within the scope of the present disclosure, including the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a first chip including a first circuit;
a second chip disposed to be spaced apart from the first chip in a first direction and including a second circuit; and
a transformer chip disposed over the first chip and including a transformer,
wherein the first circuit and the second circuit are configured to transmit a signal or power via the transformer,
wherein the transformer chip includes:
an element insulating layer; and
an outer coil and an inner coil disposed as the transformer in the element insulating layer, and
wherein the inner coil is disposed inside the outer coil so as not to overlap the outer coil when viewed from a thickness direction of the element insulating layer.

2. The semiconductor device of claim 1, wherein the transformer chip includes a semiconductor substrate in contact with the element insulating layer, and
wherein in a chip disposition state in which the transformer chip is disposed over the first chip, the semiconductor substrate is interposed between the element insulating layer and the first chip.

3. The semiconductor device of claim 2, wherein the element insulating layer includes an element front surface and an element back surface opposite to the element front surface,
wherein the outer coil is electrically connected to the first circuit, and
wherein the inner coil is disposed to be closer to the element front surface than the element back surface of the element insulating layer.

4. The semiconductor device of claim 1, wherein the first circuit includes a transmitting circuit, and the second circuit includes a receiving circuit,
wherein the outer coil and the transmitting circuit are electrically connected via a transmitting side wire, and the inner coil and the receiving circuit are electrically connected via a receiving side wire, and
wherein a length of the transmitting side wire is shorter than a length of the receiving side wire.

5. The semiconductor device of claim 1, wherein the inner coil and the outer coil are disposed at a same position in the thickness direction.

6. The semiconductor device of claim 1, wherein the element insulating layer includes a structure in which a plurality of insulators, each including a first insulating film containing silicon nitride and a second insulating film containing silicon oxide stacked over the first insulating film, are stacked,
wherein the inner coil and the outer coil are provided so as to penetrate a specific insulator which is a specific one of the insulators,
wherein the element insulating layer includes a cover insulating film including the first insulating film and in contact with the second insulating film of the specific insulator so as to cover the inner coil and the outer coil,
wherein a portion of the first insulating film of the specific insulator between the inner coil and the outer coil includes a plurality of isolation insulating films provided to be spaced apart from each other in a direction orthogonal to the thickness direction of the element insulating layer,
wherein a portion of the cover insulating film between the inner coil and the outer coil includes a plurality of cover side isolation insulating films provided to be spaced apart from each other in the direction orthogonal to the thickness direction, and
wherein each of the plurality of isolation insulating films and the plurality of cover side isolation insulating films includes the second insulating film.

7. The semiconductor device of claim 6, wherein each of the plurality of isolation insulating films and the plurality of cover side isolation insulating films is formed in an annular shape.

8. The semiconductor device of claim 1, wherein the element insulating layer includes a structure in which a plurality of insulators, each including a first insulating film containing silicon nitride and a second insulating film containing silicon oxide stacked over the first insulating film, are stacked,
wherein the inner coil and the outer coil are provided so as to penetrate a specific insulator which is a specific one of the insulators,
wherein the element insulating layer includes a cover insulating film including the first insulating film and in contact with the second insulating film of the specific insulator so as to cover the inner coil and the outer coil,
wherein a portion of the first insulating film of the specific insulator between the inner coil and the outer coil includes a plurality of concave portions that are provided to be spaced apart from each other in a direction orthogonal to the thickness direction of the element insulating layer and open toward the cover insulating film,
wherein a portion of the cover insulating film between the inner coil and the outer coil includes a plurality of cover side concave portions that are provided to be spaced apart from each other in the direction orthogonal to the thickness direction and open toward the first insulating film of the specific insulator, and
wherein the second insulating film is embedded in each of the plurality of concave portions and the plurality of cover side concave portions.

9. The semiconductor device of claim 8, wherein each of the plurality of concave portions and the plurality of cover side concave portions is formed in an annular shape.

10. The semiconductor device of claim 1, wherein the outer coil includes a first outer coil and a second outer coil, each including a first end and a second end,
wherein the second end of the first outer coil and the second end of the second outer coil are connected to each other,
wherein the first outer coil and the second outer coil are configured to generate magnetic fluxes in opposite directions when a current flows from the first end of one of the first outer coil and the second outer coil to the first end of the other of the first outer coil and the second outer coil,
wherein the inner coil includes a first inner coil and a second inner coil, each including a first end and a second end, and
wherein when viewed from the thickness direction of the element insulating layer, the first inner coil is disposed inside the first outer coil so as not to overlap the first outer coil, and the second inner coil is disposed inside the second outer coil so as not to overlap the second outer coil.

11. The semiconductor device of claim 10, wherein the first inner coil and the second inner coil are connected by a coil connecting wire provided outside the transformer chip.

12. The semiconductor device of claim 10, wherein the first outer coil is electrically connected to the first chip by a first chip connecting wire provided outside the transformer chip, and
wherein the second outer coil is electrically connected to the first chip by a second chip connecting wire provided outside the transformer chip.

13. The semiconductor device of claim 10, wherein the first inner coil is electrically connected to the second chip by a third chip connecting wire provided outside the transformer chip, and
wherein the second inner coil is electrically connected to the second chip by a fourth chip connecting wire provided outside the transformer chip.

14. The semiconductor device of claim 1, wherein when viewed in the thickness direction, the transformer chip is smaller than the first chip and is disposed to be biased toward the second chip with respect to the first chip in the first direction.

15. The semiconductor device of claim 1, wherein the transformer chip is disposed toward the second chip, shifted from the first chip in the first direction.

16. The semiconductor device of claim 1, wherein an insulating bonding material is interposed between the first chip and the transformer chip.

17. The semiconductor device of claim 1, further comprising:
a first die pad that supports the first chip;
a second die pad that supports the second chip; and
a sealing resin that seals the first chip, the second chip, the transformer chip, the first die pad, and the second die pad.

18. A semiconductor device comprising:
a first chip including a first circuit;
a second chip disposed to be spaced apart from the first chip in a first direction and including a second circuit; and
a transformer chip disposed over the second chip and including a transformer,
wherein the first circuit and the second circuit are connected via the transformer and are configured to transmit a signal or power via the transformer,
wherein the transformer chip includes:
an element insulating layer; and
an outer coil and an inner coil disposed as the transformer in the element insulating layer, and
wherein the inner coil is disposed inside the outer coil so as not to overlap the outer coil when viewed from a thickness direction of the clement insulating layer.
